(19) United States
(12) Patent Application Publication
(10) Pub. No.: US 2024/0244951 A1
(43) Pub. Date: Jul. 18, 2024

(54) ORGANOMETALLIC COMPOUND, ORGANIC LIGHT EMITTING DIODE AND ORGANIC LIGHT EMITTING DEVICE INCLUDING THE SAME

(71) Applicant: LG DISPLAY CO., LTD., Seoul (KR)

(72) Inventors: Na-Yeon LEE, Paju-si (KR); Tae-Ryang HONG, Paju-si (KR); Gyu-Hyeong KIM, Paju-si (KR)

(73) Assignee: LG DISPLAY CO., LTD., Seoul (KR)

(21) Appl. No.: 18/522,170

(22) Filed: Nov. 28, 2023

(30) Foreign Application Priority Data
Dec. 22, 2022 (KR) 10-2022-0181357

(51) Int. Cl. H10K 85/30; C07F 15/00; C09K 11/06; H10K 50/13

(52) U.S. Cl. CPC H10K 85/342; C07F 15/0033; C09K 11/06; H10K 50/131; H10K 50/12

(57) ABSTRACT

The present disclosure relates to an organometallic compound and an organic light emitting diode and an organic light emitting device each including the same, and more specifically, relates to an organometallic compound of following and an organic light emitting diode and an organic light emitting device each including the organometallic compound.

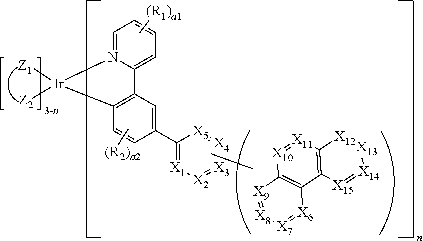

### CROSS-REFERENCE TO RELATED APPLICATIONS

The present application claims the benefit of Korean Patent Application No. 10-2022-0181357 filed in the Republic of Korea on Dec. 22, 2022, which is hereby incorporated by reference in its entirety.

### BACKGROUND

### Technical Field

The present disclosure relates to an organometallic compound, and more particularly, to an organometallic compound being capable of improving an emitting efficiency and an emission lifespan, an organic light emitting diode including an organometallic compound and an organic light emitting device including the organic light emitting diode.

### Description of the Related Art

Recently, requirement for flat panel display devices having small occupied area is increased. Among the flat panel display devices, a technology of an organic light emitting display device, which includes an organic light emitting diode (OLED) and may be called to as an organic electroluminescent device, is rapidly developed.

The OLED includes a cathode as an electron injection electrode, an anode as a hole injection electrode and an organic light emitting layer, which is disposed between the cathode and the anode and includes a host and a dopant. When electrons from the cathode and holes from the anode are injected into the organic light emitting layer, the electrons and holes are combined to generate an exciton, and the exciton is transformed from an excited state to a ground state. As a result, the light is emitted from the OLED. The OLED can be formed on a flexible transparent substrate, e.g., a plastic substrate, and can be driven by low voltage. In addition, the OLED has low power consumption and high color purity.

The dopant can be classified into a fluorescent material and a phosphorescent material.

In the fluorescent material, since only singlet exciton anticipates in the light emission, the fluorescent material has low emitting efficiency. In the phosphorescent material, since not only singlet exciton but also triplet exciton anticipates in the light emission, the phosphorescent material has high emitting efficiency. However, since an organometallic compound as a representative phosphorescent material has a short emission lifespan, there is a limitation in commercialization. Therefore, there is a need to develop a compound with improved emitting efficiency and emission lifespan.

### SUMMARY

Accordingly, embodiments of the present disclosure are directed to an organometallic compound, an OLED and an organic light emitting device that substantially obviate one or more of the problems associated with the limitations and disadvantages of the related art.

An object of the present disclosure is to provide an organometallic compound having improved emitting efficiency and emission lifespan.

An object of the present disclosure is to provide an OLED and an organic light emitting device including the organometallic compound.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

To achieve these and other advantages and in accordance with the objects of the present disclosure, as embodied and broadly described herein, an aspect of the present disclosure is an organometallic compound represented by Formula 1:

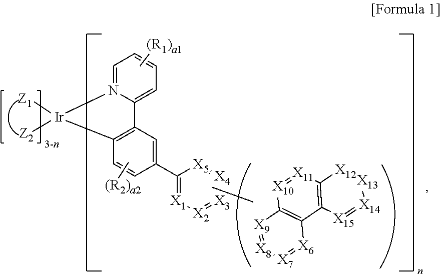

wherein a1 is an integer of 0 to 4, a2 is an integer of 0 to 3, n is an integer of 1 to 3, each of X₁ to X₅ is N or CR₃, and at least one of X₁ to X₅ is CR₃, each of X₆ to X₁₅ is N or CR₄, and at least one of X₆ to X₁₅ is N, at least one of X₆ to X₁₅ is CR₄, each of Z₁ and Z₂ is one of N, CR₅ and O, each of R₁ and R₂ is independently selected from the group consisting of deuterium, halogen, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryloxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group, and each of R₃ to R₅ is independently selected from the group consisting of hydrogen, deuterium, halogen, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryloxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group.

Another aspect of the present disclosure is an organic light emitting diode comprising a first electrode; a second electrode facing the first electrode; and a first emitting part positioned between the first and second electrodes and including a first emitting material layer, wherein the first emitting material layer includes the above organometallic compound.

Another aspect of the present disclosure is an organic light emitting device comprising a substrate; and an organic light emitting diode disposed on the substrate and including a first electrode, a second electrode facing the first electrode, a first emitting part positioned between the first and second electrodes and including a first emitting material layer; and an encapsulation covering the organic light emitting diode, wherein the first emitting material layer includes the organometallic compound.

It is to be understood that both the foregoing general description and the following detailed description are merely by way of example, and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device of the present disclosure.

FIG. 2 is a schematic cross-sectional view of an organic light emitting display device according to a first embodiment of the present disclosure.

FIG. 3 is a schematic cross-sectional view of an OLED according to a second embodiment of the present disclosure.

FIG. 4 is a schematic cross-sectional view of an OLED according to a third embodiment of the present disclosure.

FIG. 5 is a schematic cross-sectional view of an organic light emitting display device according to a fourth embodiment of the present disclosure.

FIG. 6 is a schematic cross-sectional view of an OLED according to a fifth embodiment of the present disclosure.

FIG. 7 is a schematic cross-sectional view of an OLED according to a sixth embodiment of the present disclosure.

FIG. 8 is a schematic cross-sectional view of an OLED according to a seventh embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used. It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Reference will now be made in detail to some of the examples and preferred embodiments, which are illustrated in the accompanying drawings.

An organometallic compound of the present disclosure has improved emitting efficiency and emission lifespan. The organometallic compound of the present disclosure is represented by Formula 1.

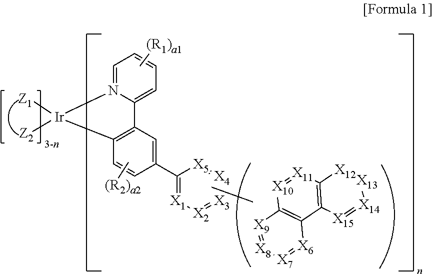

In Formula 1,
a1 is an integer of 0 to 4, a2 is an integer of 0 to 3, n is an integer of 1 to 3,
each of X₁ to X₅ is N or CR₃, and at least one of X₁ to X₅ is CR₃,
each of X₆ to X₁₅ is N or CR₄, and at least one of X₆ to X₁₅ is N, at least one of X₆ to X₁₅ is CR₄,
each of Z₁ and Z₂ is one of N, CR₅ and O,
each of R₁ and R₂ is independently selected from the group consisting of deuterium, halogen, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryloxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group, and each of R₃ to R₅ is independently selected from the group consisting of hydrogen, deuterium, halogen, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryloxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group.

In the present disclosure, without specific definition, when an alkyl group, an alkenyl group, an alkynyl group, an alkoxy group, an alkylamino group, an arylamino group, an alkylsilyl group, an arylsilyl group, an aryl group, a heteroaryl group, a cycloalkyl group, an alicyclic ring, a hetero-alicyclic ring, an aromatic ring and/or a heteroaromatic ring are substituted, a substituent may be selected from the group consisting of deuterium, halogen, a cyano group, a carboxyl group, a carbonyl group, an amine group, an alkylamine group, a nitro group, a hydrazyl group, a sulfone group, an alkyl group unsubstituted or substituted with at least one of halogen and deuterium, an alkoxy group unsubstituted or substituted with at least one of halogen and deuterium, an alkylsilyl group unsubstituted or substituted with at least one of halogen and deuterium, an alkoxysilyl group unsubstituted or substituted with at least one of halogen and deuterium, a cycloalkylsilyl group unsubstituted or substituted with at least one of halogen and deuterium, an arylsilyl group unsubstituted or substituted with at least one of halogen and deuterium, an aryl group unsubstituted or substituted with at least one of halogen and deuterium and a heteroaryl group unsubstituted or substituted with at least one of halogen and deuterium.

In the present disclosure, without specific definition, a C1 to C20 alkyl group may be selected from the group consisting of methyl, ethyl, propyl and butyl, e.g., tert-butyl.

In the present disclosure, without specific definition, a C3 to C30 cycloalkyl group may be selected from the group consisting of cyclopropyl, cyclobutyl, cyclopentyl, cyclohexyl and adamantanyl.

In the present disclosure, without specific definition, a C6 to C30 aryl group (or a C6 to C20 aromatic ring) may be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C3 to C30 heteroaryl group (or a C3 to C20 heteroaromatic ring) may be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, purinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In an aspect of the present disclosure, n may be 1 or 2.

In an aspect of the present disclosure, a1 may be 0 or 1, and a2 may be an integer of 0 to 2.

In an aspect of the present disclosure, each of R₁ and R₂ may be independently a substituted or unsubstituted C1 to C20 alkyl group, e.g., methyl.

In an aspect of the present disclosure, i) all of X₁ to X₅ may be CR₃, or ii) one or two of X₁ to X₅ may be N, and the rest of X₁ to X₅ may be CR₃.

In an aspect of the present disclosure, R₃ may be selected from the group consisting of hydrogen, a substituted or unsubstituted C1 to C20 alkyl group, e.g., methyl or tert-butyl, a C6 to C30 aryl group, e.g., phenyl, unsubstituted or substituted with a C1 to C10 alkyl group, e.g., methyl, and a C3 to C30 heteroaryl group, e.g., pyridyl, unsubstituted or substituted with a C1 to C10 alkyl group, e.g., methyl.

In an aspect of the present disclosure, one or two of X₆ to X₁₅ may be N, and the rest of X₆ to X₁₅ may be CR₄.

In an aspect of the present disclosure, R₄ may be selected from the group consisting of hydrogen, a substituted or unsubstituted C1 to C20 alkyl group, e.g., methyl or tert-butyl, a substituted or unsubstituted C6 to C30 aryl group, e.g., phenyl, and a substituted or unsubstituted C3 to C30 heteroaryl group, e.g., pyridyl or diazinyl.

The organometallic compound having the structure of Formula 1 has a main ligand in which a plurality of aromatic rings and heteroaromatic rings are fused. Accordingly, the full-width at half maximum (FWHM) in the emission spectrum is narrow. In particular, since the organometallic compound has a solid chemical structure, the rotation of the chemical structure is not free during the light emission process, so that a good light emission lifespan can be stably maintained. Since the emission spectrum of the organometallic compound according to the present disclosure can be limited to a specific range, the color purity of the organometallic compound is improved.

In addition, the organometallic compound of the present disclosure may be a heteroleptic metal complex compound in which different main ligand and auxiliary ligand are bonded to a central metal (iridium). Therefore, the color purity and the emission wavelength range of the organometallic compound can be easily controlled.

The organometallic compound having the structure of Formula 1 may have an emission wavelength range of green to red. For example, the organometallic compound having the structure of Formula 1 may be used as at least one of a green dopant, a yellow-green dopant and a red dopant. The organometallic compound emitting red light, the organometallic compound emitting green light and the organometallic compound emitting yellow-green light may have a difference in an auxiliary ligand.

The auxiliary ligand in Formula 1 may be a phenyl-pyridine ligand or an acetylacetonate ligand. Namely, Formula 1 may be represented by Formula 1a or Formula 1b.

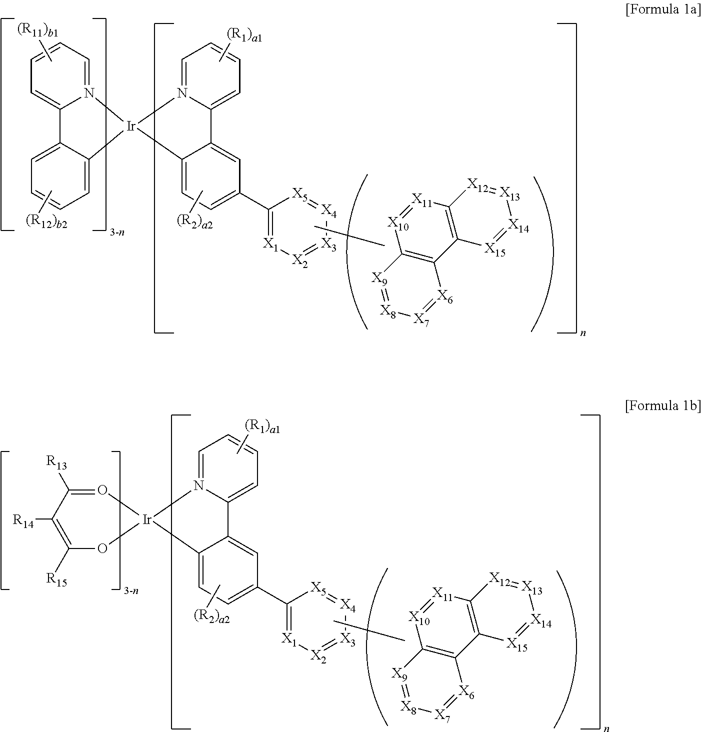

In Formula 1a,
each of b1 and b2 is independently an integer of 0 to 4, and
each of R₁₁ and R₁₂ is independently selected from the group consisting of deuterium, a substituted or unsubstituted C6 to C30 aryl group and a substituted or unsubstituted C3 to C30 heteroaryl group, or optionally, adjacent two R₁₁ and/or adjacent two R₁₂ are combined to form a ring.

In Formula 1b,
each of R₁₃, R₁₄ and R₁₅ is independently selected from the group consisting of hydrogen, deuterium, a substituted or unsubstituted C6 to C30 aryl group and a substituted or unsubstituted C3 to C30 heteroaryl group, or optionally, adjacent two of R₁₃, R₁₄ and R₁₅ are combined to each other to form a ring.

In each of Formulas 1a and 1b, definitions of a1, a2, n, X₁ to X₁₅, and R₁ to R₅ are same as those in Formula 1.

In an aspect of the present disclosure, the ring formed by adjacent two R₁₁, adjacent two R₁₂, adjacent two R₁₃ and/or adjacent two of R₁₃, R₁₄ and R₁₅ may be a substituted or unsubstituted C4 to C30 alicyclic ring, a substituted or unsubstituted C3 to C20 hetero-alicyclic ring, a substituted or unsubstituted C6 to C20 aromatic ring or a substituted or unsubstituted C3 to C20 heteroaromatic ring.

In an aspect of the present disclosure, the organometallic compound of the present disclosure may be represented by Formula 1a, b1 may be 0, and b2 may be 0 or 1. In an aspect of the present disclosure, R₁₂ may be a substituted or unsubstituted C6 to C30 aryl group, e.g., phenyl.

In each of Formulas 1, 1a and 1b, a linking position (e.g., a bonding site) of a ring including X₆ to X₁₅ may be specified. For example, Formula 1 may be represented by Formula 2-1.

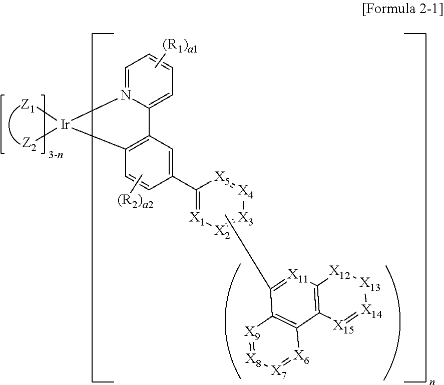

In Formula 2-1, the definitions of a1, a2, n, X₁ to X₉, X₁₁ to X₁₅, R₁ to R₅, Z₁ and Z₂ are same as those in Formula 1.

In each of Formulas 1, 1a and 1b, a linking position (e.g., a bonding site) of a ring including X₁ to X₅ and a linking position of a ring including X₆ to X₁₅ may be specified. For example, Formula 1 may be represented by Formula 2-2.

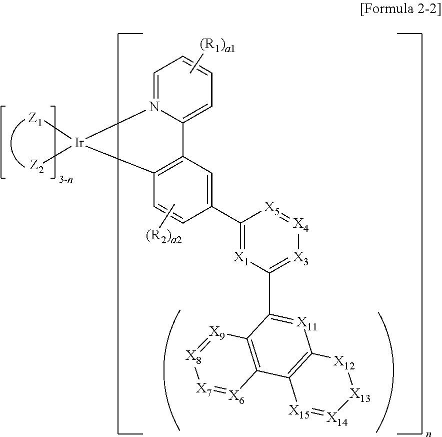

In Formula 2-2, the definitions of a1, a2, n, X₁, X₃ to X₉, X₁₁ to X₁₅, R₁ to R₅, Z₁ and Z₂ are same as those in Formula 1.

In Formula 2-2, one of X₆ to X₉, X₁₁ to X₁₅ may be N, and the rest of X₆ to X₉, X₁₁ to X₁₅ may be CR₅. In this case, one of R₅ may be a substituted or unsubstituted C1 to C20 alkyl group, e.g., methyl, and the rest of R₅ may be hydrogen.

In Formula 2-2, X₉ may be N, and X₆ to X₈, X₁₁ to X₁₅ may be CR₅. In this case, R₅ of X₁₂ may be a substituted or unsubstituted C1 to C20 alkyl group, e.g., methyl, and R₅ of X₆ to X₈, X₁₁, X₁₃ to X₁₅ may be hydrogen.

In Formula 2-2, X₁, X₃ to X₅ may be CR₄. In this case, one of R₄ may be a substituted or unsubstituted C1 to C20 alkyl group, e.g., methyl or tert-butyl, and the rest of R₄ may be hydrogen.

For example, the organometallic compound of Formula 1 may be one of compounds in Formula 3.

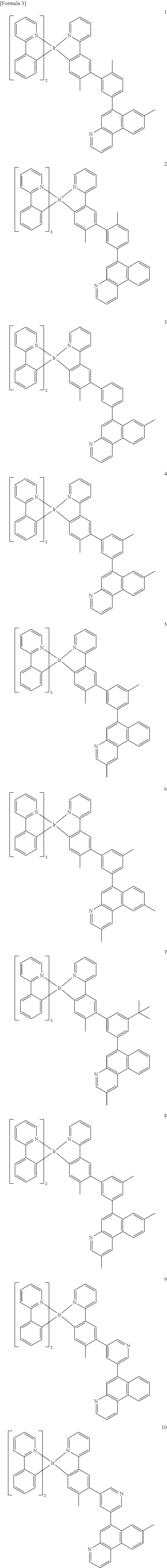

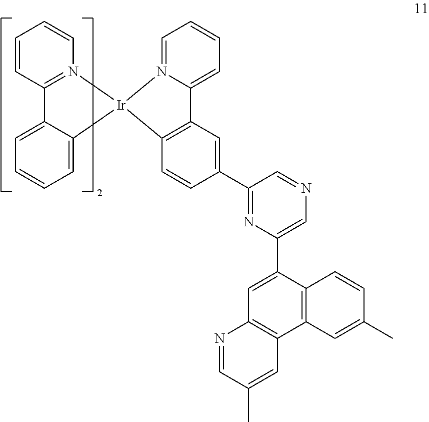

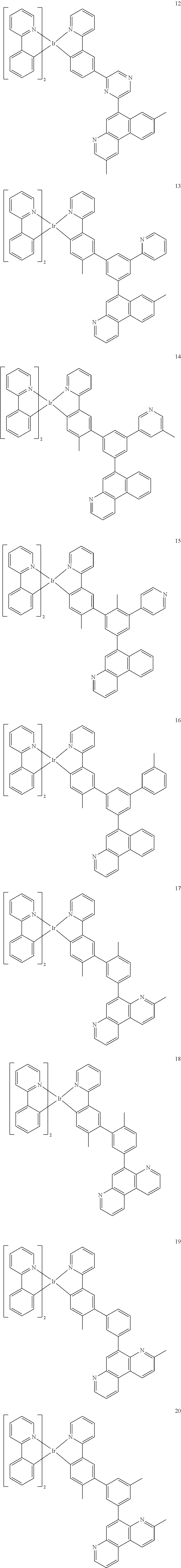

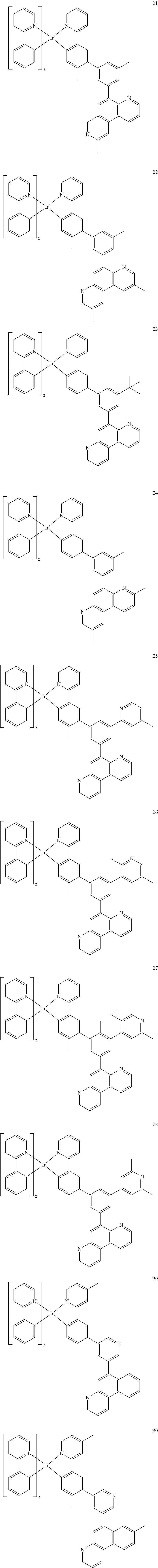

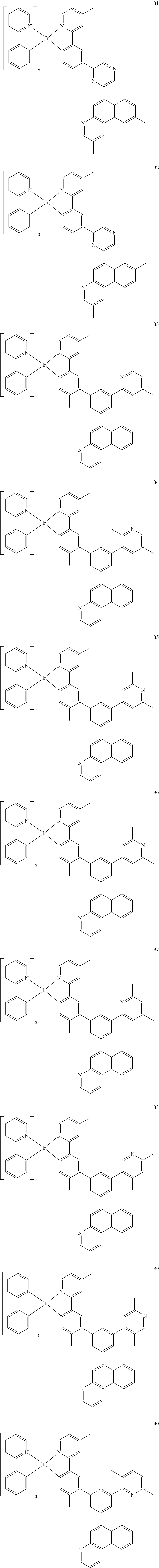

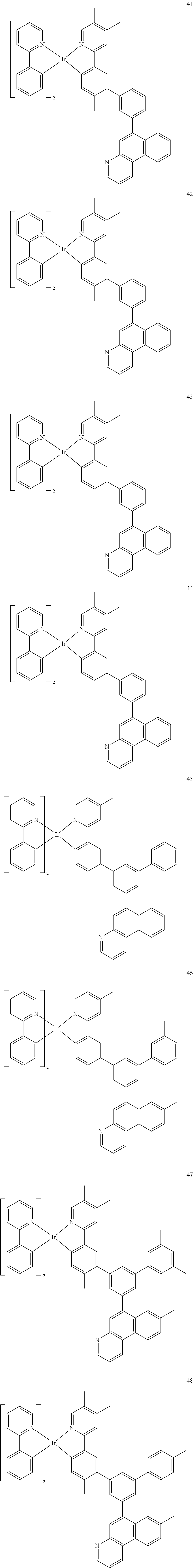

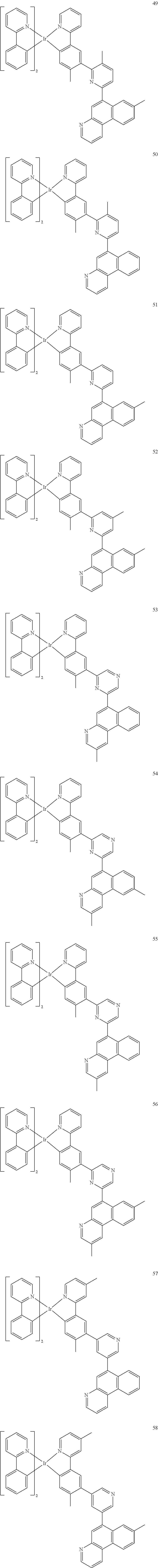

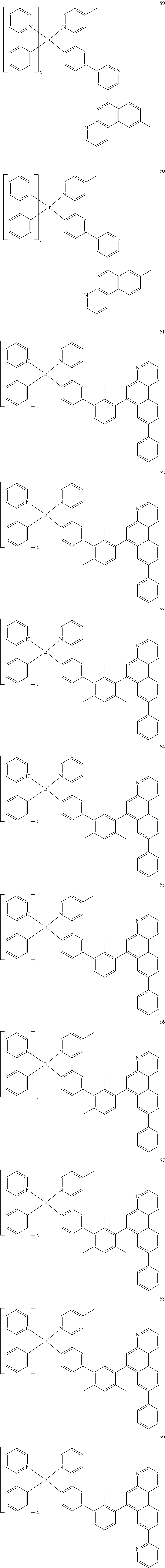

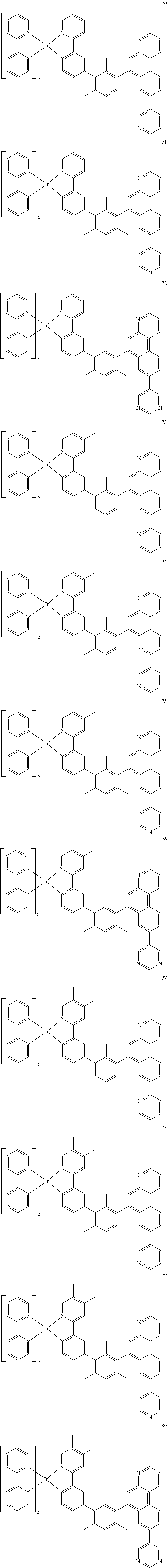

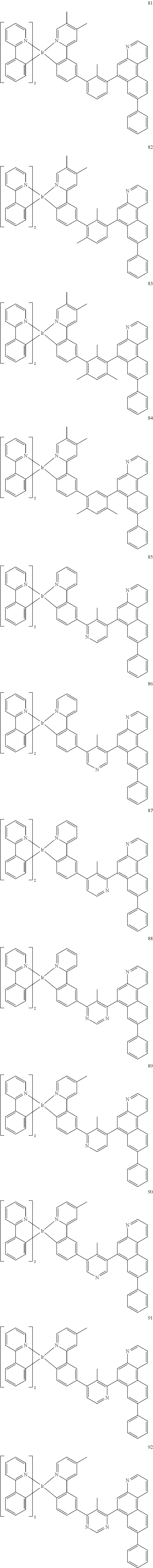

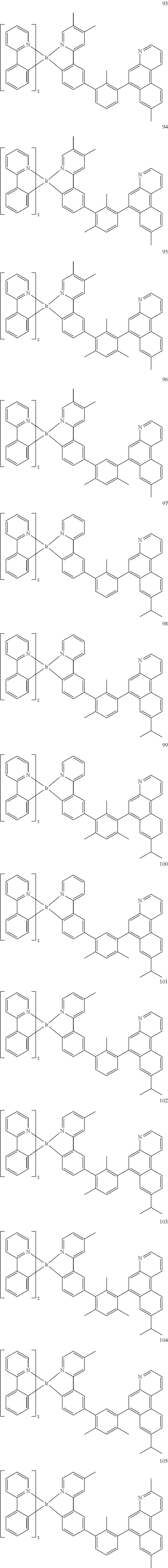

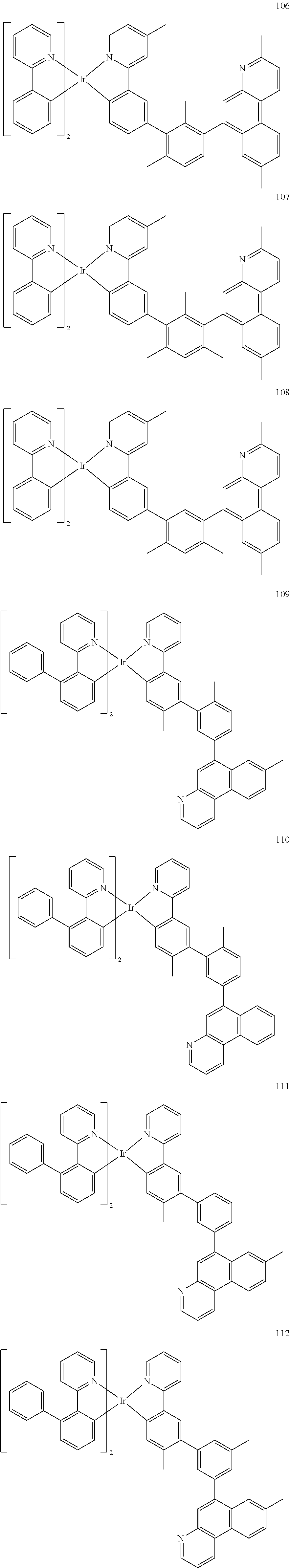

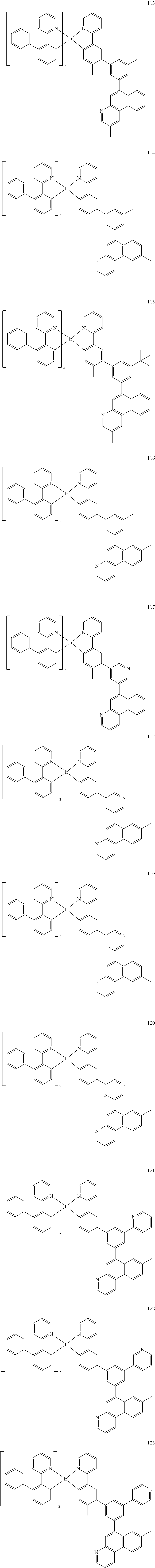

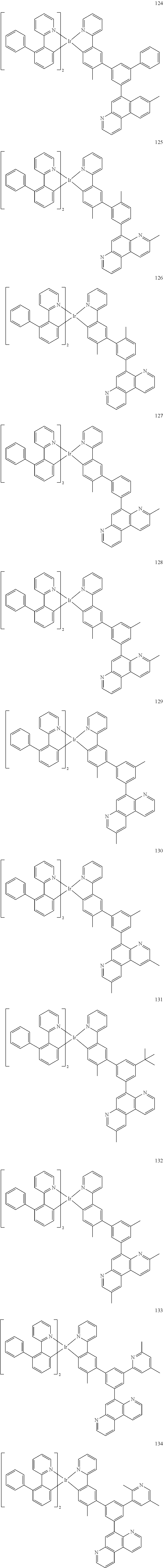

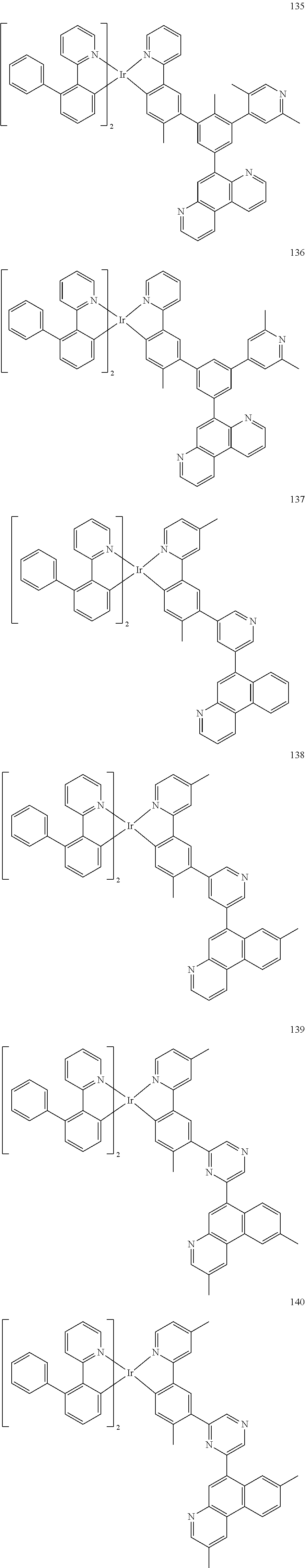

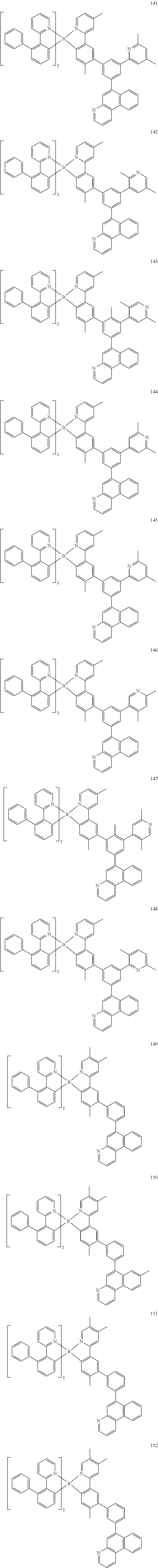

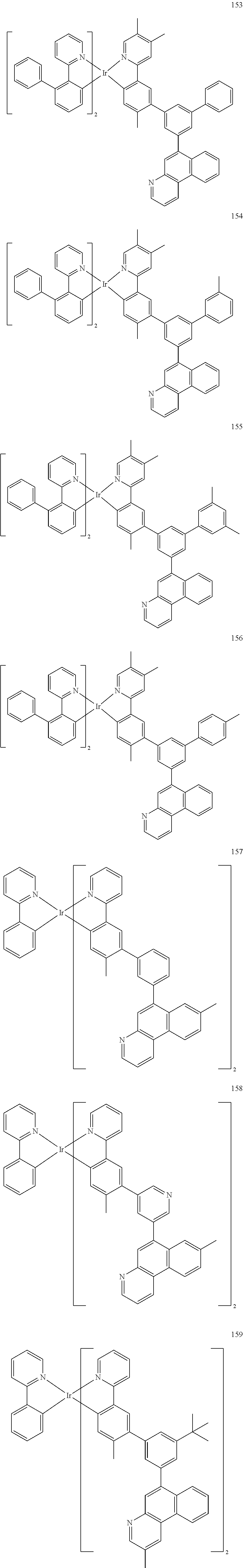

The organometallic compound of the present disclosure which is represented by one of Formulas 1, 1a, 1b, 2-1 and 2-2 and is selected from the compounds in Formula 3, emits light of green to red and is included in an emitting material layer of the OLED. As a result, the emitting efficiency and the lifespan of the OLED are improved.

### [Synthesis]

### 1. Synthesis of the Compound A

### (1) Compound A-3

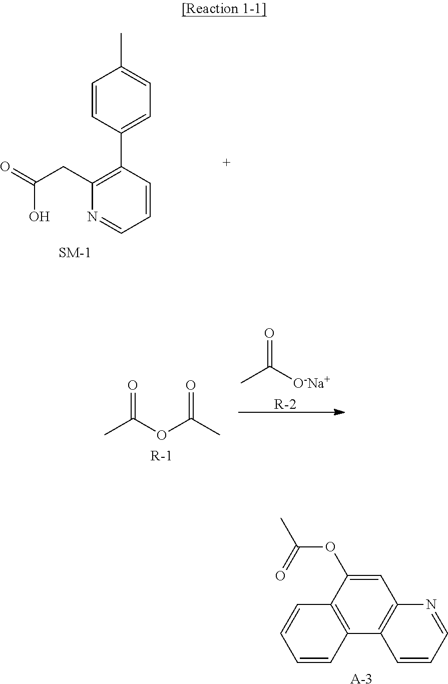

In a rounded-bottom flask (250 mL) under a nitrogen condition, the compound SM-1 (10 g, 4.4 mmol), the compound R-1 (0.45 g, 20 mmol) and the compound R-2 (36 g, 4.4 mmol) were heated, refluxed, and stirred for 6 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound A-3 (9.84 g, 89%).

### (2) Compound A-2

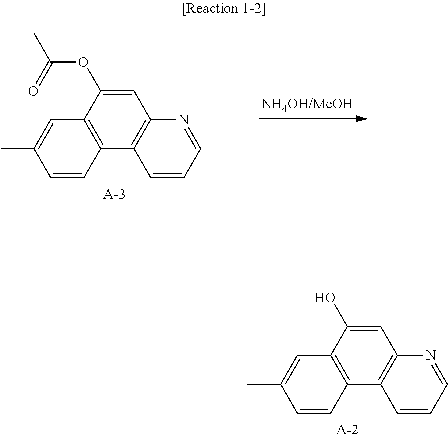

In a rounded-bottom flask (250 mL) under a nitrogen condition, the compound A-3 (4.18 g, 20 mmol) was dissolved in NH₄OH/MeOH, and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound A-2 (3.31 g, 95%).

### (3) Compound A

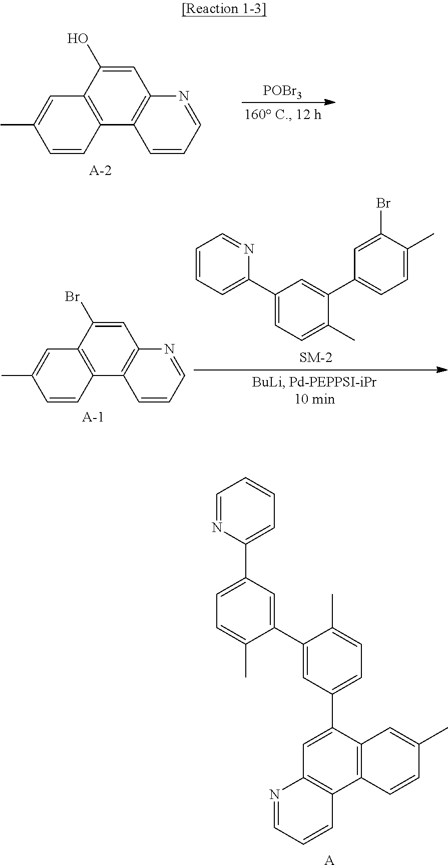

In a rounded-bottom flask (250 mL) under a nitrogen condition, the compound A-2 (4.18 g 20 mmol) was dissolved in POBr₃ (5.73 g 20 mmol), and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound A-1 (4.93 g, 91%). In a rounded-bottom flask (250 mL) under a nitrogen condition, the compound A-1 (4.93 g, 18 mmol), the compound SM-2 (6.15 g, 18 mmol), BuLi, and Pd-PEPPSi-iPr ([1,3-bis(2,6-diisopropylphenyl)imidazol-2-ylidene](3-chloropyridyl)palladium(II) dichloride) were stirred for 10 minutes. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound A (1.43 g, 85%).

### 2. Synthesis of the Compound B

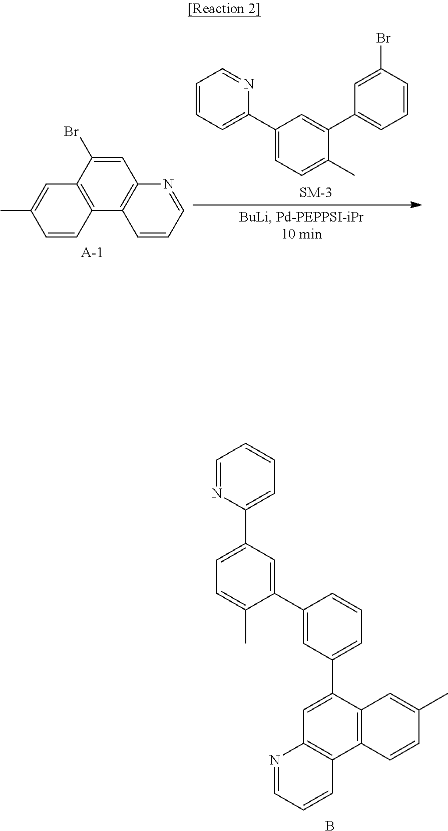

In a rounded-bottom flask (250 mL) under a nitrogen condition, the compound A-1 (5.44 g, 20 mmol), the compound SM-3 (1.76 g, 20 mmol), BuLi, and Pd-PEPPSi-iPr were stirred for 10 minutes. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound B (7.16 g, 82%).

### 3. Synthesis of the Compound C

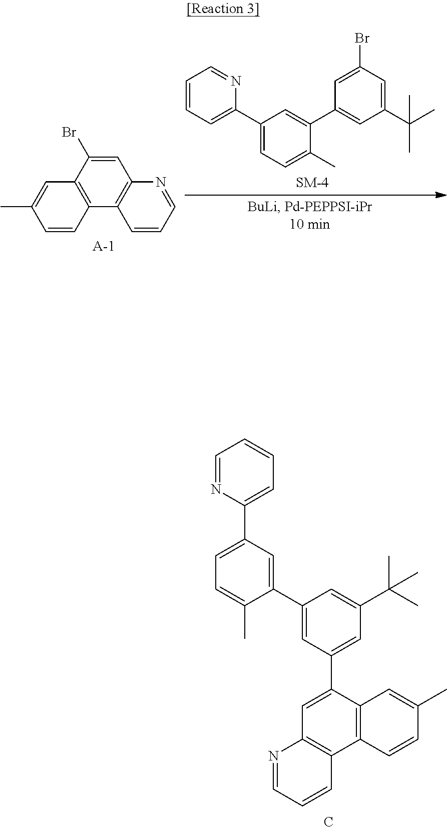

In a rounded-bottom flask (250 mL) under a nitrogen condition, the compound A-1 (5.44 g, 20 mmol), the compound SM-4 (7.61 g, 20 mmol), BuLi, and Pd-PEPPSi-iPr were stirred for 10 minutes. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound C (8.47 g, 86%).

### 4. Synthesis of the Compound D

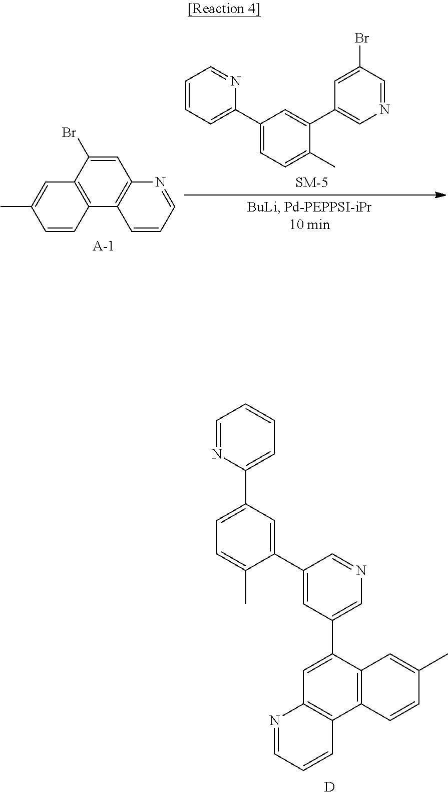

In a rounded-bottom flask (250 mL) under a nitrogen condition, the compound A-1 (6.80 g, 25 mmol), the compound SM-5 (8.13 g, 25 mmol), BuLi, and Pd-PEPPSi-iPr were stirred for 10 minutes. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound D (10.9 g, 88%).

### 5. Synthesis of the Compound E

### (1) Compound E-1

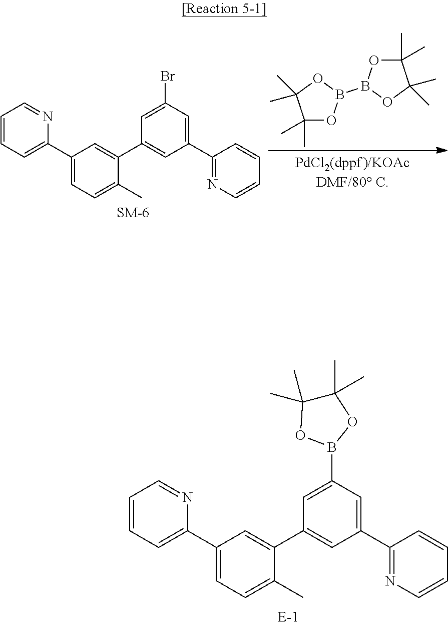

In a rounded-bottom flask (250 mL) under a nitrogen condition, the compound SM-6 (8.03 g, 20 mmol), the compound R-3 (5.08 g, 20 mmol), PdCl₂(dppf) (2.31 g, 2 mmol), 2M KOAc, and DMF (dimethylformamide) were stirred for 12 hours at 80′° C. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound E-1 (8.43 g, 94%).

### (2) Compound E

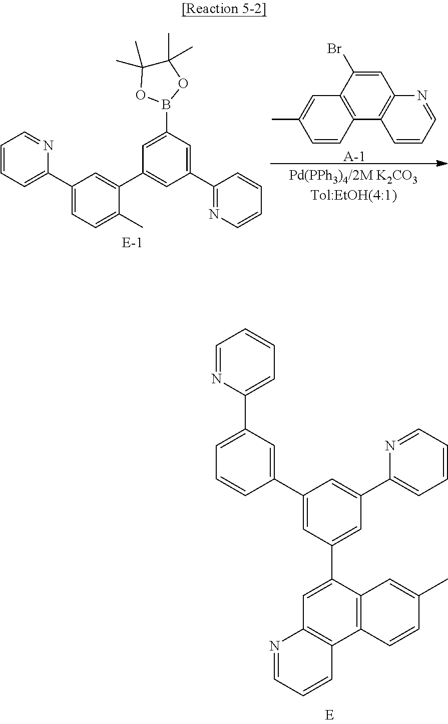

In a rounded-bottom flask (250 mL) under a nitrogen condition, the compound E-1 (4.48 g, 10 mmol), the compound A-1 (2.72 g, 10 mmol), Pd(PPh₃)₄ (2.31 g, 2 mmol), and 2M K₂CO₃ were dissolved in a mixed solution of toluene and ethanol (=4:1 (volume ratio)), and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound E (4.59 g, 92%).

### 6. Synthesis of the Compound F

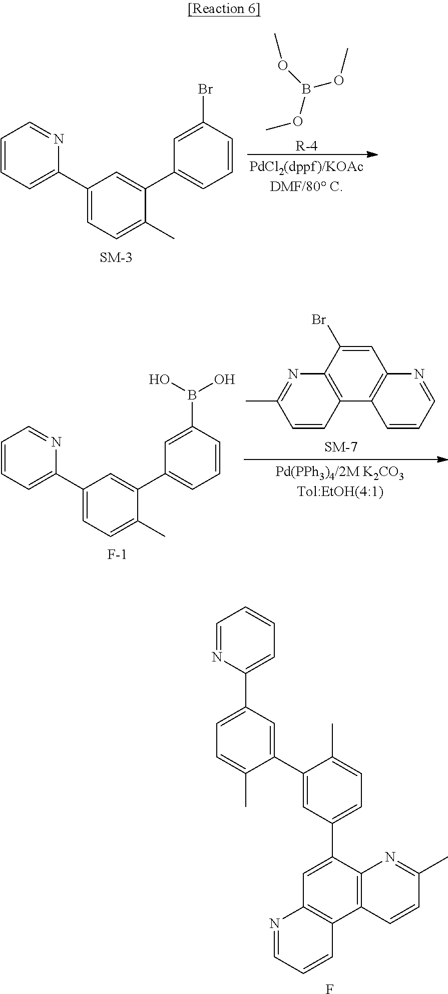

In a rounded-bottom flask (250 mL) under a nitrogen condition, the compound SM-3(6.48 g 20 mmol), the compound R-4 (2.08 g, 20 mmol), PdCl₂(dppf) (2.31 g, 2 mmol), 2M KOAc were dissolved in DMF, and the mixture was stirred for 12 hours at 80′° C. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound F-1 (5.55 g, 96%).

In a rounded-bottom flask (250 mL) under a nitrogen condition, the compound F-1(4.34 g, 15 mmol), the compound SM-7 (4.10 g, 15 mmol), Pd(PPh₃)₄(1.12 g, 1 mmol), and 2M K₂CO₃ were dissolved in a mixed solution of toluene and ethanol (=4:1 (volume ratio)), and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound F (5.90 g, 87%).

### 7. Synthesis of the Compound G

### (1) Compound G-1

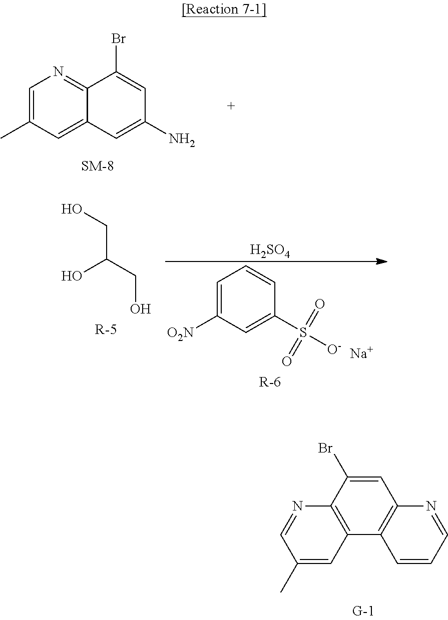

In a rounded-bottom flask (250 mL) under a nitrogen condition, the compound SM-8 (7.11 g, 30 mmol), the compound R-5 (2.76 g, 30 mmol), H₂SO₄ (1.5 mL), and the compound R-6 (6.75 g, 30 mmol) were heated, refluxed, and stirred for 6 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound G-1 (5.57 g, 68%).

### (2) Compound G

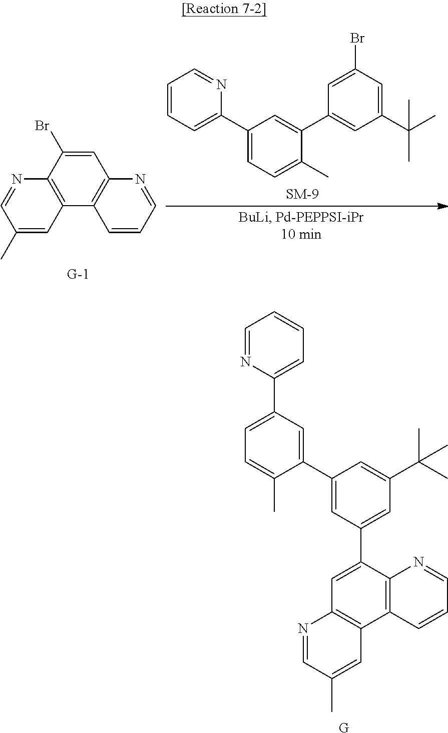

In a rounded-bottom flask (250 mL) under a nitrogen condition, the compound G-1(5.46 g, 20 mmol), the compound SM-9 (7.61 g, 20 mmol), BuLi, and Pd-PEPPSi-iPr were stirred for 10 minutes. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound G (8.69 g, 88%).

### 8. Synthesis of the Compound H

### (1) Compound H-1

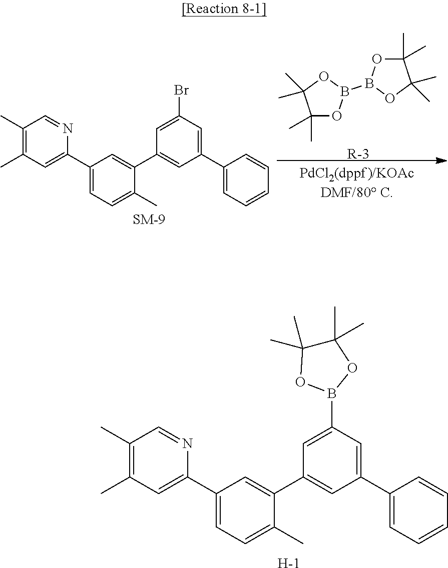

In a rounded-bottom flask (250 mL) under a nitrogen condition, the compound SM-9 (8.57 g, 20 mmol), the compound R-3 (5.08 g, 20 mmol), PdCl₂(dppf) (2.31 g, 2 mmol), 2M KOAc, and DMF(dimethylformamide) were stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound H-1 (8.18 g, 86%).

### (2) Compound H

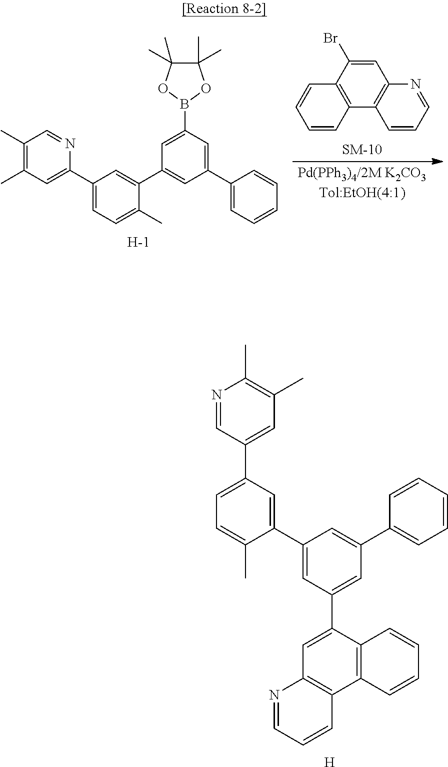

In a rounded-bottom flask (250 mL) under a nitrogen condition, the compound H-1 (7.13 g, 15 mmol), the compound SM-10 (3.87 g, 15 mmol), Pd(PPh₃)₄(2.31 g, 2 mmol), and 2M K₂CO₃ were dissolved in a mixed solution of toluene and ethanol (=4:1 (volume ratio)), and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound H (6.72 g, 85%).

### 9. Synthesis of the Compound I

### (1) Compound I-1

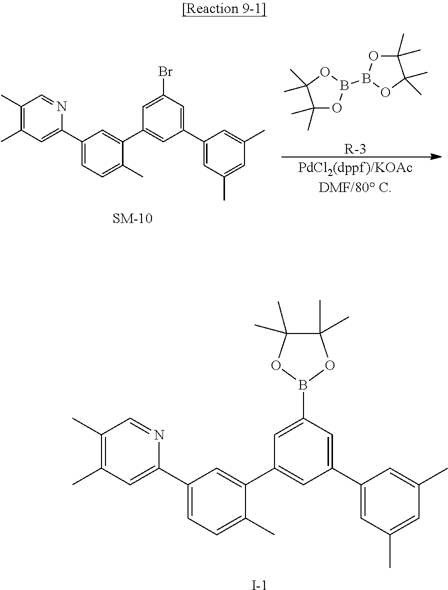

In a rounded-bottom flask (250 mL) under a nitrogen condition, the compound SM-10 (9.13 g, 20 mmol), the compound R-3 (7.61 g, 20 mmol), PdCl₂(dppf) (2.31 g, 2 mmol), 2M KOAc, and DMF(dimethylformamide) were stirred for 12 hours at 80′° C. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound I-1 (8.76 g, 88%).

### (2) Compound I

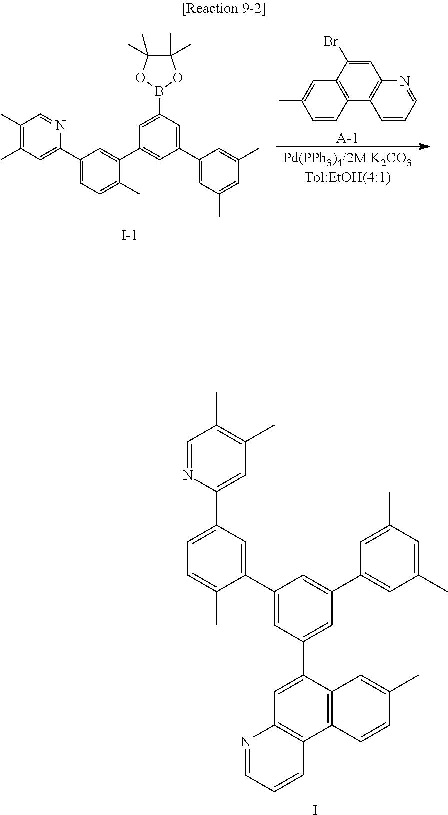

In a rounded-bottom flask (250 mL) under a nitrogen condition, the compound I-1 (5.03 g, 10 mmol), the compound A-1(2.58 g, 10 mmol), Pd(PPh₃)₄(1.25 g, 1 mmol), and 2M K₂CO₃ were dissolved in a mixed solution of toluene and ethanol (=4:1 (volume ratio)), and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound I (4.72 g, 83%).

### 10. Synthesis of the Compound J

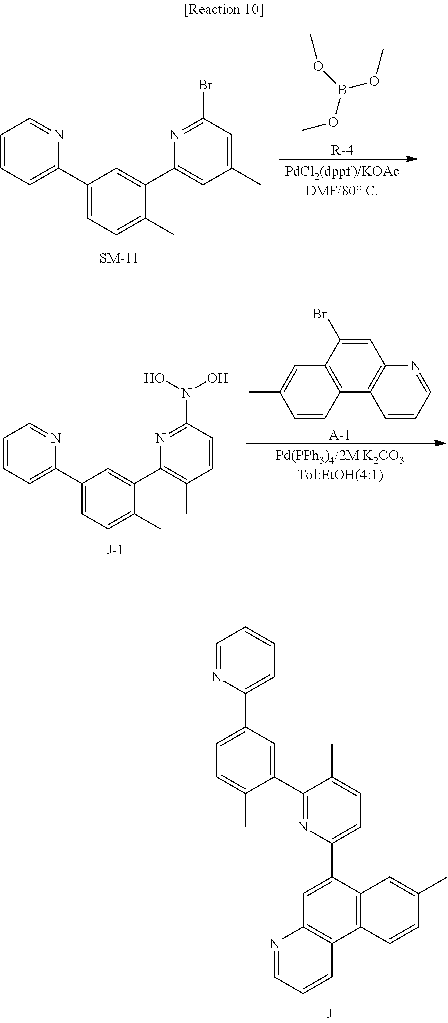

In a rounded-bottom flask (250 mL) under a nitrogen condition, the compound SM-11 (6.78 g, 20 mmol), the compound R-4 (2.08 g, 20 mmol), PdCl₂(dppf) (2.31 g, 2 mmol), 2M KOAc were dissolved in DMF, and the mixture was stirred for 12 hours at 80° C. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound J-1 (5.54 g, 91%).

In a rounded-bottom flask (250 mL) under a nitrogen condition, the compound J-1 (4.56 g, 15 mmol), the compound A-1 (4.09 g, 15 mmol), Pd(PPh₃)₄(2.31 g, 2 mmol), and 2M K₂CO₃ were dissolved in a mixed solution of toluene and ethanol (=4:1 (volume ratio)), and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound J (5.55 g, 82%).

### 11. Synthesis of the Compound K

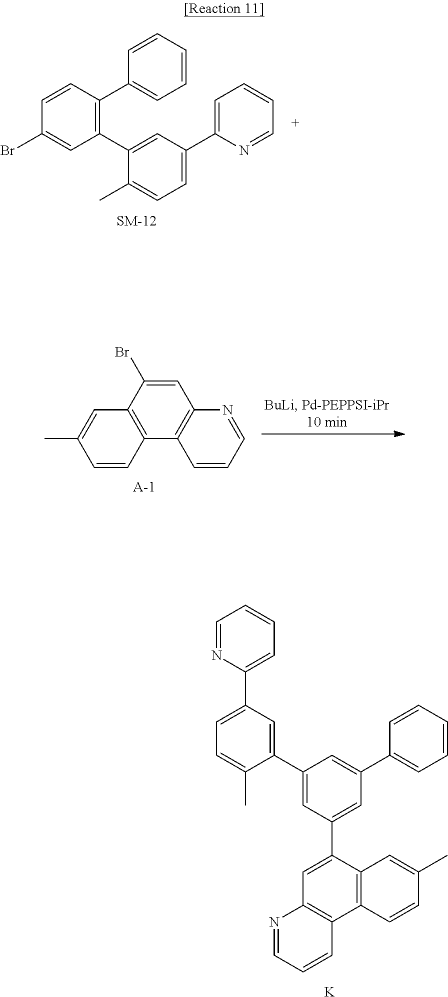

In a rounded-bottom flask (250 mL) under a nitrogen condition, the compound SM-12 (6.00 g, 15 mmol), the compound A-1 (4.08 g, 15 mmol), BuLi, and Pd-PEPPSi-iPr were stirred for 10 minutes. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound K (6.31 g, 82%).

### 12. Synthesis of the Compound L

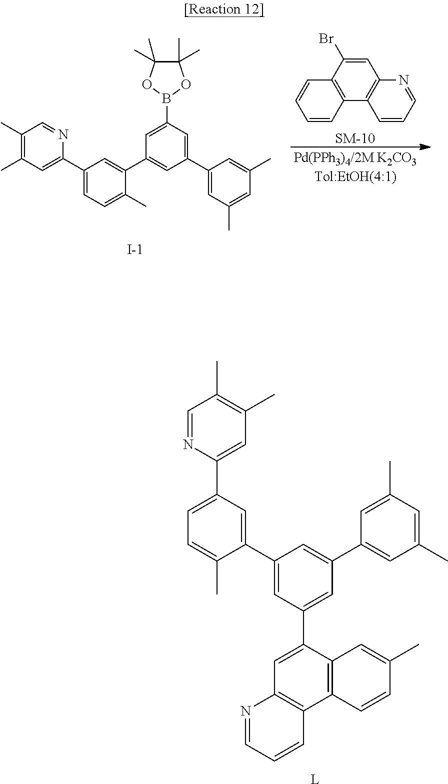

In a rounded-bottom flask (250 mL) under a nitrogen condition, the compound I-1 (10.07 g, 20 mmol), the compound SM-10 (5.16 g, 20 mmol), Pd(PPh₃)₄ (2.31 g, 2 mmol), and 2M K₂CO₃ were dissolved in a mixed solution of toluene and ethanol (=4:1 (volume ratio)), and the mixture was heated, refluxed, and stirred for 12 hours. After completion of the reaction, the temperature was lowered to room temperature, and the organic layer was extracted with dichloromethane and sufficiently washed with water. Water was removed with anhydrous magnesium sulfate, and the filtered solution was concentrated under reduced pressure. The mixture was separated by column chromatography using ethyl acetate and hexane to obtain the compound L (9.32 g, 84%).

### 13. Synthesis of the Compound M

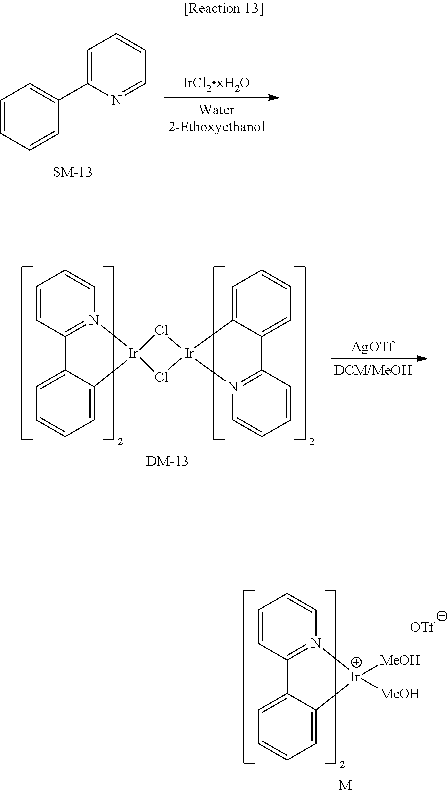

In a rounded-bottom flask (250 mL) under a nitrogen condition, the compound SM-13 (3.10 g, 20 mmol), IrCl₃ (2.39 g, 8.0 mmol) and a mixed solution of 2-ethoxyethanol and distilled water (=90 mL:30 mL) were refluxed and stirred for 24 hours. After completion of the reaction, the temperature was lowered to room temperature, and the obtained solid was separated under reduced pressure. The filtered solid was sufficiently washed with water and cool methanol and filtered under reduced pressure several times to obtain the solid compound DM-13 (12.98 g, 85%).

In a rounded-bottom flask (250 mL), the compound DM-13 (3.05 g, 4 mmol) and silver trifluoromethanesulfonate (AgOTf, 3.08 g, 12 mmol) were dissolved in a mixed solution of dichloromethane and methanol, and the mixture was stirred at room temperature for 24 hours. After completion of the reaction, the solid precipitate was removed by filtering with celite. The filtered solution was distilled under reduced pressure to obtain the compound M (1.74 g, 88%).

### 14. Synthesis of the Compound N

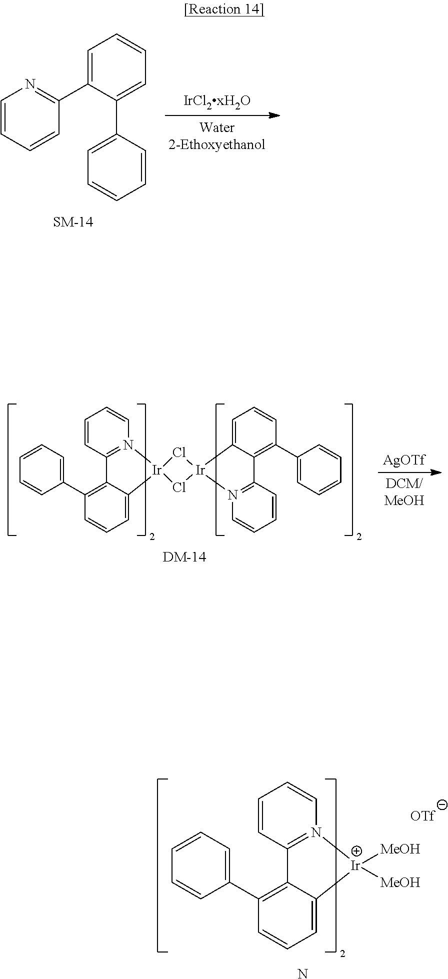

In a rounded-bottom flask (250 mL) under a nitrogen condition, the compound SM-14 (4.62 g, 20 mmol), IrCl₃ (3.56 g, 8.0 mmol) and a mixed solution of 2-ethoxyethanol and distilled water (=90 mL:30 mL) were refluxed and stirred for 24 hours. After completion of the reaction, the temperature was lowered to room temperature, and the obtained solid was separated under reduced pressure. The filtered solid was sufficiently washed with water and cool methanol and filtered under reduced pressure several times to obtain the solid compound DM-14 (19.34 g, 85%).

In a rounded-bottom flask (250 mL), the compound DM-14 (4.54 g, 4 mmol) and silver trifluoromethanesulfonate (AgOTf, 4.59 g, 12 mmol) were dissolved in a mixed solution of dichloromethane and methanol, and the mixture was stirred at room temperature for 24 hours. After completion of the reaction, the solid precipitate was removed by filtering with celite. The filtered solution was distilled under reduced pressure to obtain the compound N (2.59 g, 88%).

### 15. Synthesis of the Compound O

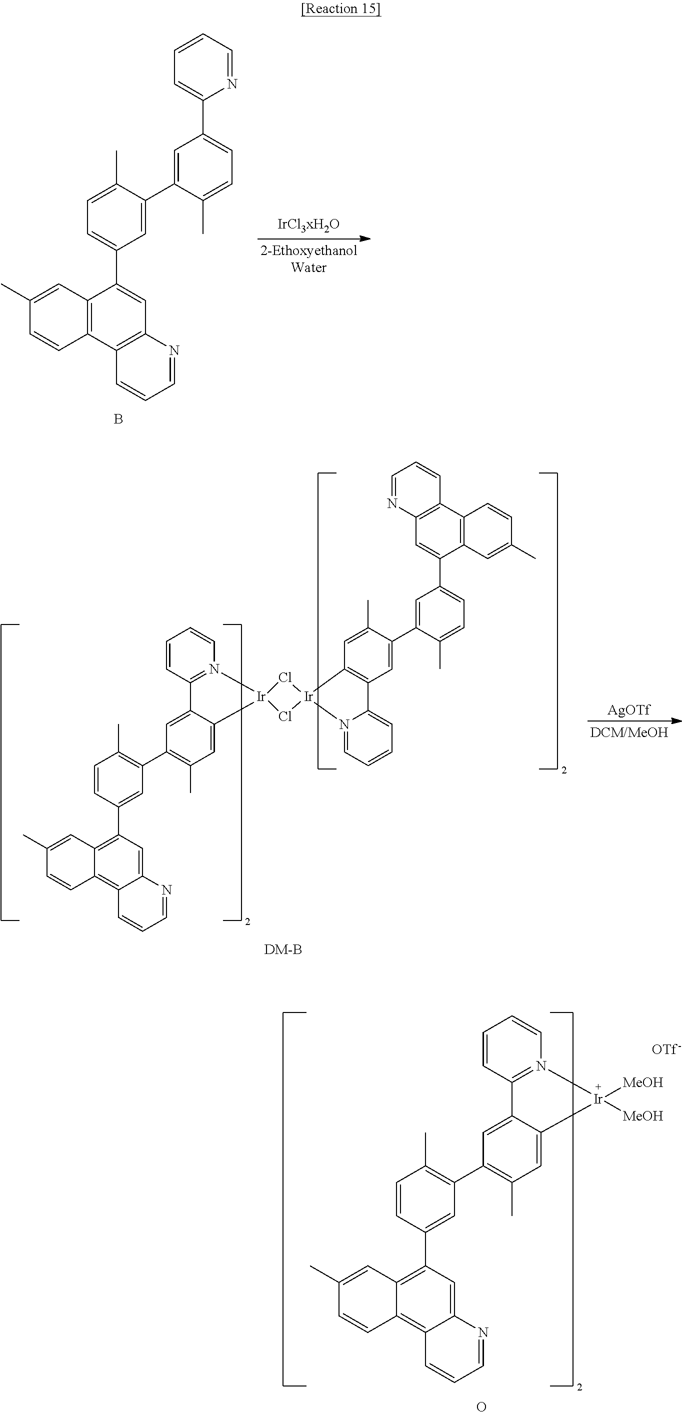

In a rounded-bottom flask (250 mL) under a nitrogen condition, the compound B (9.01 g 20 mmol), IrCl₃ (6.93 g, 8.0 mmol) and a mixed solution of 2-ethoxyethanol and distilled water (=90 mL:30 mL) were refluxed and stirred for 24 hours. After completion of the reaction, the temperature was lowered to room temperature, and the obtained solid was separated under reduced pressure. The filtered solid was sufficiently washed with water and cool methanol and filtered under reduced pressure several times to obtain the solid compound DM-B. In a rounded-bottom flask (250 mL), the compound DM-B (8.93 g, 4 mmol) and silver trifluoromethanesulfonate (AgOTf, 6.84 g, 12 mmol) were dissolved in a mixed solution of dichloromethane and methanol, and the mixture was stirred at room temperature for 24 hours. After completion of the reaction, the solid precipitate was removed by filtering with celite. The filtered solution was distilled under reduced pressure to obtain the compound O (5.05 g, 89%).

### 16. Synthesis of the Compound P

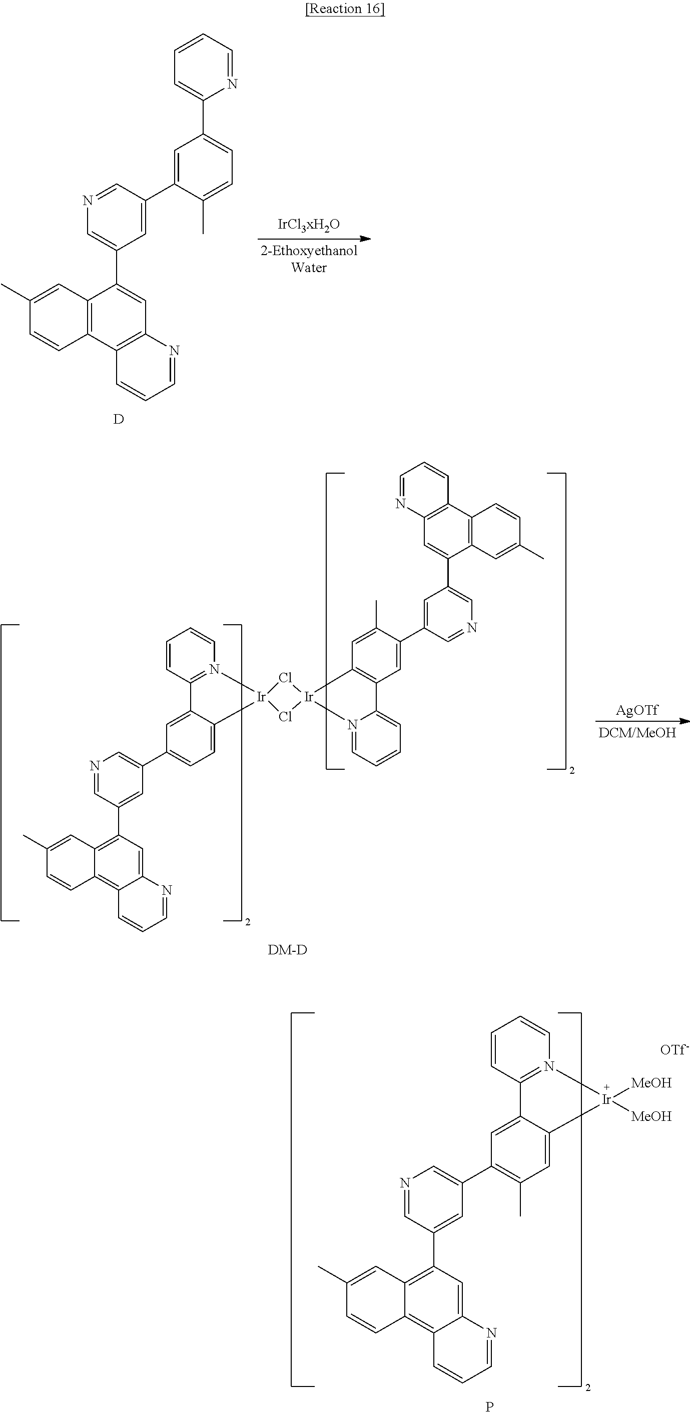

In a rounded-bottom flask (250 mL) under a nitrogen condition, the compound D (8.75 g, 20 mmol), IrCl₃ (6.74 g, 8.0 mmol) and a mixed solution of 2-ethoxyethanol and distilled water (=90 mL:30 mL) were refluxed and stirred for 24 hours. After completion of the reaction, the temperature was lowered to room temperature, and the obtained solid was separated under reduced pressure. The filtered solid was sufficiently washed with water and cool methanol and filtered under reduced pressure several times to obtain the solid compound DM-D. In a rounded-bottom flask (250 mL), the compound DM-D (8.60 g, 4 mmol) and silver trifluoromethanesulfonate (AgOTf, 6.84 g, 12 mmol) were dissolved in a mixed solution of dichloromethane and methanol, and the mixture was stirred at room temperature for 24 hours. After completion of the reaction, the solid precipitate was removed by filtering with celite. The filtered solution was distilled under reduced pressure to obtain the compound P (4.91 g, 89%).

### 17. Synthesis of the Compound Q

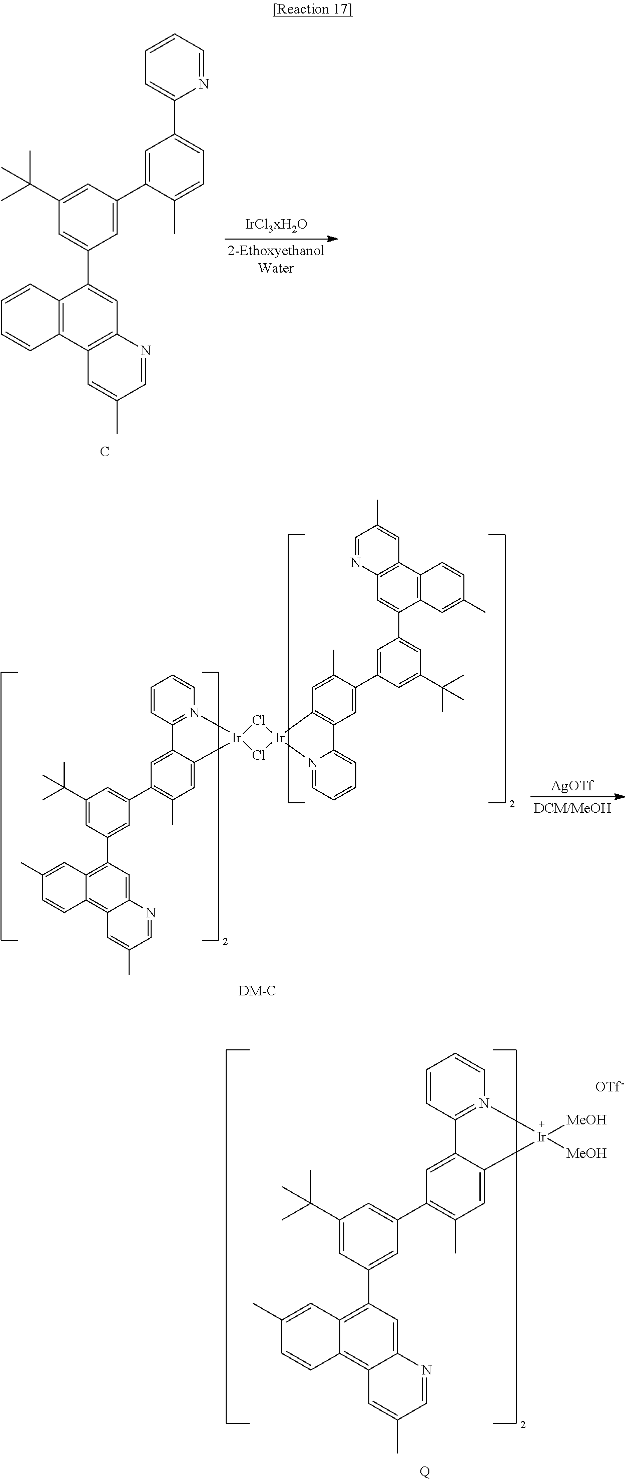

In a rounded-bottom flask (250 mL) under a nitrogen condition, the compound C (9.85 g, 20 mmol), IrCl₃ (7.60 g, 8.0 mmol) and a mixed solution of 2-ethoxyethanol and distilled water (=90 mL:30 mL) were refluxed and stirred for 24 hours. After completion of the reaction, the temperature was lowered to room temperature, and the obtained solid was separated under reduced pressure. The filtered solid was sufficiently washed with water and cool methanol and filtered under reduced pressure several times to obtain the solid compound DM-C. In a rounded-bottom flask (250 mL), the compound DM-C (9.70 g, 4 mmol) and silver trifluoromethanesulfonate (AgOTf, 6.84 g, 12 mmol) were dissolved in a mixed solution of dichloromethane and methanol, and the mixture was stirred at room temperature for 24 hours. After completion of the reaction, the solid precipitate was removed by filtering with celite. The filtered solution was distilled under reduced pressure to obtain the compound Q (5.53 g, 89%).

### 18. Synthesis of the Compound 1

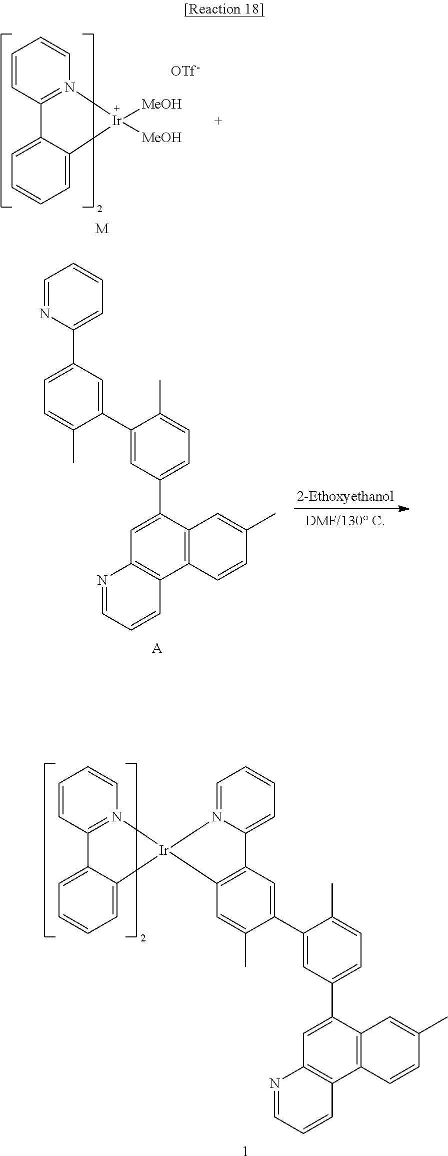

In a rounded-bottom flask (250 mL) under a nitrogen condition, the compound M (0.75 g 1.5 mmol) and the ligand A (1.35 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 1 (2.14 g, 75%).

### 19. Synthesis of the Compound 3

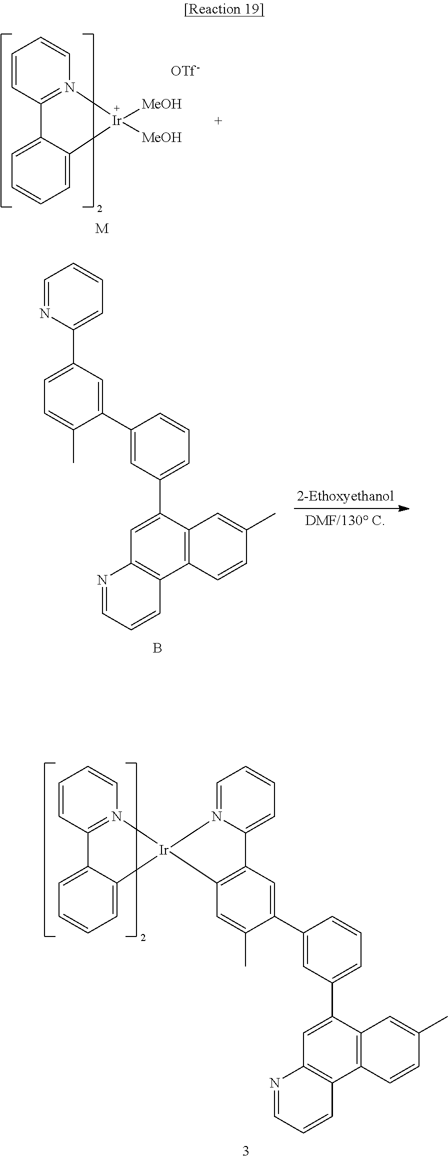

In a rounded-bottom flask (250 mL) under a nitrogen condition, the compound M (0.75 g, 1.5 mmol) and the ligand B (1.31 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 3 (2.05 g, 73%).

### 20. Synthesis of the Compound 7

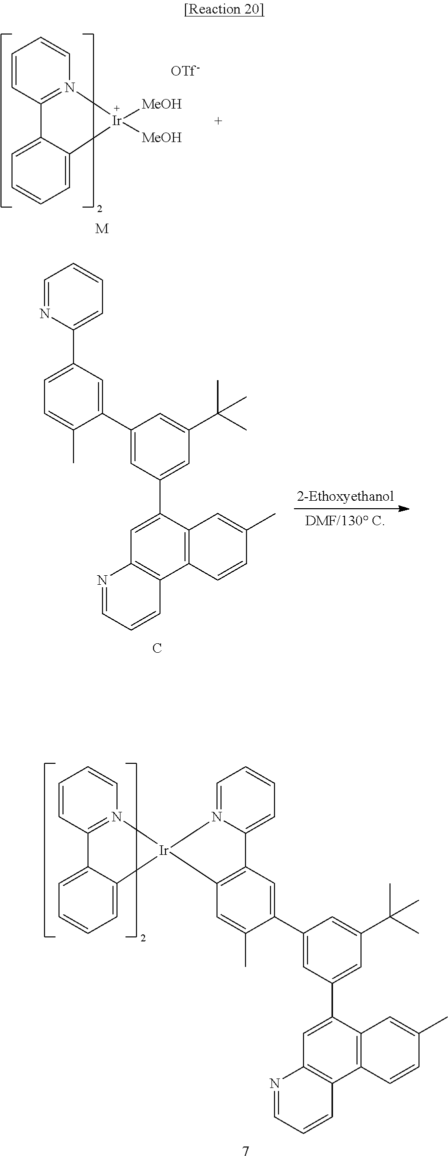

In a rounded-bottom flask (250 mL) under a nitrogen condition, the compound M (0.75 g, 1.5 mmol) and the ligand C (1.48 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 7 (2.26 g, 76%).

### 21. Synthesis of the Compound 10

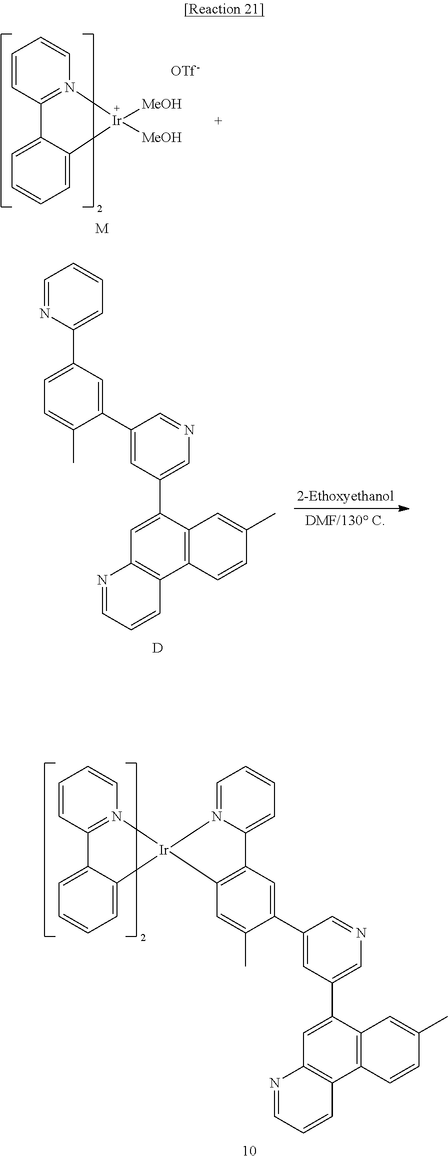

In a rounded-bottom flask (250 mL) under a nitrogen condition, the compound M (0.75 g, 1.5 mmol) and the ligand D (1.31 g, 3 mmol) were put into 2-ethoxyethanol (50 mL) and DMF (50 mL), and the mixture was heated, refluxed, and stirred for 24 hours at 130′C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 10 (2.00 g, 71%).

### 22. Synthesis of the Compound 13

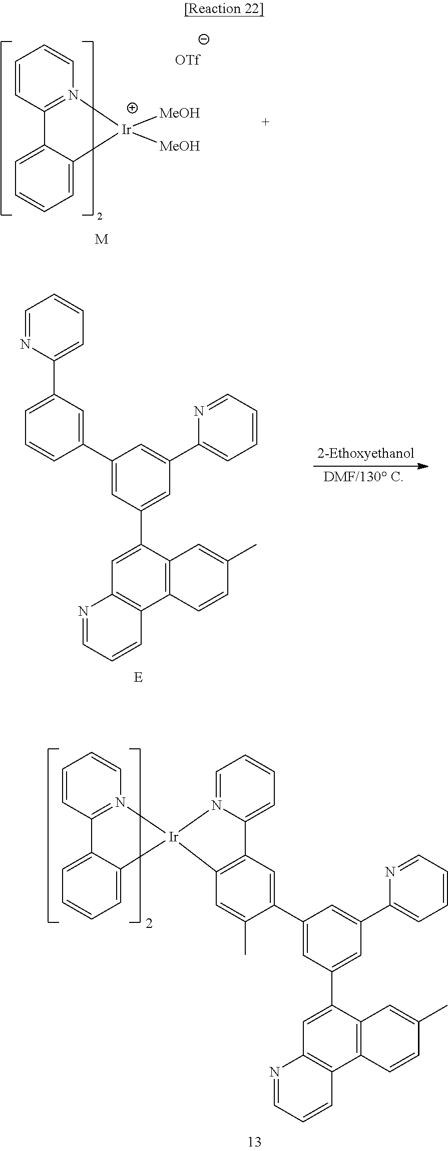

In a rounded-bottom flask (250 mL) under a nitrogen condition, the compound M (0.75 g 1.5 mmol) and the ligand E (1.50 g, 3 mmol) were put into 2-ethoxyethanol (50 mL) and DMF (50 mL), and the mixture was heated, refluxed, and stirred for 24 hours at 130° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 13 (2.55 g, 84%).

### 23. Synthesis of the Compound 17

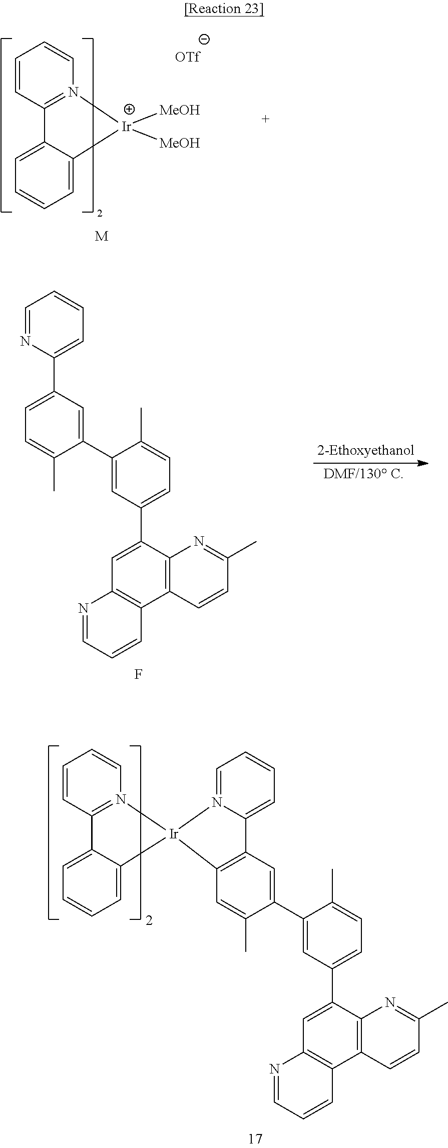

In a rounded-bottom flask (250 mL) under a nitrogen condition, the compound M (0.75 g, 1.5 mmol) and the ligand F (1.35 g, 3 mmol) were put into 2-ethoxyethanol (50 mL) and DMF (50 mL), and the mixture was heated, refluxed, and stirred for 24 hours at 130° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 17 (2.31 g, 81%).

### 24. Synthesis of the Compound 23

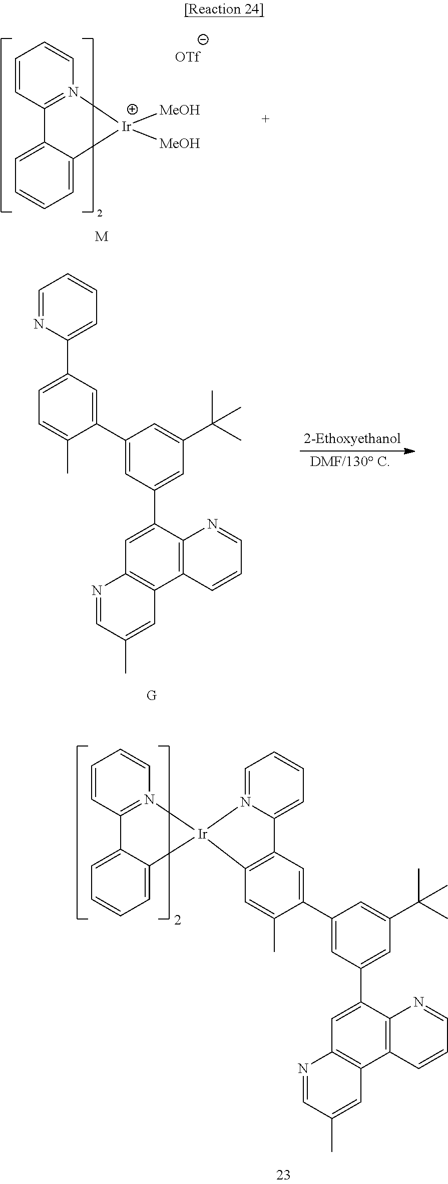

In a rounded-bottom flask (250 mL) under a nitrogen condition, the compound M (0.75 g 1.5 mmol) and the ligand G (1.48 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 23 (2.35 g, 79%).

### 25. Synthesis of the Compound 45

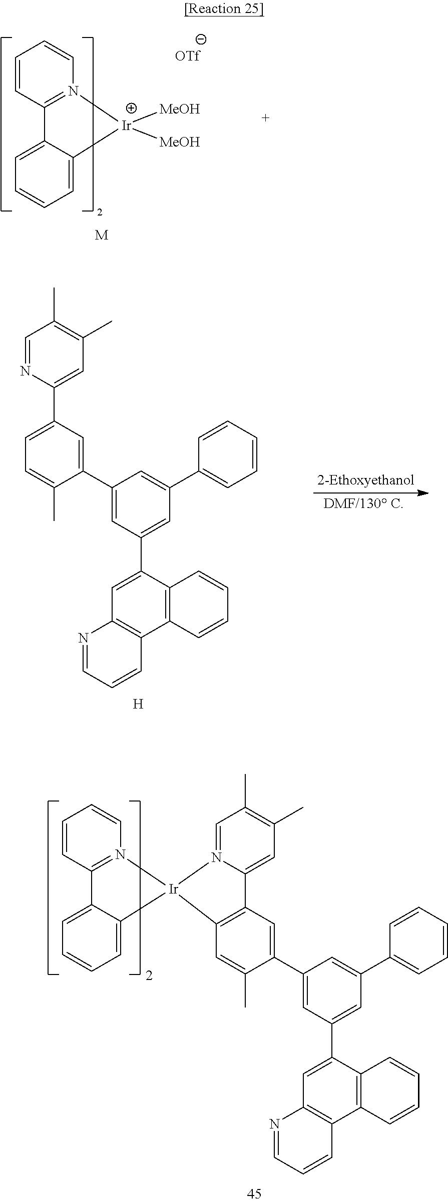

In a rounded-bottom flask (250 mL) under a nitrogen condition, the compound M (0.75 g 1.5 mmol) and the ligand H (1.58 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 45 (2.43 g, 79%).

### 26. Synthesis of the Compound 47

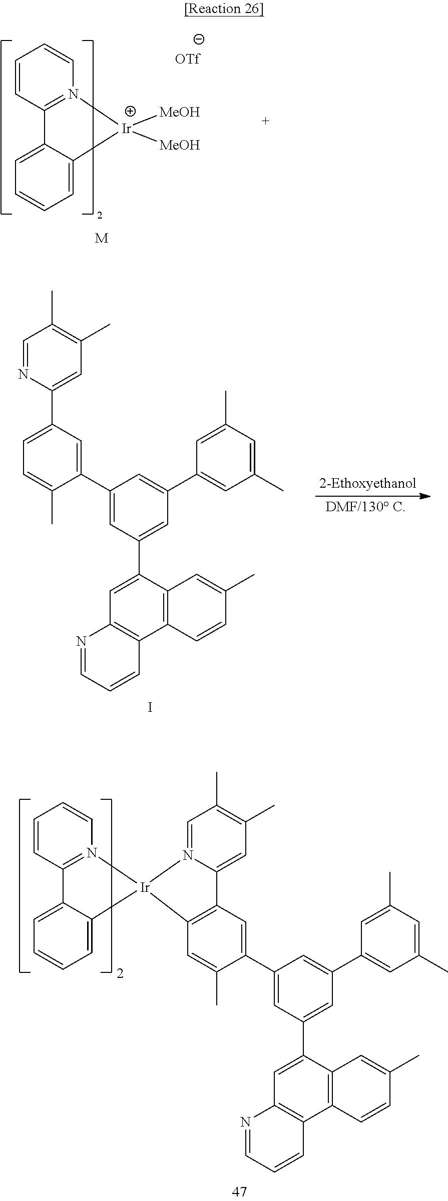

In a rounded-bottom flask (250 mL) under a nitrogen condition, the compound M (0.75 g, 1.5 mmol) and the ligand 1 (1.71 g, 3 mmol) were put into 2-ethoxyethanol (50 mL) and DMF (50 mL), and the mixture was heated, refluxed, and stirred for 24 hours at 130′C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 47 (2.34 g, 73%).

### 27. Synthesis of the Compound 49

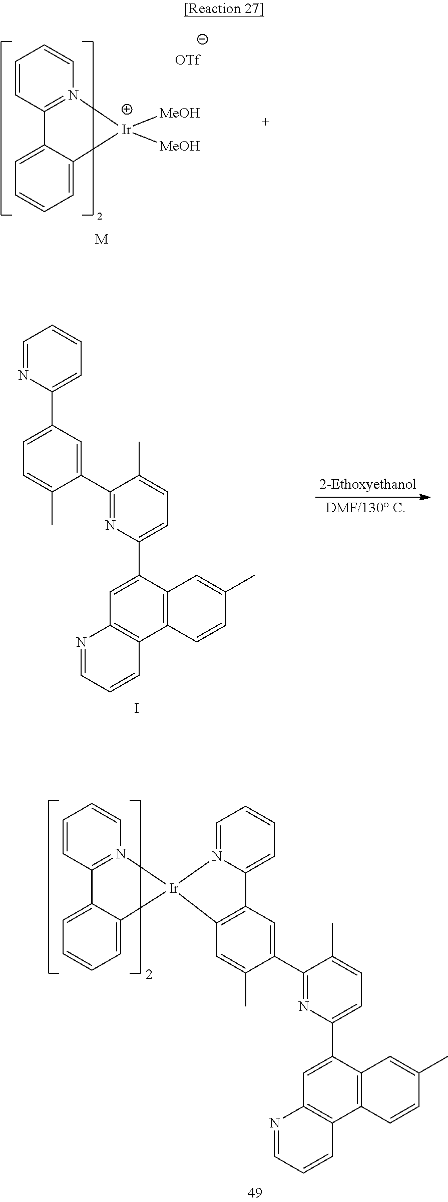

In a rounded-bottom flask (250 mL) under a nitrogen condition, the compound M (0.75 g 1.5 mmol) and the ligand J (1.35 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 49 (2.43 g, 85%).

### 28. Synthesis of the Compound 109

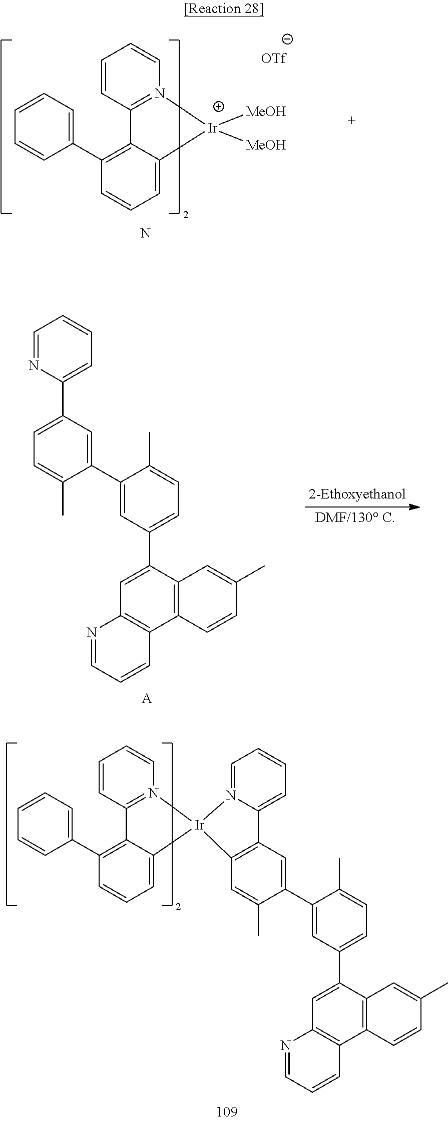

In a rounded-bottom flask (250 mL) under a nitrogen condition, the compound N (1.20 g, 1.5 mmol) and the ligand J (1.35 g, 3 mmol) were put into 2-ethoxyethanol (50 mL) and DMF (50 mL), and the mixture was heated, refluxed, and stirred for 24 hours at 130° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 109 (2.81 g, 85%).

### 29. Synthesis of the Compound 111

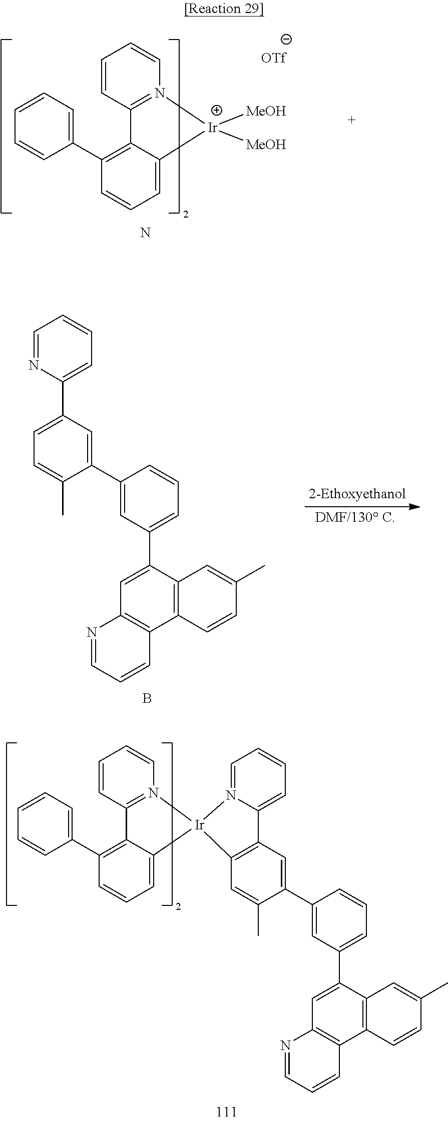

In a rounded-bottom flask (250 mL) under a nitrogen condition, the compound N (1.20 g, 1.5 mmol) and the ligand B (1.31 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 111 (2.58 g, 79%).

### 30. Synthesis of the Compound 121

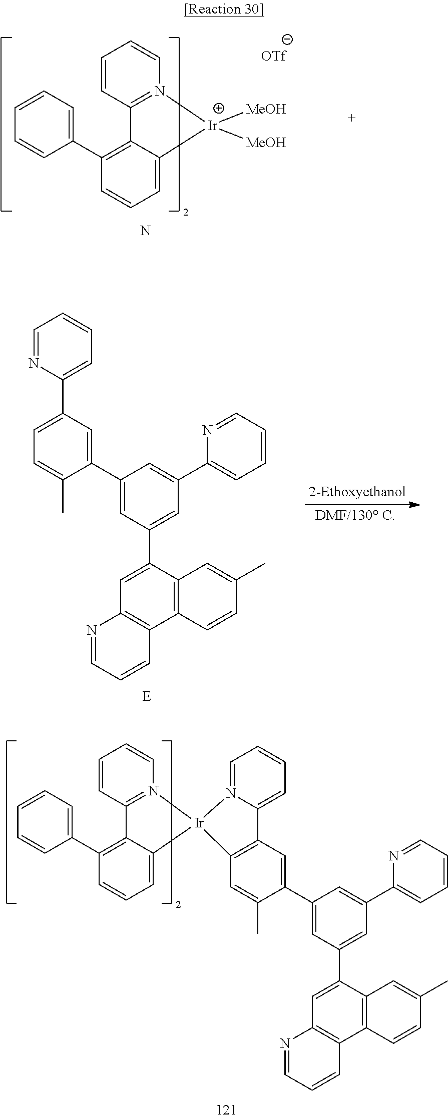

In a rounded-bottom flask (250 mL) under a nitrogen condition, the compound N (1.20 g, 1.5 mmol) and the ligand E (1.54 g, 3 mmol) were put into 2-ethoxyethanol (50 mL) and DMF (50 mL), and the mixture was heated, refluxed, and stirred for 24 hours at 130° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50.50) to obtain the compound 121 (2.76 g, 79%).

### 31. Synthesis of the Compound 124

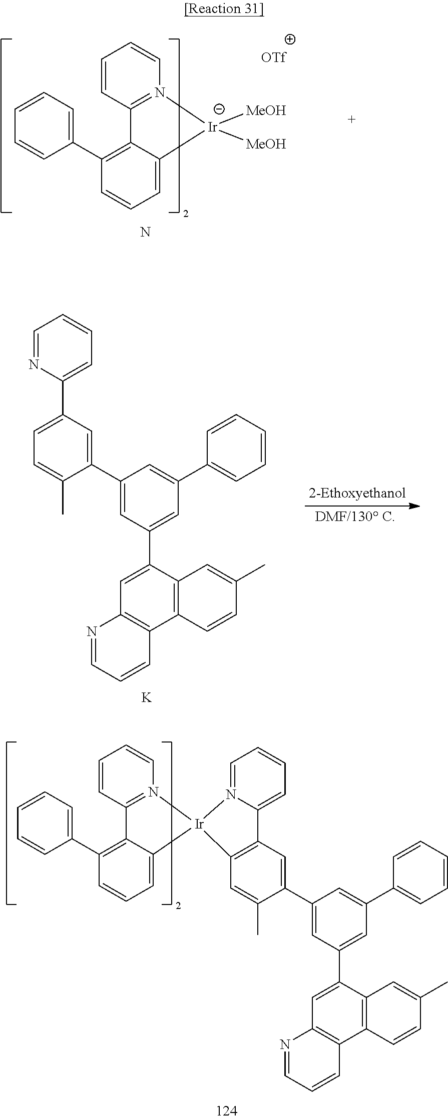

In a rounded-bottom flask (250 mL) under a nitrogen condition, the compound N (1.20 g 1.5 mmol) and the ligand K (1.54 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 124 (2.65 g, 76%).

### 32. Synthesis of the Compound 153

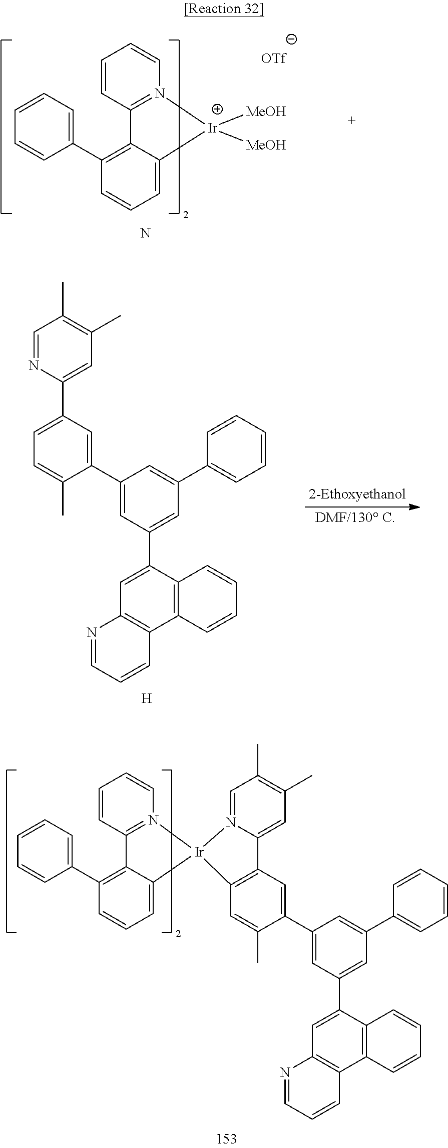

In a rounded-bottom flask (250 mL) under a nitrogen condition, the compound N (1.20 g, 1.5 mmol) and the ligand H (1.58 g, 3 mmol) were put into 2-ethoxyethanol (50 mL) and DMF (50 mL), and the mixture was heated, refluxed, and stirred for 24 hours at 130′C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 153 (2.58 g, 73%).

### 33. Synthesis of the Compound 155

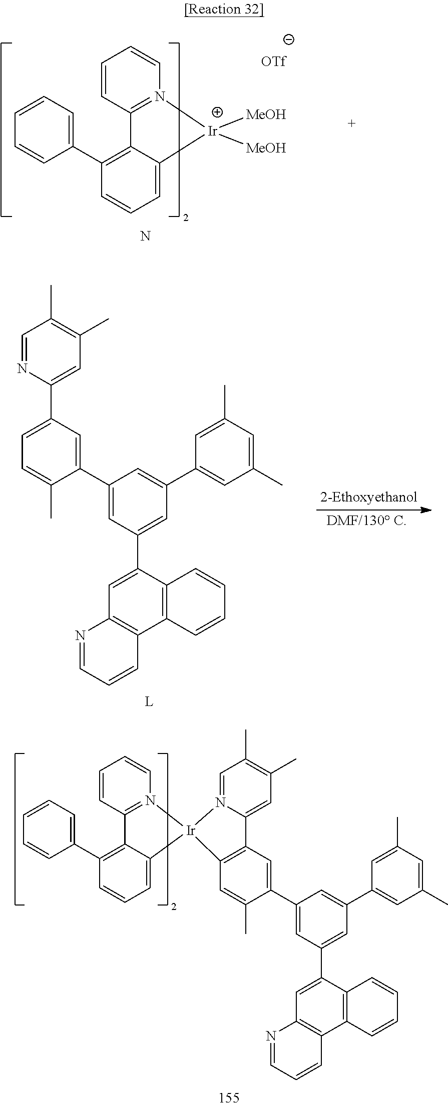

In a rounded-bottom flask (250 mL) under a nitrogen condition, the compound N (1.20 g 1.5 mmol) and the ligand L (1.66 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 155 (2.71 g, 75%).

### 34. Synthesis of the Compound 157

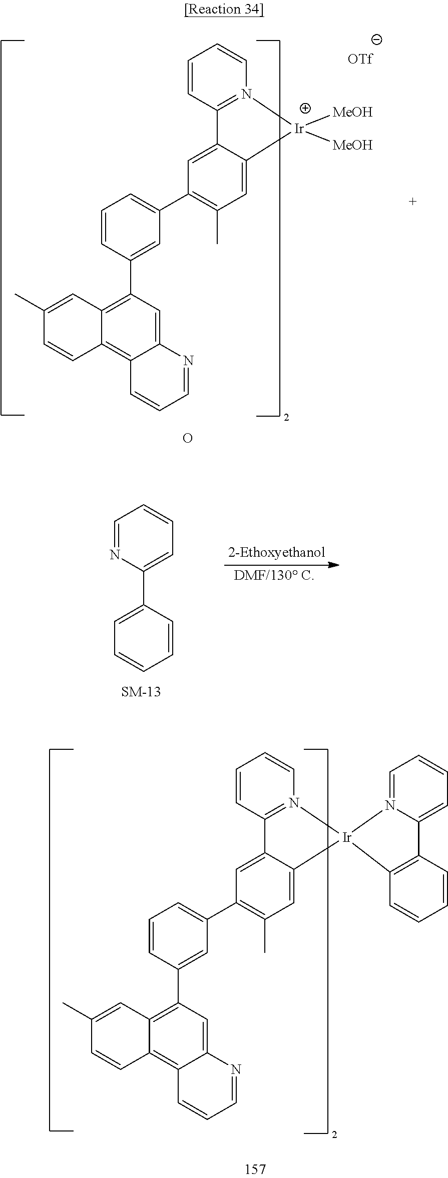

In a rounded-bottom flask (250 mL) under a nitrogen condition, the compound O (1.19 g, 1.5 mmol) and the ligand SM-3 (0.70 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 157 (2.66 g, 73%).

### 35. Synthesis of the Compound 158

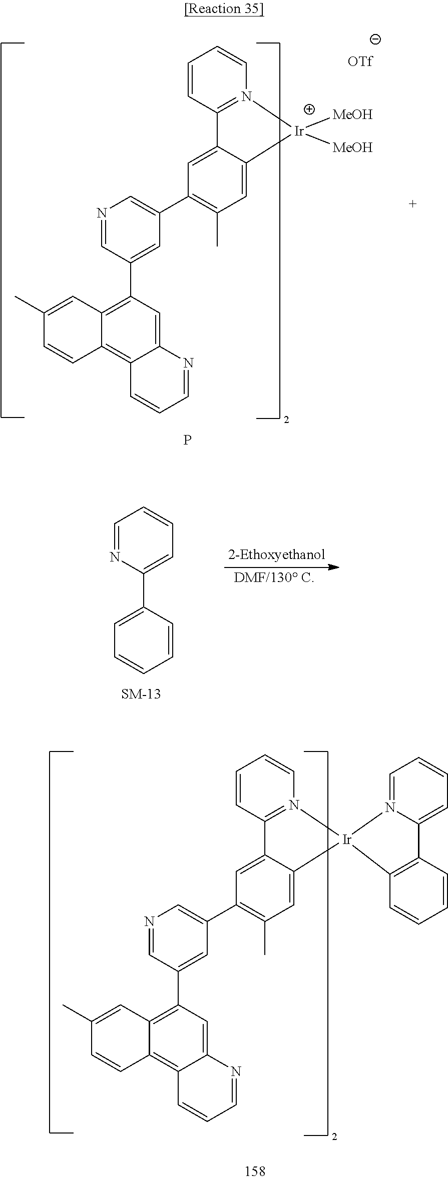

In a rounded-bottom flask (250 mL) under a nitrogen condition, the compound P (1.19 g, 1.5 mmol) and the ligand SM-13 (0.70 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 158 (2.67 g, 73%).

### 36. Synthesis of the Compound 159

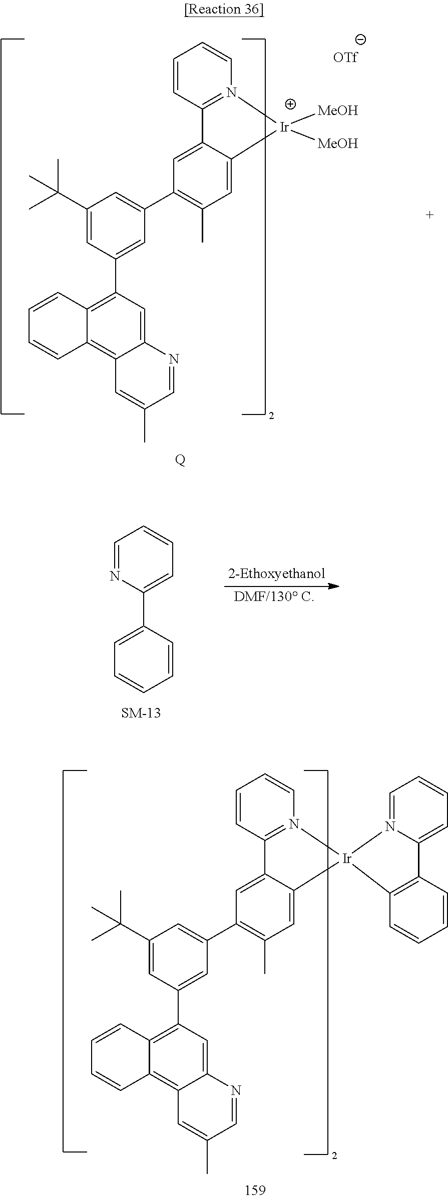

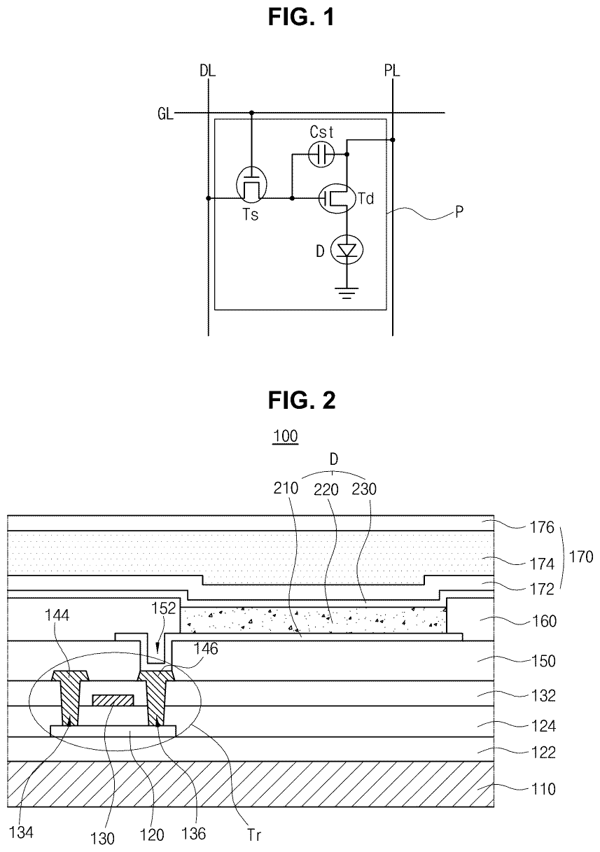

In a rounded-bottom flask (250 mL) under a nitrogen condition, the compound Q (1.19 g, 1.5 mmol) and the ligand SM-1 (0.70 g, 3 mmol) were put into 2-ethoxyethanol (50 mL) and DMF (50 mL), and the mixture was heated, refluxed, and stirred for 24 hours at 130′° C. After completion of the reaction, the temperature was lowered to room temperature, and the organic layer was extracted with dichloromethane and distilled water. Water was removed with anhydrous magnesium sulfate. The filtered solution was concentrated under reduced pressure to obtain a crude product. The crude product was purified by column chromatography using ethylacetate and hexane (volume ratio=50:50) to obtain the compound 159 (2.91 g, 73%). The present disclosure relates to an OLED, in which the organometallic compound represented by Formula 1 is included in an emitting material layer, and an organic light emitting device including the OLED. As an example, an organic light emitting display device, which is a display device including the OLED of the present disclosure, will be mainly described. FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region may include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr and an OLED D connected to the TFT Tr.

The substrate 110 may be a glass substrate or a flexible substrate. For example, the substrate 110 may be one of a polyimide (PI) substrate, a polyethersulfone (PES) substrate, a polyethylenenaphthalate (PEN) substrate, a polyethylene Terephthalate (PET) substrate and a polycarbonate (PC) substrate.

A buffer layer 122 is formed on the substrate, and the TFT Tr is formed on the buffer layer 122. The buffer layer 122 may be omitted.

A semiconductor layer 120 is formed on the buffer layer 122. The semiconductor layer 120 may include an oxide semiconductor material or polycrystalline silicon.

When the semiconductor layer 120 includes the oxide semiconductor material, a light-shielding pattern (not shown) may be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities may be doped into both sides of the semiconductor layer 120.

A gate insulating layer 124 is formed on the semiconductor layer 120. The gate insulating layer 124 may be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120.

In FIG. 2, the gate insulating layer 124 is formed on an entire surface of the substrate 110. Alternatively, the gate insulating layer 124 may be patterned to have the same shape as the gate electrode 130.

An interlayer insulating layer 132, which is formed of an insulating material, is formed on the gate electrode 130. The interlayer insulating layer 132 may be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first and second contact holes 134 and 136 are formed through the gate insulating layer 124. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132.

The source electrode 144 and the drain electrode 146 are spaced apart from each other with respect to the gate electrode 130 and respectively contact both sides of the semiconductor layer 120 through the first and second contact holes 134 and 136.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure. Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element. In addition, the power line, which may be formed to be parallel to and spaced apart from one of the gate and data lines, and the storage capacitor for maintaining the voltage of the gate electrode of the TFT Tr in one frame may be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr. The OLED D is disposed on the planarization layer 150 and includes a first electrode 210, which is connected to the drain electrode 146 of the TFT Tr, an light emitting layer 220 and a second electrode 230. The light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 may be an anode and may be formed of a conductive material, e.g., a transparent conductive oxide (TCO), having a relatively high work function. For example, the first electrode 210 may be formed of indium-tin-oxide (ITO), indium-zinc-oxide (IZO), indium-tin-zinc-oxide (ITZO), tin oxide (SnO), zinc oxide (ZnO), indium-copper-oxide (ICO) or aluminum-zinc-oxide (Al:ZnO, AZO).

When the organic light emitting display device 100 of the present disclosure is operated in a bottom-emission type, the first electrode 210 may have a single-layered structure of a transparent conductive oxide layer of the transparent conductive oxide. Alternatively, when the organic light emitting display device 100 of the present disclosure is operated in a top-emission type, the first electrode 210 may further include a reflection layer to have a double-layered structure or a triple-layered structure. For example, the reflection layer may be formed of silver (Ag) or aluminum-palladium-copper (APC) alloy. In the top-emission type OLED, the first electrode 210 may have a double-layered structure of Ag/ITO or APC/ITO or a triple-layered structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 is formed on the first electrode 210. The organic light emitting layer 220 may have a single-layered structure of an emitting material layer (EML) including an emitting material. Alternatively, the organic light emitting layer 220 may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure. In addition, two or more organic light emitting layers may be disposed to be spaced apart from each other such that the OLED D may have a tandem structure.

In at least one of the red pixel region and the green pixel region, the organic light emitting layer 220 of the OLED D includes the organometallic compound of the present disclosure so that the emitting efficiency and the lifespan of the OLED D and the organic light emitting display device 100 are improved.

The second electrode 230 is formed over the substrate 110 where the organic light emitting layer 220 is formed. The second electrode 230 covers an entire surface of the display area and may be formed of a conductive material having a relatively low work function to serve as a cathode. For example, the second electrode 230 may be formed of a high reflective material, e.g., aluminum (Al), magnesium (Mg), calcium (Ca), silver (Ag), their alloy, or their combination. In the top-emission type organic light emitting display device 100, the second electrode 230 may have a thin profile to be transparent (or semi-transparent).

Although not shown, the organic light emitting display device 100 may include a color filter layer corresponding to the red, green and blue pixel regions. The color filter layer may include a red color filter, a green color filter and a blue color filter corresponding to the red, green and blue pixel regions, respectively. When the OLED includes the color filter layer, the color purity of the OLED can be further improved.

When the organic light emitting display device 100 is operated in a bottom-emission type, the color filter may be disposed between the OLED D and the substrate 110, e.g., between the interlayer insulating layer 132 and the planarization layer 150. Alternatively, the organic light emitting display device 100 is operated in a top-emission type, the color filter may be disposed over the OLED D, e.g., over the second electrode 230.

An encapsulation layer (or an encapsulation film) 170 is formed on the second electrode 230 to prevent penetration of moisture into the OLED D. The encapsulation layer 170 includes a first inorganic insulating layer 172, an organic insulating layer 174 and a second inorganic insulating layer 176 sequentially stacked, but it is not limited thereto.

In the bottom-emission type organic light emitting display device 100, a metal plate may be further disposed on the encapsulation layer 170.

The organic light emitting display device 100 may further include a polarization plate (not shown) for reducing an ambient light reflection. For example, the polarization plate may be a circular polarization plate. In the bottom-emission type organic light emitting display device 100, the polarization plate may be positioned under the substrate 110. Alternatively, in the top-emission type organic light emitting display device 100, the polarization plate may be positioned on or over the encapsulation layer 170.

In addition, in the top-emission type organic light emitting display device 100, a cover window (not shown) may be attached to the encapsulation layer 170. In this instance, the substrate 110 and the cover window have a flexible property such that a flexible organic light emitting display device may be provided.

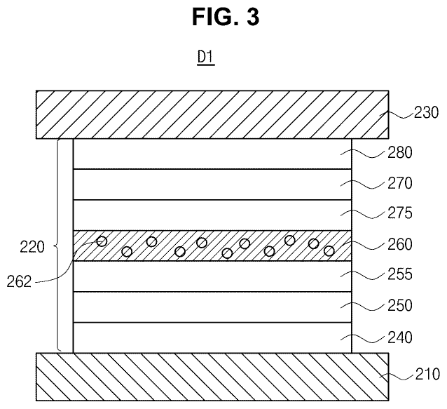

FIG. 3 is a schematic cross-sectional view of an OLED according to a second embodiment of the present disclosure.

As shown in FIG. 3, the OLED D1 includes the first and second electrodes 210 and 230, which face each other, and the organic light emitting layer 220 therebetween.

The organic light emitting display device 100 includes the red, green and blue pixel regions. In addition, the organic light emitting display device 100 may further include a white pixel region. The OLED D1 may be positioned in at least one of the red and green pixel regions. For example, the OLED D1 may be positioned in the green pixel region.

The first electrode 210 may be anode, and the second electrode 230 may be a cathode. One of the first and second electrodes 210 and 230 may be a transparent electrode (or a semi-transparent electrode), and the other one of the first and second electrodes 210 and 230 may be a reflection electrode.

The organic light emitting layer 220 includes an emitting material layer (EML) 260.

The organic light emitting layer 220 further include at least one of a hole transporting layer (HTL) 250 between the first electrode 210 and the EML 260 and an electron transporting layer (ETL) 270 between the second electrode 230 and the EML 260.

In addition, the organic light emitting layer 220 may further include at least one of a hole injection layer (HIL) 240 between the first electrode 210 and the HTL 250 and an electron injection layer (EIL) 280 between the second electrode 230 and the ETL 270.

Moreover, the organic light emitting layer 220 may further include at least one of an electron blocking layer (EBL) 255 between the HTL 250 and the EML 260 and a hole blocking layer (HBL) 275 between the EML 260 and the ETL 270.

Namely, the OLED D1 according to the second embodiment of the present disclosure has a single emitting part (unit).

For example, the HIL 240 may include a hole injection material selected from the group consisting of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile (HAT-CN), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine), and N,N′-diphenyl-N,N′-di[4-(N,N-diphenyl-amino)phenyl]benzidine (NPNPB), but it is not limited thereto. For example, the hole injection material of the HIL 240 may include a compound in Formula 4. The HIL 240 may have a thickness of 1 to 20 nm.

The HTL 250 may include a hole transporting material selected from the group consisting of N,N′-diphenyl-N,N′-bis(3-methylphenyl)-1,1′-biphenyl-4,4′-diamine (TPD), NPB (NPD), 4,4′-bis(N-carbazolyl)-1,1′-biphenyl (CBP), poly[N,N′-bis(4-butylpnehyl)-N,N′-bis(phenyl)-benzidine] (poly-TPD), (poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, and N-([1,1′-biphenyl]-4-yl)-9,9-dimethyl-N-(4-(9-phenyl-9H-carbazol-3-yl)phenyl)-9H-fluoren-2-amine, but it is not limited thereto. For example, the hole transporting material of the HTL 250 may include a compound in Formula 5. The HTL 250 may have a thickness of 30 to 150 nm, preferably 50 to 120 nm. The ETL 270 may include an electron transporting material selected from the group consisting of tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,08)-(1,1′-biphenyl-4-olato)aluminum (BAlq), 4,7-diphenyl-1,10-phenanthroline (Bphen), 2,9-bis(naphthalene-2-yl)-4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), diphenyl-4-triphenylsilyl-phenylphosphine oxide (TSPO1), and 2-[4-(9,10-Di-2-naphthalen2-yl-2-anthracen-2-yl)phenyl]-1-phenyl-1H-benzimidazole (ZADN). The ETL 270 may have a thickness of 10 to 100 nm, preferably 10 to 50 nm. The EIL 280 may include an electron injection material selected from the group consisting of LiF, CsF, NaF, BaF₂, Liq, lithium benzoate, and sodium stearate, but it is not limited thereto. The EIL 280 may have a thickness of 0.1 to 10 nm, preferably 0.5 to 5 nm.

In FIG. 3, the ETL 270 and the EIL 280 as separated elements are formed. Alternatively, an electron transporting-injection layer as a single layer having an electron transporting function and an electron injection function may be formed. In this case, the electron transporting-injection layer may include an electron transporting material and an electron injection material and may have a thickness of 10 to 50 nm. For example, the electron transporting-injection layer may include a compound in Formula 7 and a compound in Formula 8, and a weight % of the compound in Formula 7 and a weight % of the compound in Formula 8 may be same.

The EBL 255, which is positioned between the HTL 250 and the EML 260 to block the electron transfer from the EML 260 into the HTL 250, may include an electron blocking material selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene), but it is not limited thereto. The EBL 255 may have a thickness of 1 to 30 nm.

The HBL 275, which is positioned between the EML 260 and the ETL 270 to block the hole transfer from the EML 260 into the ETL 270, may include the above material of the ETL 270.

For example, the HBL 275 may include a hole blocking material selected from the group consisting of BCP, BAlq, Alq₃, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole, and TSPO1, but it is not limited thereto. The HBL 275 may have a thickness of 1 to 30 nm.

The EML 260 may have a thickness of 10 to 100 nm, preferably 20 to 50 nm.

In at least one of the red and green pixel regions, the EML 260 includes a first compound 262 being the organometallic compound of the present disclosure. The first compound 262 serves as a dopant (e.g., an emitter or a light emitter). In addition, the EML 260 may further include a second compound as a host. In the EML 260, a weight % of the first compound 262 is smaller than that of the second compound. For example, in the EML 260, the first compound 262 may have a weight % of 1 to 40, preferably 1 to 20, more preferably 1 to 10.

When the EML 260 in the red and green pixel regions includes the organometallic compound of the present disclosure as the first compound 262, the first compound 262 (e.g., a red dopant) in the EML 260 in the red pixel region and the first compound 262 (e.g., a green dopant) in the EML 260 in the green pixel region have a difference in the auxiliary ligand in Formula 1 to have a difference in the emission wavelength.

For example, when the voltage is applied to the first and second electrodes 210 and 230, a hole from the first electrode 210 and an electron from the second electrode 230 are injected to the EML 260 so that an exciton is generated in the second compound. The generated exciton is transferred into the first compound 262, and thus the light is emitted from the first compound 262.

When the EML 260 in the green pixel region include the first compound 262 being the organometallic compound of Formula 1, the EML 260 in the green pixel region may further include a green host as the second compound.

For example, the second compound, i.e., the green host, may be one of 9-(3-(9H-carbazol-9-yl)phenyl)-9H-carbazole-3-carbonitrile (mCP-CN), CBP, 3,3′-bis(N-carbazolyl)-1,1′-biphenyl (mCBP), 1,3-bis(carbazol-9-yl)benzene (mCP), DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto. When the EML 260 in the red pixel region include the first compound 262 being the organometallic compound of Formula 1, the EML 260 in the red pixel region may further include a red host as the second compound.

For example, the second compound, i.e., the red host, may be one of mCP-CN, CBP, mCBP, mCP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene), 9-(4-(9H-carbazol-9-yl)phenyl)-9H-3,9′-bicarbazole), 9-(3-(9H-carbazol-9-yl)phenyl)-9H-3,9′-bicarbazole), 9-(6-(9H-carbazol-9-yl)pyridin-3-yl)-9H-3,9′-bicabazole), 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbipheyl (CDBP), 2,7-bis(carbazole-9-yl)-9,9-dimethylfluorene (DMFL-CBP), 2,2′,7,7′-tetrakis(carbazole-9-yl)-9,9-spirofluorene (Spiro-CBP), 3,6-bis(carbazole-9-yl)-9-(2-ethyl-hexyl)-9H-carbazole (TCzl), bis(2-hydroxylphenyl)-pyridine)beryllium (Bepp2), bis(10-hydroxylbenzo[h] quinolinato)beryllium (Bebg2), and 1,3,5-tris(1-pyrenyl)benzene (TPB3), but it is not limited thereto.

Alternatively, the EML 260 in the red pixel region may include a red dopant being not the organometallic compound of Formula 1. In this instance, the red dopant may include at least one of a red phosphorescent material, a red fluorescent material and a red delayed fluorescent material. For example, the red dopant may be one of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)2(acac)), tris[2-(4-n-hexylphenyl)quinoline]iridium(III) (Hex-Ir(phq)3), tris[2-phenyl-4-methylquinoline]iridium(III) (Ir(Mphq)3), bis(2-phenylquinoline)(2,2,6,6-tetramethylheptene-3,5-dionate)iridium(III) (Ir(dpm)PQ2), bis(phenylisoquinoline)(2,2,6,6-tetramethylheptene-3,5-dionate)iridium(III) (Ir(dpm)(piq)2), bis[(4-n-hexylphenyl)isoquinoline](acetylacetonate)iridium(III) (Hex-Ir(piq)2(acac)), tris[2-(4-n-hexylphenyl)quinoline]iridium(III) (Hex-Ir(piq)3), tris(2-(3-methylphenyl)-7-methyl-quinolato)iridium (Ir(dmpq)3), bis[2-(2-methylphenyl)-7-methyl-quinoline](acetylacetonate)iridium(III) (Ir(dmpq)2(acac)), bis[2-(3,5-dimethylphenyl)-4-methyl-quinoline](acetylacetonate)iridium(III) (Ir(mphmq)2(acac)), and tris(dibenzoylmethane)mono(1,10-phenanthroline)europium(III) (Eu(dbm)3(phen)). The organometallic compound of the present disclosure is an iridium complex having a structure of Formula 1 and is included in the EML 260 of the OLED D1. As a result, the emitting efficiency and the lifespan of the OLED D1 and the organic light emitting display device 100 are improved.

### [OLED]

On a substrate, where an anode (ITO, 100 nm) is coated, an HIL (the compound HI-1 in Formula 4, 60 nm), an HTL (the compound NPB in Formula 5, 80 nm), an EML (a host (the compound CBP in Formula 6, 95 wt %) and a dopant (5 wt %), 30 nm), an electron transporting-injection layer (the compound ET-1 in Formula 7 and the compound Liq in Formula 8 (a weight ratio=1:1), 30 nm), and a cathode (Al, 100 nm) were sequentially stacked to form a green OLED.

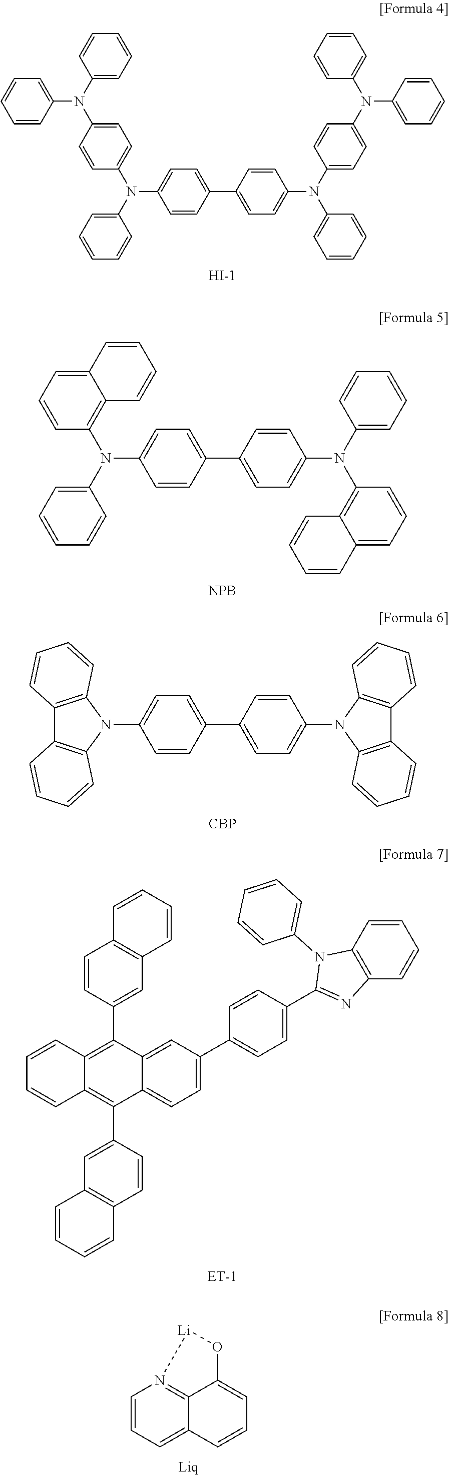

### 1. Comparative Examples 1 to 7 (Ref1 to Ref7)

The compounds Ref-1, Ref-2, Ref-3, Ref-4, Ref-5, Ref-6 and Ref-7 in Formula 9 were respectively used as the dopant.

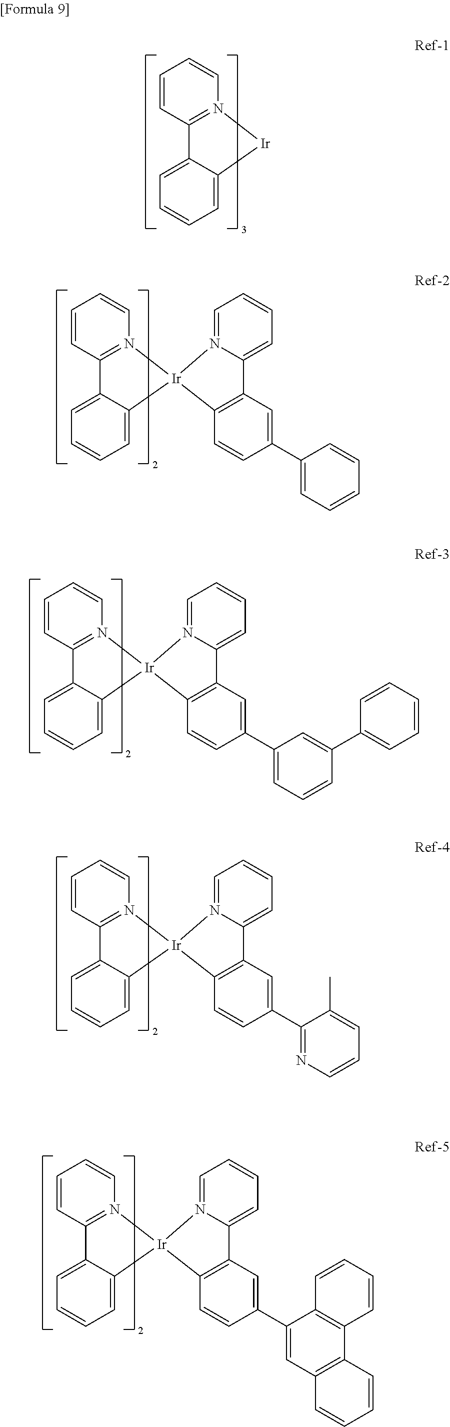

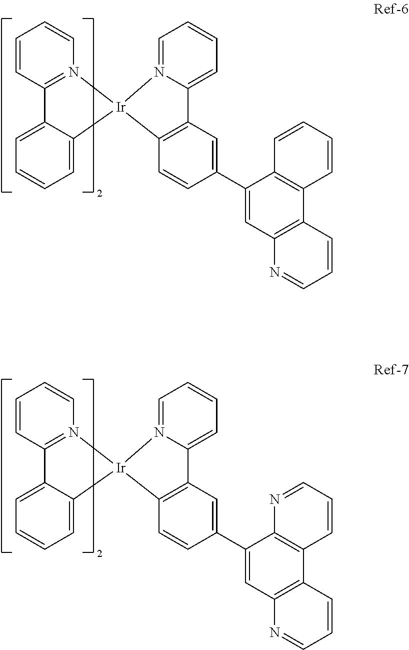

### 2. Examples 1 to 8 (Ex1 to Ex8)

The compounds 1, 3, 13, 49, 109, 111, 121 and 124 in Formula 3 were respectively used as the dopant.

The emitting properties, i.e., a driving voltage (V), a maximum current efficiency (CEmax, %) an external quantum efficiency (EQE, C) and a lifespan (LT95, E) of the OLED in Comparative Examples 1 to 7 and Examples 1 to 8 were measured and listed in Table 1. The emitting properties of the OLED were measured at the room temperature using a current source (KEITHLEY) and a photometer (PR 650), and the driving voltage, the maximum current efficiency, the external quantum efficiency and the lifetime are relative values with respect to Comparative Example 1.

TABLE 1

| | dopant | V | CEmax (%) | EQE (%) | LT95 (%) |
|---|---|---|---|---|---|
| Ref1 | Ref-1 | 4.25 | 100 | 100 | 100 |
| Ref2 | Ref-2 | 4.25 | 104 | 88 | 99 |
| Ref3 | Ref-3 | 4.30 | 105 | 87 | 102 |
| Ref4 | Ref-4 | 4.35 | 107 | 87 | 94 |
| Ref5 | Ref-5 | 4.30 | 104 | 90 | 92 |
| Ref6 | Ref-6 | 4.30 | 104 | 91 | 98 |
| Ref7 | Ref-7 | 4.33 | 100 | 80 | 80 |
| Ex1 | 1 | 4.22 | 115 | 111 | 125 |
| Ex2 | 3 | 4.23 | 115 | 122 | 124 |
| Ex3 | 13 | 4.23 | 116 | 116 | 120 |
| Ex4 | 49 | 4.22 | 116 | 121 | 130 |
| Ex5 | 109 | 4.20 | 115 | 121 | 122 |
| Ex6 | 111 | 4.21 | 116 | 119 | 123 |
| Ex7 | 121 | 4.23 | 116 | 118 | 120 |
| Ex8 | 124 | 4.21 | 115 | 120 | 126 |

As shown in Table 1, in comparison to the OLED of Comparative Examples 1 to 7, in the OLED of Examples 1 to 8, the driving voltage is decreased, and the emitting efficiency and the lifespan are increased.

For example, each of compounds 1, 3, 13, 49, 109, 111, 121 and 124 in Formula 3 has a structure, where an azaphenanthrene moiety is combined to a phenylpyridine moiety through a substituted or unsubstituted arylene moiety, e.g., phenylene, or a substituted or unsubstituted heteroarylene moiety, e.g., pyridylene, and the azaphenanthrene moiety is substituted with a substituted or unsubstituted C1 to C20 alkyl group, e.g., methyl. In the OLEDs of Examples 1 to 8, which respectively include compounds 1, 3, 13, 49, 109, 111, 121 and 124 in Formula 3 as a dopant, the driving voltage is decreased, and the emitting efficiency and the lifespan are increased.

### 3. Examples 9 to 11 (Ex9 to Ex11)

The compounds 7, 17 and 23 in Formula 3 were respectively used as the dopant.

The emitting properties, i.e., a driving voltage (V), a maximum current efficiency (CEmax, %), an external quantum efficiency (EQE, %) and a lifespan (LT95, %), of the OLED in Comparative Examples 1, 2 and 5 to 7 and Examples 9 to 11 were measured and listed in Table 2. The emitting properties of the OLED were measured at the room temperature using a current source (KEITHLEY) and a photometer (PR 650), and the driving voltage, the maximum current efficiency, the external quantum efficiency and the lifetime are relative values with respect to Comparative Example 1.

TABLE 2

| | | | CEmax | | |
|---|---|---|---|---|---|
| | dopant | V | (%) | EQE (%) | LT95 (%) |
| Ref1 | Ref-1 | 4.25 | 100 | 100 | 100 |
| Ref2 | Ref-2 | 4.25 | 104 | 88 | 99 |
| Ref5 | Ref-5 | 4.30 | 104 | 90 | 92 |
| Ref6 | Ref-6 | 4.30 | 104 | 91 | 98 |
| Ref7 | Ref-7 | 4.33 | 100 | 80 | 80 |
| Ex1 | 1 | 4.22 | 115 | 111 | 125 |
| Ex9 | 7 | 4.20 | 118 | 129 | 123 |
| Ex10 | 17 | 4.22 | 115 | 113 | 120 |
| Ex11 | 23 | 4.22 | 114 | 117 | 121 |

As shown in Table 2, in comparison to the OLED of Comparative Examples 1, 2 and 5 to 7, in the OLED of Examples 9 to 11, the driving voltage is decreased, and the emitting efficiency and the lifespan are increased.

For example, each of the compounds 1, 7, 17 and 23 in Formula 3 has a structure of Formula 2-2, where each of X₁ and X₃ to X₅ is CR₄, one of R₄ is a substituted or unsubstituted C1 to C20 alkyl group, e.g., methyl or tert-butyl, and the rest of R4 are hydrogen. In the OLEDs of Examples 1 and 9 to 11, which respectively include compounds 1, 7, 17 and 23 in Formula 3 as a dopant, the driving voltage is decreased, and the emitting efficiency and the lifespan are increased.

### 4. Examples 12 to 15 (Ex12 to Ex15)

The compounds 45, 47, 153 and 155 in Formula 3 were respectively used as the dopant.

The emitting properties, i.e., a driving voltage (V), a maximum current efficiency (CEmax, %), an external quantum efficiency (EQE, %) and a lifespan (LT95, %), of the OLED in Comparative Examples 1 to 3 and 5 to 7 and Examples 12 to 15 were measured and listed in Table 3. The emitting properties of the OLED were measured at the room temperature using a current source (KEITHLEY) and a photometer (PR 650), and the driving voltage, the maximum current efficiency, the external quantum efficiency and the lifetime are relative values with respect to Comparative Example 1.

TABLE 3

| | | | CEmax | | |
|---|---|---|---|---|---|
| | dopant | V | (%) | EQE (%) | LT95 (%) |
| Ref1 | Ref-1 | 4.25 | 100 | 100 | 100 |
| Ref2 | Ref-2 | 4.25 | 104 | 88 | 99 |
| Ref3 | Ref-3 | 4.30 | 105 | 87 | 102 |
| Ref5 | Ref-5 | 4.30 | 104 | 90 | 92 |
| Ref6 | Ref-6 | 4.30 | 104 | 91 | 98 |
| Ref7 | Ref-7 | 4.33 | 100 | 80 | 80 |
| Ex12 | 45 | 4.22 | 115 | 111 | 125 |
| Ex13 | 47 | 4.20 | 118 | 129 | 125 |
| Ex14 | 153 | 4.22 | 115 | 113 | 120 |
| Ex15 | 155 | 4.22 | 114 | 117 | 124 |

As shown in Table 3, in comparison to the OLED of Comparative Examples 1 to 3 and 5 to 7, in the OLED of Examples 12 to 15, the driving voltage is decreased, and the emitting efficiency and the lifespan are increased.

For example, each of the compounds 45, 47, 153 and 155 in Formula 3 has a structure of Formula 2-2, where each of X₁ and X₃ to X₅ is CR₄, one of R₄ is a substituted or unsubstituted C6 to C30 aryl group, e.g., phenyl, and the rest of R₄ are hydrogen. In the OLEDs of Examples 12 to 15, which respectively include compounds 45, 47, 153 and 155 in Formula 3 as a dopant, the driving voltage is decreased, and the emitting efficiency and the lifespan are increased.

### 5. Examples 16 to 19 (Ex16 to Ex19)

The compounds 10, 157, 158 and 159 in Formula 3 were respectively used as the dopant. The emitting properties, i.e., a driving voltage (V), a maximum current efficiency (CEmax, %) an external quantum efficiency (EQE, %) and a lifespan (LT95, %), of the OLED in Comparative Examples 2 to 7 and Examples 2, 9 and 16 to 19 were measured and listed in Table 4. The emitting properties of the OLED were measured at the room temperature using a current source (KEITHLEY) and a photometer (PR 650), and the driving voltage, the maximum current efficiency, the external quantum efficiency and the lifetime are relative values with respect to Comparative Example 1.

TABLE 4

| | dopant | V | CEmax (%) | EQE (%) | LT95 (%) |
|---|---|---|---|---|---|
| Ref2 | Ref-2 | 4.25 | 104 | 88 | 99 |
| Ref3 | Ref-3 | 4.30 | 105 | 87 | 102 |
| Ref4 | Ref-4 | 4.35 | 107 | 87 | 94 |
| Ref5 | Ref-5 | 4.30 | 104 | 90 | 92 |
| Ref6 | Ref-6 | 4.30 | 104 | 91 | 98 |
| Ref7 | Ref-7 | 4.33 | 100 | 80 | 80 |
| Ex2 | 3 | 4.23 | 115 | 122 | 124 |
| Ex9 | 7 | 4.21 | 115 | 121 | 125 |
| Ex16 | 10 | 4.22 | 116 | 121 | 129 |
| Ex17 | 157 | 4.23 | 117 | 120 | 118 |
| Ex18 | 158 | 4.24 | 115 | 121 | 120 |
| Ex19 | 159 | 4.23 | 117 | 122 | 122 |

As shown in Table 4, in comparison to the OLED of Comparative Examples 2 to 7, in the OLED of Examples 2, 9 and 16 to 19, the driving voltage is decreased, and the emitting efficiency and the lifespan are increased.

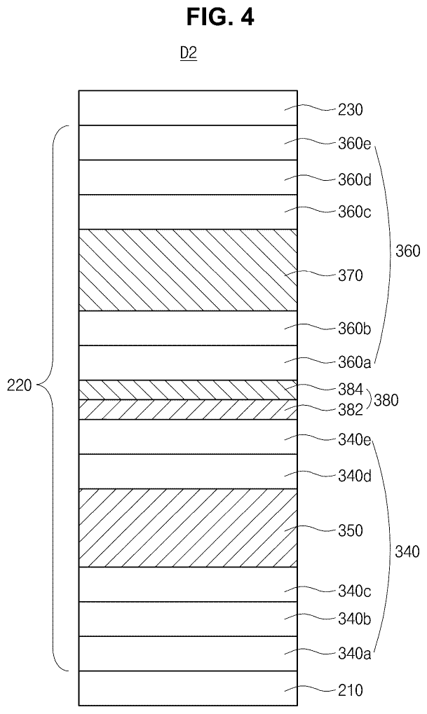

FIG. 4 is a schematic cross-sectional view of an OLED according to a third embodiment of the present disclosure.

As shown in FIG. 4, the OLED D2 includes the first and second electrodes 210 and 230, which face each other, and the emitting layer 220 therebetween.

The organic light emitting display device 100 (of FIG. 2) may include a red pixel region, a green pixel region and a blue pixel region. The organic light emitting display device 100 may further include a white pixel region. The OLED D2 may be positioned in at least one of the red and green pixel region. For example, the OLED D2 may be positioned in the green pixel region.

The first electrode 210 may be an anode, and the second electrode 230 may be a cathode. One of the first and second electrodes 210 and 230 may be a transparent electrode (or a semi-transparent electrode), and the other one of the first and second electrodes 210 and 230 may be a reflection electrode.

The organic light emitting layer 320 includes a first emitting part 340 including a first EML 350 and a second emitting part 360 including a second EML 370. In addition, the organic light emitting layer 320 may further include a charge generation layer (CGL) 380 between the first and second emitting parts 340 and 360.

The CGL 380 is positioned between the first and second emitting parts 340 and 360 such that the first emitting part 340, the CGL 380 and the second emitting part 360 are sequentially stacked on the first electrode 210. Namely, the first emitting part 340 is positioned between the first electrode 210 and the CGL 380, and the second emitting part 360 is positioned between the second electrode 230 and the CGL 380.

The first emitting part 340 may further include at least one of a first HTL 340b between the first electrode 210 and the first EML 350, an HIL 340a between the first electrode 210 and the first HTL 340b, and a first ETL 340e between the first EML 350 and the CGL 380. Moreover, the first emitting part 340 may further include at least one of a first EBL 340c between the first HTL 340b and the first EML 350 and a first HBL 340d between the first EML 350 and the first ETL 340e.

The second emitting part 360 may further include at least one of a second HTL 360a between the CGL 380 and the second EML 370, a second ETL 360d between the second EML 370 and the second electrode 230, and an EIL 360e between the second ETL 360d and the second electrode 230.

Moreover, the second emitting part 360 may further include at least one of a second EBL 360b between the second HTL 360a and the second EML 370 and a second HBL 360c between the second EML 370 and the second ETL 360d.

The HIL 340a may include the above-mentioned hole injection material and may have a thickness of 10 to 100 nm.

Each of the first and second HTLs 340b and 360a may include the above-mentioned hole transporting material and may have a thickness of 30 to 150 nm, preferably 50 to 120 nm. Each of the first and second ETLs 340e and 360d may include the above-mentioned electron transporting material and may have a thickness of 10 to 100 nm, preferably 10 to 50 nm. The EIL 360e may include the above-mentioned electron injection material and may have a thickness of 0.1 to 10 nm, preferably 0.5 to 5 nm.

In FIG. 4, the ETL 360d and the EIL 360e as separated elements are formed. Alternatively, an electron transporting-injection layer as a single layer having an electron transporting function and an electron injection function may be formed. In this case, the electron transporting-injection layer may include an electron transporting material and an electron injection material and may have a thickness of 10 to 50 nm. For example, the electron transporting-injection layer may include a compound in Formula 7 and a compound in Formula 8, and a weight % of the compound in Formula 7 and a weight % of the compound in Formula 8 may be same.

Each of the first and second EBLs 340c and 360b may include the above-mentioned electron blocking material and may have a thickness of 1 to 30 nm.

Each of the first and second HBLs 340d and 360c may include the above-mentioned hole blocking material and may have a thickness of 1 to 30 nm.

The CGL 380 is positioned between the first and second emitting parts 340 and 360. Namely, the first and second emitting parts 340 and 360 are connected to each other through the CGL 380. The CGL 380 may be a P-N junction type CGL of an N-type CGL 382 and a P-type CGL 384.

The N-type CGL 382 is positioned between the first ETL 340e and the second HTL 360a, and the P-type CGL 384 is positioned between the N-type CGL 382 and the second HTL 360a. The N-type CGL 382 provides an electron into the first EML 350 of the first emitting part 340, and the P-type CGL 384 provides a hole into the second EML 370 of the second emitting part 360.

The N-type CGL 382 may be an organic layer doped with an alkali metal, e.g., Li, Na, K and Cs, and/or an alkali earth metal, e.g., Mg, Sr, Ba and Ra. For example, the N-type CGL 382 may be formed of an N-type charge generation material including a host being the organic material, e.g., 4,7-diphenyl-1,10-phenanthroline (Bphen) and MTDATA, a dopant being an alkali metal and/or an alkali earth metal, and the dopant may be doped with a weight % of 0.01 to 30.

The P-type CGL 384 may be formed of a P-type charge generation material including an inorganic material, e.g., tungsten oxide (WOx), molybdenum oxide (MoOx), beryllium oxide (Be203) and vanadium oxide (V205), an organic material, e.g., NPD, HAT-CN, F4TCNQ, TPD, TNB, TCTA and N,N′-dioctyl-3,4,9,10-perylenedicarboximide (PTCDI-C8).

The first and second EMLs 350 and 370 are a green EML. At least one of the first and second EMLs 350 and 370 includes a first compound being the organometallic compound represented by Formula 1. In addition, at least one of the first and second EMLs 350 and 370 may further include a second compound being a green host. The first compound may have a weight % of 1 to 40, preferably 1 to 20, more preferably 1 to 10.

The second compound as the green host may be the above-mentioned green host material.

In an aspect of the present disclosure, both the first EML 350 and the second EML 370 may include the first compound being the organometallic compound represented by Formula land the second compound being the green host. In this case, the first compound in the first EML 350 and the first compound in the second EML 370 may be same or different. In addition, the second compound in the first EML 350 and the second compound in the second EML 370 may be same or different.

In an aspect of the present disclosure, one of the first EML 350 and the second EML 370 may include the first compound being the organometallic compound represented by Formula 1 and the second compound being the green host, and the other one of the first EML 350 and the second EML 370 may include one of a green dopant, which is other than the organometallic compound represented by Formula 1, and a green host. In this case, the green dopant may include at least one of a green phosphorescent material, a green fluorescent material and a green delayed fluorescent material. For example, the green dopant may be one of [bis(2-phenylpyridine)](pyridyl-2-benzofuro[2,3-b]pyridine)iridium, Ir(ppy)3, fac-Ir(ppy)3, Ir(ppy)2(acac), Ir(mppy)3, Ir(npy)2acac, Ir(3mppy)3 and TEG, but it is not limited thereto. In an aspect of the present disclosure, the first and second EMLs 350 and 370 are a red EML. In this case, at least one of the first and second EMLs 350 and 370 includes a first compound being the organometallic compound represented by Formula 1. In addition, at least one of the first and second EMLs 350 and 370 may further include a second compound being a red host. The first compound may have a weight % of 1 to 40, preferably 1 to 20, more preferably 1 to 10.

The second compound as the red host may be the above-mentioned red host material.

In an aspect of the present disclosure, in the red pixel region, both the first EML 350 and the second EML 370 may include the first compound being the organometallic compound represented by Formula land the second compound being the red host. In this case, the first compound in the first EML 350 and the first compound in the second EML 370 may be same or different. In addition, the second compound in the first EML 350 and the second compound in the second EML 370 may be same or different.

In an aspect of the present disclosure, in the red pixel region, one of the first EML 350 and the second EML 370 may include the first compound being the organometallic compound represented by Formula land the second compound being the red host, and the other one of the first EML 350 and the second EML 370 may include a red dopant, which is other than the organometallic compound represented by Formula 1, and a red host. In this case, the red dopant may include at least one of a red phosphorescent material, a red fluorescent material or a red delayed fluorescent material. For example, the red dopant may be one of the above-mentioned red dopant materials.

The organometallic compound of the present disclosure is an iridium complex having a structure of Formula 1 and is included in at least one of the first and second EMLs 350 and 370 of the OLED D2. As a result, the emitting efficiency and the lifespan of the OLED D2 and the organic light emitting display device 100 are improved.

In addition, since the OLED D2 has a double stack structure including two green EMLs or two red EMLs, the color sense of the OLED D2 is improved and/or the emitting efficiency of the OLED D2 is optimized.

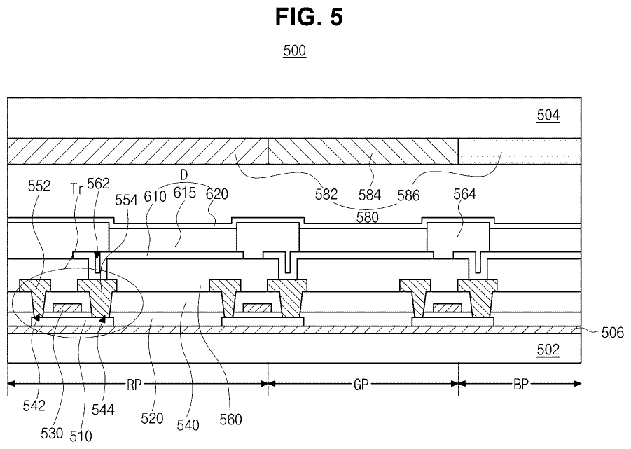

FIG. 5 is a schematic cross-sectional view illustrating an organic light emitting display device according to a fourth embodiment of the present disclosure.

As illustrated in FIG. 5, the organic light emitting display device 500 includes a first substrate 502, where a red pixel region RP, a green pixel region GP and a blue pixel region BP are defined, a second substrate 504 facing the first substrate 502, an OLED D, which is positioned between the first and second substrates 502 and 504 and providing white emission, and a color filter layer 580 between the OLED D and the second substrate 504.

Each of the first and second substrates 502 and 504 may be a glass substrate or a flexible substrate. For example, each of the first and second substrates 502 and 504 may be a polyimide (PI) substrate, a polyethersulfone (PES) substrate, a polyethylenenaphthalate (PEN) substrate, a polyethylene terephthalate (PET) substrate or a polycarbonate (PC) substrate. A buffer layer 506 is formed on the substrate 502, and the TFT Tr corresponding to each of the red, green and blue pixel regions RP, GP and BP is formed on the buffer layer 506. The buffer layer 506 may be omitted. The TFT Tr may be a driving TFT.

A semiconductor layer 510 is formed on the buffer layer 506. The semiconductor layer 510 may include an oxide semiconductor material or polycrystalline silicon.

A gate insulating layer 520 is formed on the semiconductor layer 510. The gate insulating layer 520 may be formed of an inorganic insulating material such as silicon oxide or silicon nitride.

A gate electrode 530, which is formed of a conductive material, e.g., metal, is formed on the gate insulating layer 520 to correspond to a center of the semiconductor layer 510.

An interlayer insulating layer 540, which is formed of an insulating material, is formed on the gate electrode 530. The interlayer insulating layer 540 may be formed of an inorganic insulating material, e.g., silicon oxide or silicon nitride, or an organic insulating material, e.g., benzocyclobutene or photo-acryl.

The interlayer insulating layer 540 includes first and second contact holes 542 and 544 exposing both sides of the semiconductor layer 510. The first and second contact holes 542 and 544 are positioned at both sides of the gate electrode 530 to be spaced apart from the gate electrode 530.

A source electrode 552 and a drain electrode 554, which are formed of a conductive material, e.g., metal, are formed on the interlayer insulating layer 540. The source electrode 552 and the drain electrode 554 are spaced apart from each other with respect to the gate electrode 530 and respectively contact both sides of the semiconductor layer 510 through the first and second contact holes 542 and 544.

The semiconductor layer 510, the gate electrode 530, the source electrode 552 and the drain electrode 554 constitute the TFT Tr.

A planarization layer 560 is formed on the source and drain electrodes 552 and 554 to cover the TFT Tr. The planarization layer 560 includes a drain contact hole 562 exposing the drain electrode 554 of the TFT Tr.

An OLED D is disposed on the planarization layer 560. The OLED D includes a first electrode 610, which is connected to the drain electrode 554 of the TFT Tr through the drain contact hole 562, a second electrode 620 facing the first electrode 610 and an organic light emitting layer 615 between the first and second electrodes 610 and 620.

The first electrode 610 is separately formed in each pixel region and may be an anode. The first electrode 610 includes a transparent conductive oxide material layer.

A bank layer 564 is formed on the planarization layer 560 to cover an edge of the first electrode 610. Namely, the bank layer 564 is positioned at a boundary of the pixel region and exposes a center of the first electrode 610 in each of the red, green and blue pixel regions RP, GP and BP. Since the OLED D emits the white light in each of the red, green and blue pixel regions RP, GP and BP, the organic light emitting layer 615 can be formed as a common layer in the red, green and blue pixel regions RP, GP and BP without separation in the red, green and blue pixel regions RP, GP and BP. The bank layer 564 may be formed to prevent a current leakage at an edge of the first electrode 610 and may be omitted.

As described below, the organic light emitting layer 615 is formed on the first electrode 610 and includes two or more emitting parts (units). Namely, the OLED D has a tandem structure.

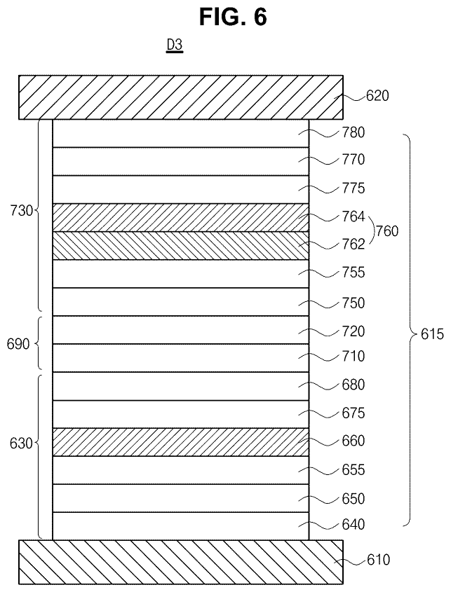

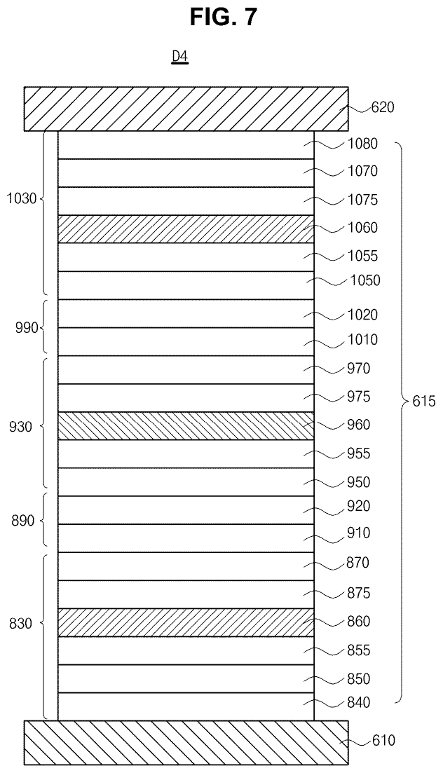

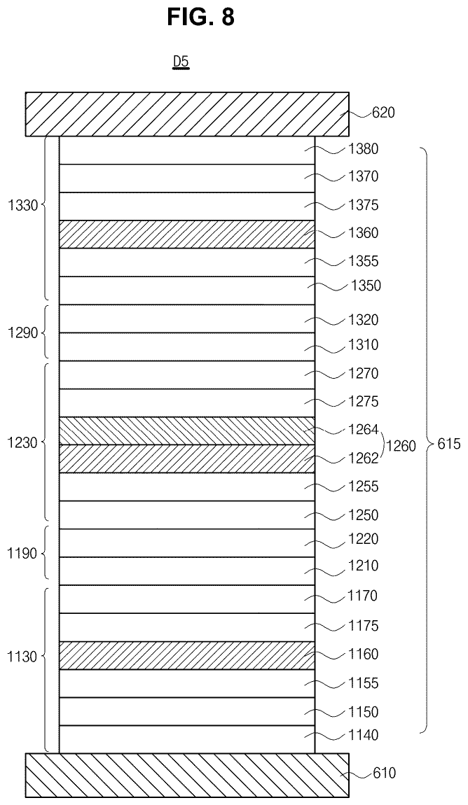

For example, as shown in FIG. 6, the organic light emitting layer 615 may include two emitting parts 630 and 730 and a CGL 690. Alternatively, as shown in FIGS. 7 and 8, the organic light emitting layer 615 may include three or more emitting parts and two or more CGLs. Each of the emitting parts includes an EML, and the CGL is positioned between adjacent emitting parts.

The second electrode 620 is formed on the organic light emitting layer 615. The second electrode 620 may cover an entire of a display area and may be a cathode.

Since the light from the organic light emitting layer 615 passes through the second electrode 620 and is incident to the color filter layer 580, the second electrode 620 has a thin profile to be light-transparent. In addition, a reflection layer may be disposed under the first electrode 610. The color filter layer 580 is disposed on or over the OLED D and includes a red color filter 582, a green color filter 584 and a blue color filter 586 respectively corresponding to the red pixel region RP, the green pixel region GP, and the blue pixel region BP. The red color filter 582 may include at least one of a red dye and a red pigment, the green color filter 584 may include at least one of a green dye and a green pigment, and the blue color filter 586 may include at least one of a blue dye and a blue pigment.

The color filter layer 580 may be attached to the OLED D using an adhesion layer.

Alternatively, the color filter layer 580 may be formed directly on the OLED D.

In FIG. 5, the light from the organic light emitting layer 615 passes through the second electrode 620, and the color filter layer 580 is disposed over the OLED D. Alternatively, the light from the organic light emitting layer 615 may pass through the first electrode 610, and the color filter layer 580 may be disposed between the OLED D and the first substrate 502.

In addition, a color conversion layer may be disposed between the OLED D and the color filter layer 580. The color conversion layer may include red, green and blue color conversion layers respectively corresponding to the red, green and blue pixel regions RP, GP and BP. The white light from the OLED D can be converted into red, green and blue light by the red, green and blue color conversion layers.

As described above, the white light from the OLED D passes through the red, green and blue color filters 582, 584 and 586 in the red, green and blue pixel regions RP, GP and BP, so that the red, green and blue light are respectively displayed in the red, green and blue pixel regions RP, GP and BP.

FIG. 6 is a schematic cross-sectional view of an OLED according to a fifth embodiment of the present disclosure.

As shown in FIG. 6, the OLED D3 according to the fifth embodiment of the present disclosure includes the first and second electrodes 610 and 620 facing each other and an organic light emitting layer 615 therebetween, and the organic light emitting layer 615 includes a first emitting part 630 between the first and second electrodes 610 and 620 and a second emitting part 730 between the first emitting part 630 and the second electrode 620. In addition, the organic light emitting layer 615 may further include a CGL 690 between the first and second emitting parts 630 and 730.

The organic light emitting display device 500 includes the red, green and blue pixel regions RP, GP and BP, and the OLED D3 is positioned in the red, green and blue pixel regions RP, GP and BP.

The first electrode 610 may be an anode, and the second electrode 620 may be a cathode. The first electrode 610 may be a reflective electrode, and the second electrode 620 may be a transparent electrode.

The first emitting part 630 includes a first EML 660.

The first emitting part 630 may further include at least one of a first HTL (e.g., a lower HTL) 650 under the first EML 660 and a first ETL (e.g., a lower ETL) 670 on the first EML 660. In addition, the first emitting part 630 may further include an HIL 640 under the first HTL 650. Moreover, the first emitting part 630 may further include at least one of a first EBL (e.g., a lower EBL) 655 between the first HTL 650 and the first EML 660 and a first HBL (e.g., a lower HBL) 675 between the first EML 660 and the first ETL 670.

The second emitting part 730 includes a second EML 760, and the second EML 760 includes a lower EML 762 and an upper EML 764 between the lower EML 762 and the second electrode 620. One of the lower and upper EMLs 762 and 764 is a red EML, and the other one of the lower and upper EMLs 762 and 764 is a green EML. For example, the upper EML 764 may be a red EML.

The second emitting part 730 may further include at least one of a second HTL (e.g., an upper HTL) 750 under the second EML 760 and a second ETL (e.g., an upper ETL) 770 on the second EML 760.

In addition, the second emitting part 730 may further include an EIL 780 on the second ETL 770. Moreover, the second emitting part 730 may further include at least one of a second EBL (e.g., an upper EBL) 755 between the second HTL 750 and the second EML 760 and a second HBL (e.g., an upper HBL) 775 between the second EML 760 and the second ETL 770. The HIL 640 may include the above-mentioned hole injection material and may have a thickness of 10 to 100 nm. Each of the first and second HTLs 650 and 750 may include the above-mentioned hole transporting material and may have a thickness of 30 to 150 nm, preferably 50 to 120 nm.

Each of the first and second ETLs 680 and 770 may include the above-mentioned electron transporting material and may have a thickness of 10 to 100 nm, preferably 10 to 50 nm. The EIL 780 may include the above-mentioned electron injection material and may have a thickness of 0.1 to 10 nm, preferably 0.5 to 5 nm.

In FIG. 6, the ETL 770 and the EIL 780 as separated elements are formed. Alternatively, an electron transporting-injection layer as a single layer having an electron transporting function and an electron injection function may be formed. In this case, the electron transporting-injection layer may include an electron transporting material and an electron injection material and may have a thickness of 10 to 50 nm. For example, the electron transporting-injection layer may include a compound in Formula 7 and a compound in Formula 8, and a weight % of the compound in Formula 7 and a weight % of the compound in Formula 8 may be same. Each of the first and second EBLs 655 and 755 may include the above-mentioned electron blocking material, and each of the first and second HBLs 675 and 775 may include the above-mentioned hole blocking material.

The CGL 690 is positioned between the first and second emitting parts 630 and 730. The CGL 690 includes an N-type CGL 710 positioned to be closer to the first emitting part 630 and a P-type CGL 720 positioned to be closer to the second emitting part 730. The N-type CGL 710 provides an electron into the first emitting part 630, and the P-type CGL 720 provides a hole into the second emitting part 730.

The N-type CGL 710 may include the above-mentioned N-type charge generation material, and the P-type CGL 720 may include the above-mentioned P-type charge generation material. The first EML 660 may be a blue EML. The first EML 660 may include a blue host and a blue dopant. For example, in the first EML 660, the blue dopant may have a weight % of 1 to 40, preferably 1 to 20, more preferably 1 to 10.

The blue host may include a blue host material being one of mCP, mCP-CN, mCBP, CBP-CN, CBP, 9-(3-(9H-Carbazol-9-yl)phenyl)-3-(diphenylphosphoryl)-9H-carbazole (mCPPO1), 3,5-di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spirobifluoren-2-yl-diphenyl-phosphine oxide (SPPO1), and 9,9′-(5-(triphenylsilyl)-1,3-phenylene)bis(9H-carbazole) (SimCP), but it is not limited thereto.

The blue dopant may include a blue dopant material being one of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,5,8,11-Tetra-tetr-butylperylene (TBPe), Bepp2, 9-(9-phenylcarbazole-3-yl)-10-(naphthalene-1-yl)anthracene (PCAN), mer-tris(1-phenyl-3-methylimidazolin-2-ylidene-C,C(2)′ iridium(III) (mer-Ir(pmi)₃), fac-tris(1,3-diphenyl-benzimidazolin-2-ylidene-C,C(2)′ iridium(III) (fac-Ir(dpbic)₃), bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃), and bis[2-(4,6-difluorophenyl)pyridinato-C²,N](picolinato)iridium(III); FIrpic), but it is not limited thereto. In an aspect to the present disclosure, the first EML 660 may include an anthracene derivative as a blue host and a boron derivative as a blue dopant.

At least one of the lower EML 762 and the upper EML 764 includes the organometallic compound represented by Formula 1 as a first compound.

For example, the upper EML 764 being the red EML may include the organometallic compound represented by Formula 1 as the first compound, i.e., a red dopant. In addition, the upper EML 764 may further include a second compound as a red host. In the upper EML 764 being the red EML, a weight % of the first compound is smaller than that of the second compound. For example, in the upper EML 764 being the red EML, the first compound may have a weight % of 1 to 40, preferably 1 to 20, more preferably 1 to 10.

The second compound, i.e., the red host, may include the above-mentioned red host material, but it is not limited thereto.

For example, the lower EML 762 being the green EML may include the organometallic compound represented by Formula 1 as the first compound, i.e., a green dopant. In addition, the lower EML 762 may further include a second compound as a green host. In the lower EML 762 being the green EML, a weight % of the first compound is smaller than that of the second compound. For example, in the lower EML 762 being the green EML, the first compound may have a weight % of 1 to 40, preferably 1 to 20, more preferably 1 to 10. The second compound, i.e., the green host, may include the above-mentioned green host material, but it is not limited thereto.

When both the lower EML 762 being the green EML and the upper EML 764 being the red EML include the organometallic compound represented by Formula 1 as a first compound, the first compound, i.e., the green dopant, in the lower EML 762 and the first compound, i.e., the red dopant, in the upper EML 764 may have a difference in the auxiliary ligand in Formula 1 and emit light having different wavelength ranges.

Alternatively, the upper EML 764 being the red EML may include a red dopant other than the organometallic compound represented by Formula 1. In this case, the red dopant may include at least one of a red phosphorescent material, a red fluorescent material and a red delayed fluorescent material. For example, the red dopant may be the above-mentioned green dopant material, but it is not limited thereto.

In FIG. 6, the first emitting part 630 includes the blue EML, and the second emitting part 730 includes the red and green EMLs. Alternatively, the first emitting part 630 may include the red and green EMLs, and the second emitting part 730 may include the blue EML.

In FIG. 6, the second EML 760 has a double-layered structure including the lower EML 762, which is one of the red and green EMLs, and the upper EML 764, which is the other one of the red and green EMLs. Alternatively, the second EML 760 may further include a yellow-green EML between the red and green EMLs 762 and 764 to have a triple-layered structure. In FIG. 6, the organic light emitting layer 615 includes the first emitting part 630 including the first EML 660 and the second emitting part 730 including the second EML 760 so that the OLED D3 has a two-stack structure. Alternatively, the organic light emitting layer 615 may further include a third emitting part including a blue EML and positioned between the second emitting part 730 and the second electrode 620 so that the OLED D3 may have a triple-layered structure. In this case, a CGL may be disposed between the second emitting part 730 and the third emitting part. In addition, the second EML 760 may further include a yellow-green EML between the lower EML 762, which is one of the red and green EMLs, and the upper EML 764, which is the other one of the red and green EMLs, to have a triple-layered structure.

As described above, the OLED D3 includes the first emitting part 630 including the first EML 660 being the blue EML and the second emitting part 730 including the red and green EMLs 762 and 764. As a result, the OLED D3 provides white emission. The OLED D3 is applied to the organic light emitting display device 500 including the color filter layer 580 so that the organic light emitting display device 500 can provide a full-color image.

In the OLED D3 of the present disclosure, at least one of the lower and upper EMLs 762 and 764 of the second EML 760 includes the organometallic compound of the present disclosure. As a result, the emitting efficiency and the lifespan of the OLED D3 are improved.

FIG. 7 is a schematic cross-sectional view of an OLED according to a sixth embodiment of the present disclosure.

As shown in FIG. 7, the OLED D4 according to the sixth embodiment of the present disclosure includes the first and second electrodes 610 and 620 facing each other and an organic light emitting layer 615 therebetween, and the organic light emitting layer 615 includes a first emitting part 830 between the first and second electrodes 610 and 620, a second emitting part 930 between the first emitting part 830 and the second electrode 620 and a third emitting part 1030 between the second emitting part 930 and the second electrode 620. In addition, the organic light emitting layer 615 may further include a first CGL 890 between the first and second emitting parts 830 and 930 and a second CGL 990 between the second and third emitting parts 930 and 1030.

The organic light emitting display device 500 includes the red, green and blue pixel regions RP, GP and BP, and the OLED D4 is positioned in the red, green and blue pixel regions RP, GP and BP.

The first electrode 610 may be an anode, and the second electrode 620 may be a cathode. The first electrode 610 may be a reflective electrode, and the second electrode 620 may be a transparent electrode.

The first emitting part 830 includes a first EML 860.

The first emitting part 830 may further include at least one of a first HTL 850 under the first EML 860 and a first ETL 870 on the first EML 860.

In addition, the first emitting part 830 may further include an HIL 840 under the first HTL 850. Moreover, the first emitting part 830 may further include at least one of a first EBL 855 between the first HTL 850 and the first EML 860 and a first HBL 875 between the first EML 860 and the first ETL 870.

The second emitting part 930 includes a second EML 960.

In addition, the second emitting part 930 may further include at least one of a second HTL 950 under the second EML 960 and a second ETL 970 on the second EML 960.

Moreover, the second emitting part 930 may further include at least one of a second EBL 955 between the second HTL 950 and the second EML 960 and a second HBL 975 between the second EML 960 and the second ETL 970.

The third emitting part 1030 includes a third EML 1060.

In addition, the third emitting part 1030 may further include an EIL 1080 on the second ETL 1070. Moreover, the third emitting part 1030 may further include at least one of a third EBL 1055 between the third HTL 1050 and the third EML 1060 and a third HBL 1075 between the third EML 1060 and the third ETL 1070.

The HIL 840 may include the above-mentioned hole injection material, and each of the first to third HTLs 850, 950 and 1050 may include the above-mentioned hole transporting material.

Each of the first to third ETLs 870, 970 and 1070 may include the above-mentioned electron transporting material, and the EIL 1080 may include the above-mentioned electron injection material.

Each of the first to third EBLs 855, 955 and 1055 may include the above-mentioned electron blocking material, and each of the first to third HBLs 875, 975 and 1075 may include the above-mentioned hole blocking material.

The first CGL 890 is positioned between the first and second emitting parts 830 and 930, and the second CGL 990 is positioned between the second and third emitting parts 930 and 1030. The first CGL 890 includes a first N-type CGL 910 positioned to be closer to the first emitting part 830 and a first P-type CGL 920 positioned to be closer to the second emitting part 930. The second CGL 990 includes a second N-type CGL 1010 positioned to be closer to the second emitting part 930 and a second P-type CGL 1020 positioned to be closer to the third emitting part 1030. The first and second N-type CGLs 910 and 1010 respectively provide an electron into the first and second emitting parts 830 and 930, and the first and second P-type CGL 920 and 1020 respectively provide a hole into the second and third emitting parts 930 and 1030. Each of the first and second N-type CGLs 910 and 1010 may include the above-mentioned N-type charge generation material, and each of the first and second P-type CGL 920 and 1020 may include the above-mentioned P-type charge generation material.

One of the first third EMLs 860, 960 and 1060 is a red EML, another one of the first third EMLs 860, 960 and 1060 is a green EML, and the other one of the first third EMLs 860, 960 and 1060 is a blue EML. Accordingly, the OLED 500 can provide white emission.

For example, the first EML 860 may be a red EML, the second EML 960 may be a green EML, and the third EML 1060 may be a blue EML.

In this case, the first EML 860 being the red EML may include the organometallic compound represented by Formula 1 as the first compound, i.e., a red dopant. In addition, the first EML 860 may further include a second compound as a red host. In the first EML 860, a weight % of the first compound is smaller than that of the second compound. For example, in the first EML 860, the first compound may have a weight % of 1 to 40, preferably 1 to 20, more preferably 1 to 10.

The second compound, i.e., the red host, may include the above-mentioned red host material. The second EML 960 being the green EML may include the organometallic compound represented by Formula 1 as the first compound, i.e., a green dopant. In addition, the second EML 960 may further include a second compound as a green host. In the second EML 960, a weight % of the first compound is smaller than that of the second compound. For example, in the second EML 960, the first compound may have a weight % of 1 to 40, preferably 1 to 20, more preferably 1 to 10.

The second compound, i.e., the green host, may include the above-mentioned green host material.

When both the first EML 860 being the red EML and the second EML 960 being the green EML include the organometallic compound represented by Formula 1 as a first compound, the first compound, i.e., the red dopant, in the first EML 860 and the first compound, i.e., the green dopant, in the second EML 960 may have a difference in the auxiliary ligand in Formula 1 and emit light having different wavelength ranges.

Alternatively, the first EML 860 being the red EML may include a red dopant other than the organometallic compound represented by Formula 1. In this case, the red dopant may include at least one of a red phosphorescent material, a red fluorescent material and a red delayed fluorescent material. For example, the red dopant may be the above-mentioned red dopant material.

The third EML 1060 may be a blue EML. The third EML 1060 may include a blue host and a blue dopant. For example, in the third EML 1060, the blue dopant may have a weight % of 1 to 40, preferably 1 to 20, more preferably 1 to 10.

The blue host may be the above-mentioned blue host material, and the blue dopant may be the above-mentioned blue dopant material.

As described above, the OLED D4 includes the first emitting part 830 including the first EML 860, which may be the red EML, the second emitting part 930 including the second EML 960, which may be the green EML, and the third emitting part 1030 including the third EML 1060, which may be the blue EML. As a result, the OLED D4 provides white emission. The OLED D4 is applied to the organic light emitting display device 500 including the color filter layer 580 so that the organic light emitting display device 500 can provide a full-color image.

In the OLED D4 of the present disclosure, at least one of the first and second EMLs 860 and 930 includes the organometallic compound of the present disclosure. As a result, the emitting efficiency and the lifespan of the OLED D4 are improved.

FIG. 8 is a schematic cross-sectional view of an OLED according to a seventh embodiment of the present disclosure.

As shown in FIG. 8, the OLED D5 according to the seventh embodiment of the present disclosure includes the first and second electrodes 610 and 620 facing each other and an organic light emitting layer 615 therebetween, and the organic light emitting layer 615 includes a first emitting part 1130 between the first and second electrodes 610 and 620, a second emitting part 1230 between the first emitting part 1130 and the second electrode 620 and a third emitting part 1330 between the second emitting part 1230 and the second electrode 620. In addition, the organic light emitting layer 615 may further include a first CGL 1190 between the first and second emitting parts 1130 and 1230 and a second CGL 1290 between the second and third emitting parts 1230 and 1330.

The organic light emitting display device 500 includes the red, green and blue pixel regions RP, GP and BP, and the OLED D5 is positioned in the red, green and blue pixel regions RP, GP and BP.

The first electrode 610 may be an anode, and the second electrode 620 may be a cathode. The first electrode 610 may be a reflective electrode, and the second electrode 620 may be a transparent electrode.

The first emitting part 1130 includes a first EML 1160.

The first emitting part 1130 may further include at least one of a first HTL 1150 under the first EML 1160 and a first ETL 1170 on the first EML 1160.

In addition, the first emitting part 1130 may further include an HIL 1140 under the first HTL 1150. Moreover, the first emitting part 1130 may further include at least one of a first EBL 1155 between the first HTL 1150 and the first EML 1160 and a first HBL 1175 between the first EML 1160 and the first ETL 1170.

The second emitting part 1230 includes a second EML 1260.

In addition, the second emitting part 1230 may further include at least one of a second HTL 1250 under the second EML 1260 and a second ETL 1270 on the second EML 1260.

Moreover, the second emitting part 1230 may further include at least one of a second EBL 1255 between the second HTL 1250 and the second EML 1260 and a second HBL 1275 between the second EML 1260 and the second ETL 1270.

The third emitting part 1330 includes a third EML 1360.

In addition, the third emitting part 1330 may further include an EIL 1380 on the second ETL 1370. Moreover, the third emitting part 1330 may further include at least one of a third EBL 1355 between the third HTL 1350 and the third EML 1360 and a third HBL 1375 between the third EML 1360 and the third ETL 1370.

The HIL 1140 may include the above-mentioned hole injection material, and each of the first to third HTLs 1150, 1250 and 1350 may include the above-mentioned hole transporting material.

Each of the first to third ETLs 1170, 1270 and 1370 may include the above-mentioned electron transporting material, and the EIL 1380 may include the above-mentioned electron injection material.

Each of the first to third EBLs 1155, 1255 and 1355 may include the above-mentioned electron blocking material, and each of the first to third HBLs 1175, 1275 and 1375 may include the above-mentioned hole blocking material.

The first CGL 1190 is positioned between the first and second emitting parts 1130 and 1230, and the second CGL 1290 is positioned between the second and third emitting parts 1230 and 1330. The first CGL 1190 includes a first N-type CGL 1210 positioned to be closer to the first emitting part 1130 and a first P-type CGL 1220 positioned to be closer to the second emitting part 1230. The second CGL 1290 includes a second N-type CGL 1310 positioned to be closer to the second emitting part 1230 and a second P-type CGL 1320 positioned to be closer to the third emitting part 1330. The first and second N-type CGLs 1210 and 1310 respectively provide an electron into the first and second emitting parts 1130 and 1230, and the first and second P-type CGL 1220 and 1320 respectively provide a hole into the second and third emitting parts 1230 and 1330.

Each of the first and second N-type CGLs 1210 and 1310 may include the above-mentioned N-type charge generation material, and each of the first and second P-type CGL 1220 and 1320 may include the above-mentioned P-type charge generation material.

Each of the first and third EMLs 1160 and 1360 may be a blue EML. Each of the first and third EMLs 1160 and 1360 may include a blue host and a blue dopant. The blue host in the first EML 1160 and the blue host in the third EML 1360 may be same or different, and the blue dopant in the first EML 1160 and the blue dopant in the third EML 1360 may be same or different. For example, in each of the first and third EMLs 1160 and 1360, the blue dopant may have a weight % of 1 to 40, preferably 1 to 20, more preferably 1 to 10.

The blue host may be the above-mentioned blue host material, and the blue dopant may be the above-mentioned blue dopant material.

The second EML 1260 includes a lower EML 122 between the second EBL 1255 and the second HBL 1275 and an upper EML 1264 between the lower EML 1262 and the second HBL 1275. One of the lower and upper EMLs 1262 and 1264 is a red EML, and the other one of the lower and upper EMLs 1262 and 1264 is a green EML. For example, the lower EML 1262 may be a red EML.

At least one of the lower EML 1262 and the upper EML 1264 includes the organometallic compound represented by Formula 1 as a first compound.

For example, the lower EML 1262 being the red EML may include the organometallic compound represented by Formula 1 as the first compound, i.e., a red dopant. In addition, the lower EML 1262 may further include a second compound as a red host. In the lower EML 1262 being the red EML, a weight % of the first compound is smaller than that of the second compound. For example, in the lower EML 1262 being the red EML, the first compound may have a weight % of 1 to 40, preferably 1 to 20, more preferably 1 to 10.

The second compound, i.e., the red host, may include the above-mentioned red host material. For example, the upper EML 1264 being the green EML may include the organometallic compound represented by Formula 1 as the first compound, i.e., a green dopant. In addition, the upper EML 1264 may further include a second compound as a green host. In the upper EML 1264 being the green EML, a weight % of the first compound is smaller than that of the second compound. For example, in the upper EML 1264 being the green EML, the first compound may have a weight % of 1 to 40, preferably 1 to 20, more preferably 1 to 10. The second compound, i.e., the green host, may include the above-mentioned green host material.

When both the lower EML 1262 being the red EML and the upper EML 1264 being the green EML include the organometallic compound represented by Formula 1 as a first compound, the first compound, i.e., the red dopant, in the lower EML 1262 and the first compound, i.e., the green dopant, in the upper EML 1264 may have a difference in the auxiliary ligand in Formula 1 and emit light having different wavelength ranges.

Alternatively, the lower EML 1262 being the red EML may include a red dopant other than the organometallic compound represented by Formula 1. In this case, the red dopant may include at least one of a red phosphorescent material, a red fluorescent material and a red delayed fluorescent material. For example, the red dopant may be the above-mentioned red dopant material.

In FIG. 8, the second EML 1260 has a double-layered structure of the lower EML 1262 being the red EML and the upper EML 1264 being the green EML.

Alternatively, the second EML 1260 may further include a yellow-green EML between the lower and upper EMLs 1262 and 1264 to have a triple-layered structure.

The yellow-green EML may include the organometallic compound represented by Formula 1 as a yellow-green dopant. In addition, the yellow-green EML may further include a yellow-green host. For example, in the yellow-green EML, the yellow-green dopant may have a weight % of 1 to 40, preferably 1 to 20, more preferably 1 to 10.

Alternatively, the yellow-green EML may include a yellow-green dopant other than the organometallic compound represented by Formula 1. In this case, the yellow-green dopant may include at least one of a yellow-green phosphorescent material, a yellow-green fluorescent material and a yellow-green delayed fluorescent material.

For example, the yellow-green dopant may be one of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)iridium(III) (Ir(BT)₂(acac)), bis(2-(9,9-diethytl-fluoren-2-yl)-1-phenyl-1H-benzo[d]imdiazolato)(acetylacetonate)iridium(III) (Ir(fbi)₂(acac)), bis(2-phenylpyridine)(3-(pyridine-2-yl)-2H-chromen-2-onate)iridium(TT) (fac-Ir(ppy)₂Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(ITT) (PO-01).

As described above, the OLED D5 includes the first and third emitting parts 1130 and 1330 respectively including the first and third EMLs 1160 and 1360, each of which is the blue EML, and the second emitting part 1230 including the red and green EMLs. As a result, the OLED D5 provides white emission. The OLED D5 is applied to the organic light emitting display device 500 including the color filter layer 580 so that the organic light emitting display device 500 can provide a full-color image.

In the OLED D5 of the present disclosure, at least one of the lower and upper EMLs 1262 and 1264 of the second EML 1260 includes the organometallic compound of the present disclosure. As a result, the emitting efficiency and the lifespan of the OLED D5 are improved.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organometallic compound represented by Formula 1: 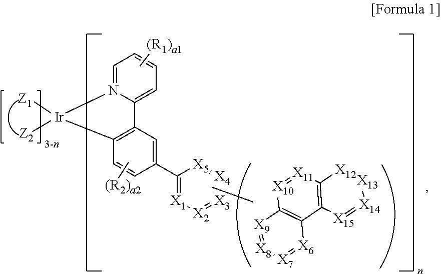
wherein a1 is an integer of 0 to 4, a2 is an integer of 0 to 3, n is an integer of 1 to 3,
each of X₁ to X₅ is N or CR₃, and at least one of X₁ to X₅ is CR₃,
each of X₆ to X₁₅ is N or CR₄, and at least one of X₆ to X₁₅ is N, at least one of X₆ to X₁₅ is CR₄,
each of Z₁ and Z₂ is one of N, CR₅ and 0,
each of R₁ and R₂ is independently selected from the group consisting of deuterium, halogen, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryloxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group, and
each of R₃ to R₅ is independently selected from the group consisting of hydrogen, deuterium, halogen, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryloxy group, a substituted or unsubstituted C1 to C20 alkylamino group, a substituted or unsubstituted C6 to C30 arylamino group, a substituted or unsubstituted C1 to C20 alkylsilyl group, a substituted or unsubstituted C6 to C30 arylsilyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group.

2. The organometallic compound according to claim 1, wherein the Formula 1 is represented by Formula 1a or Formula 1b: 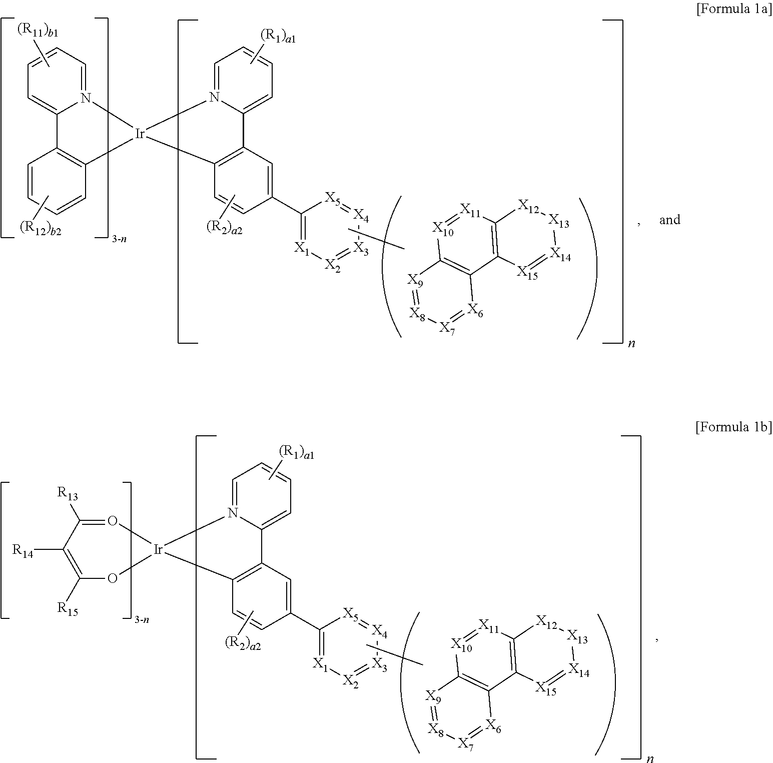
wherein in the Formula 1a,
each of b1 and b2 is independently an integer of 0 to 4, and
each of R₁₁ and R₁₂ is independently selected from the group consisting of deuterium, a substituted or unsubstituted C6 to C30 aryl group and a substituted or unsubstituted C3 to C30 heteroaryl group, or optionally, adjacent two R₁ and/or adjacent two R₁₂ are combined to form a ring,
wherein in the Formula 1b,
each of R₁₃, R₁₄ and R₁₅ is independently selected from the group consisting of hydrogen, deuterium, a substituted or unsubstituted C6 to C30 aryl group and a substituted or unsubstituted C3 to C30 heteroaryl group, or optionally, adjacent two of R₁₃, R₁₄ and R₁₅ are combined to each other to form a ring, and
wherein in each of Formulas 1a and Tb, definitions of a1, a2, a3, n, X, X₁ to X₄, and R₁ to R₅ are same as those in Formula 1.

3. The organometallic compound according to claim 1, wherein the Formula 1 is represented by Formula 2-1: 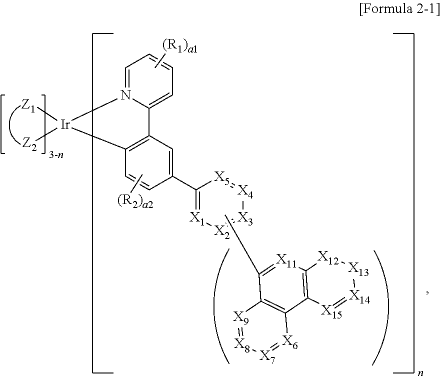
wherein in the Formula 2-1, the definitions of a1, a2, n, X₁ to X₉, X₁₁ to X₁₅, R₁ to R₅, Z₁ and Z₂ are same as those in Formula 1.

4. The organometallic compound according to claim 1, wherein the Formula 1 is represented by Formula 2-2: 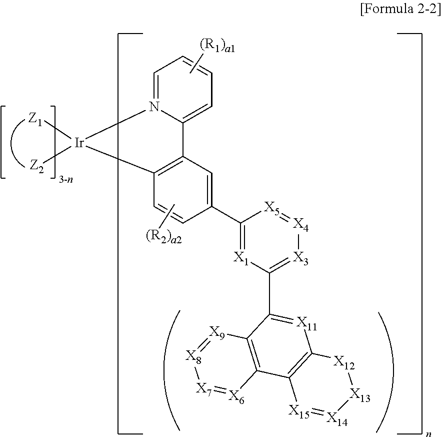
wherein in the Formula 2-2, the definitions of a1, a2, X₁, X₃ to X₉, X₁ to X₅, R₁ to R₅, Z₁ and Z₂ are same as those in Formula 1.

5. The organometallic compound according to claim 1, wherein the organometallic compound is one of compounds in Formula 3:

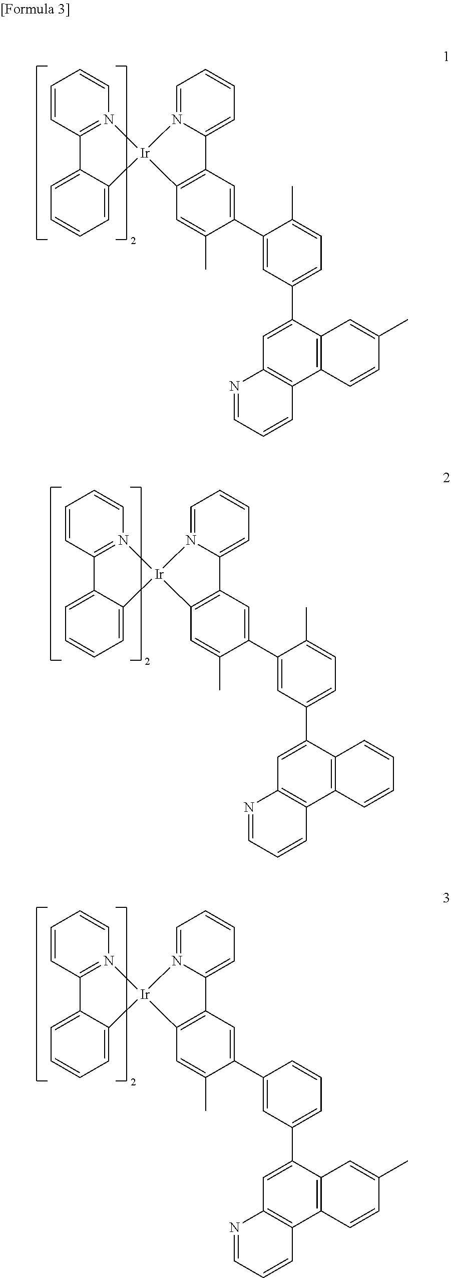

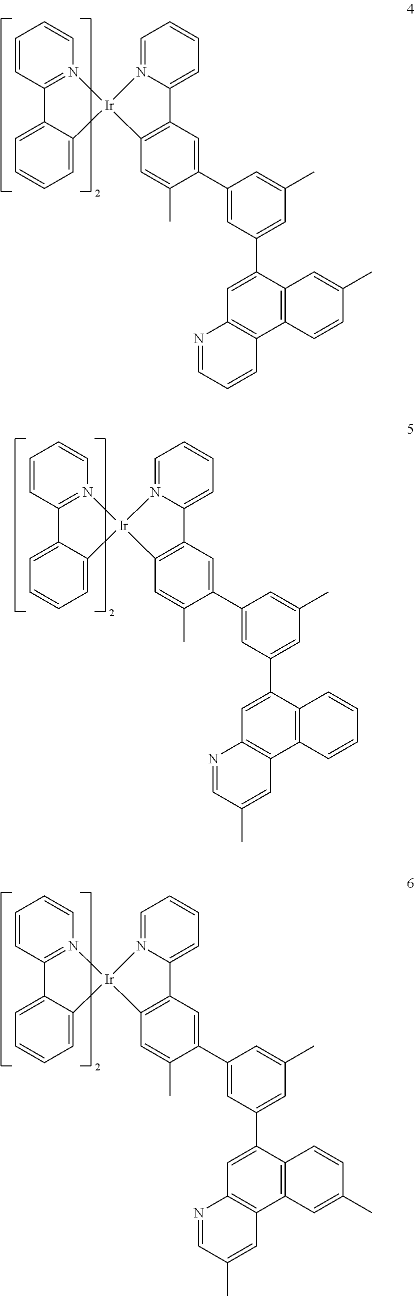

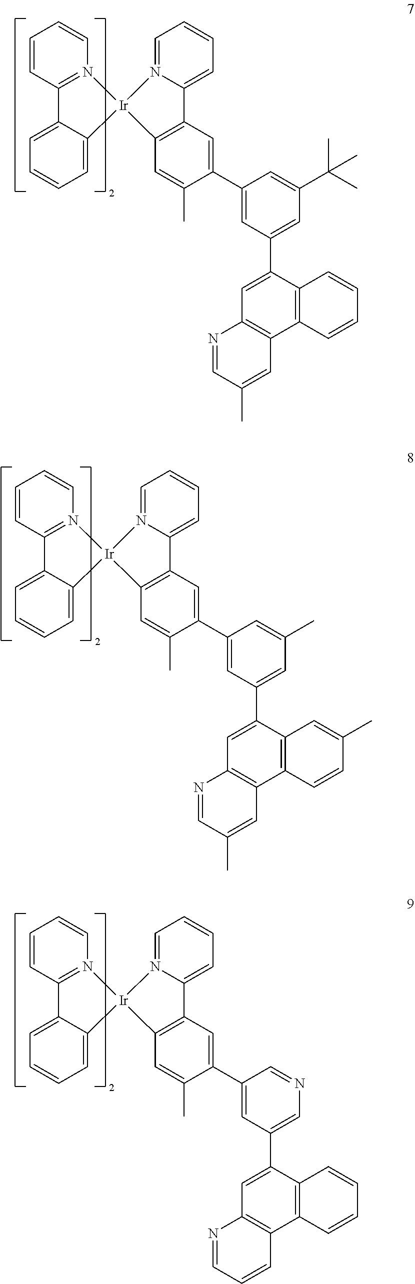

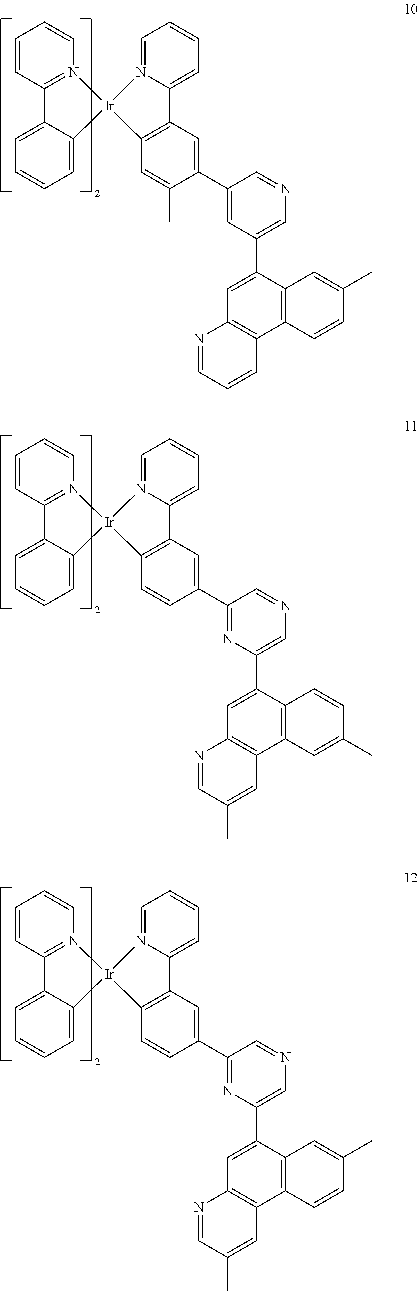

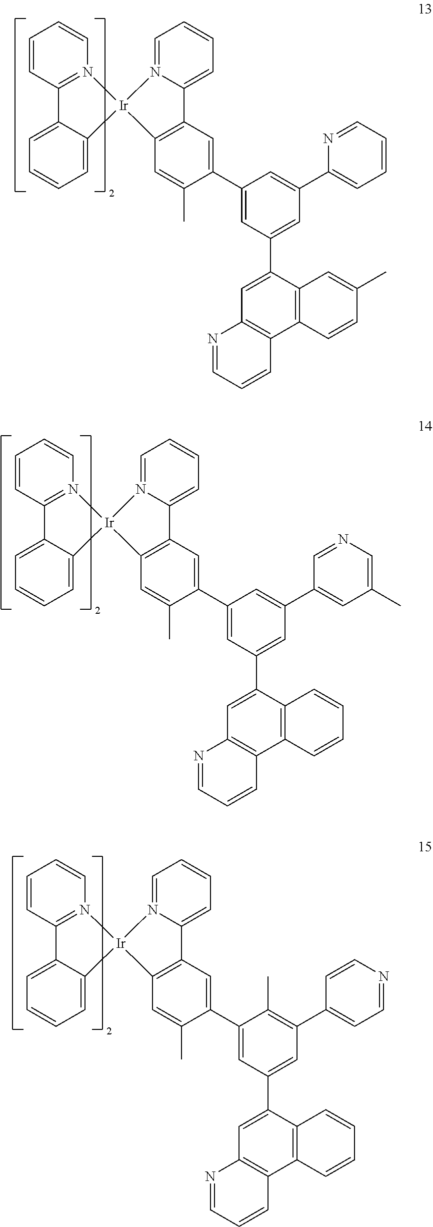

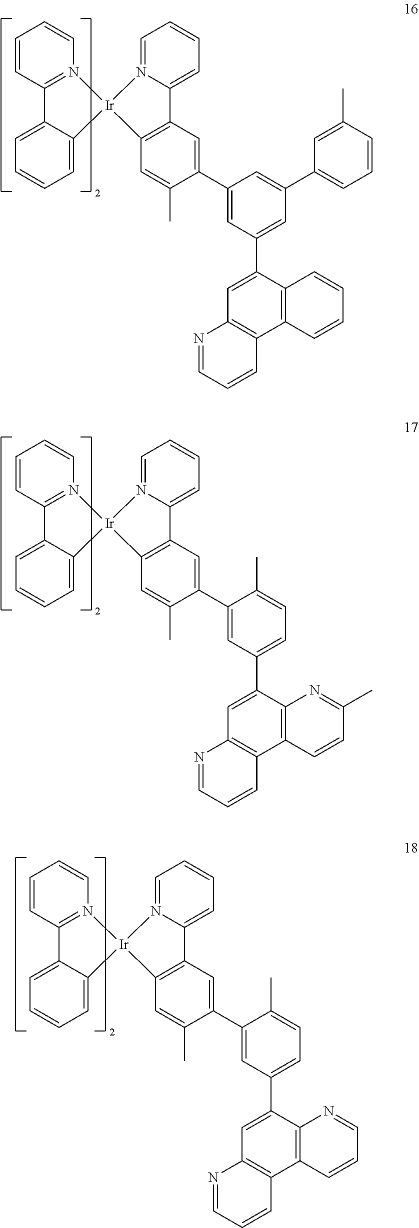

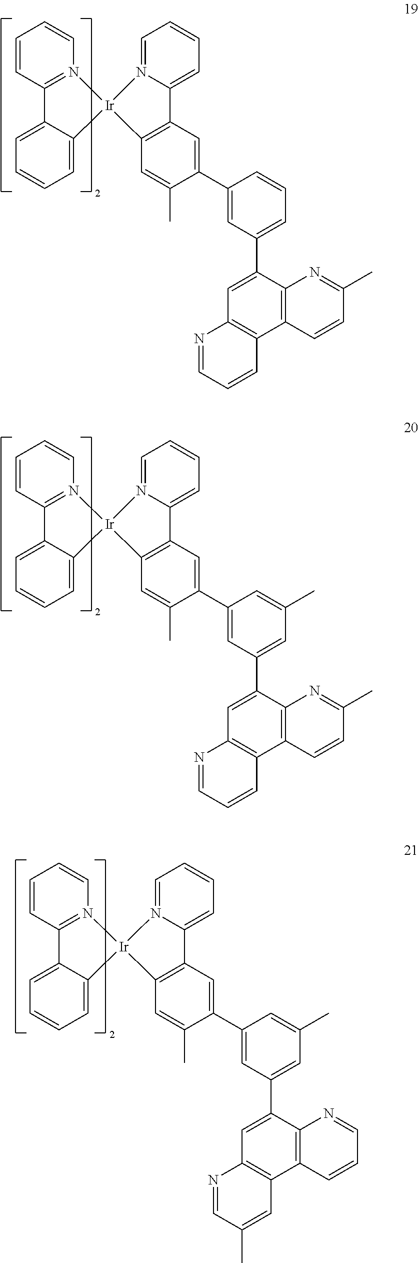

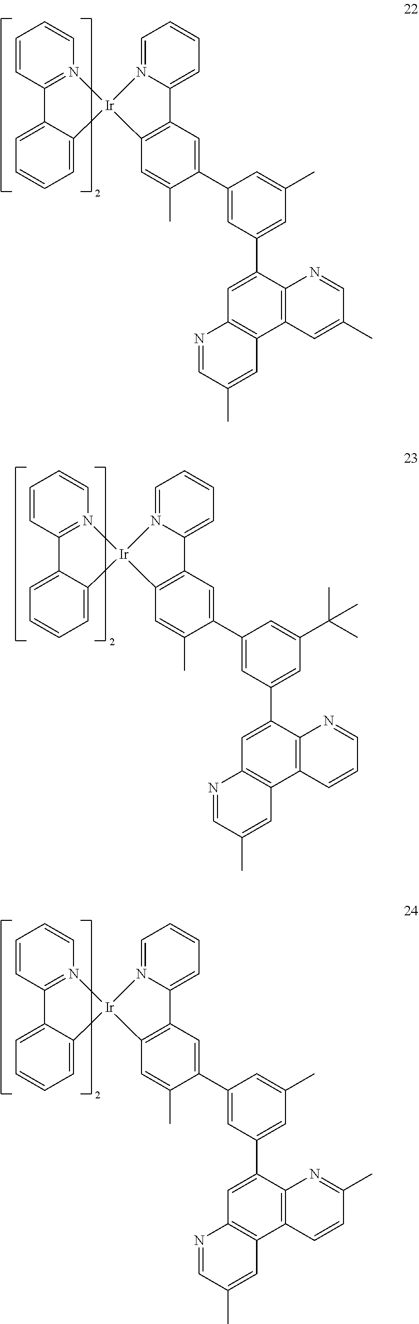

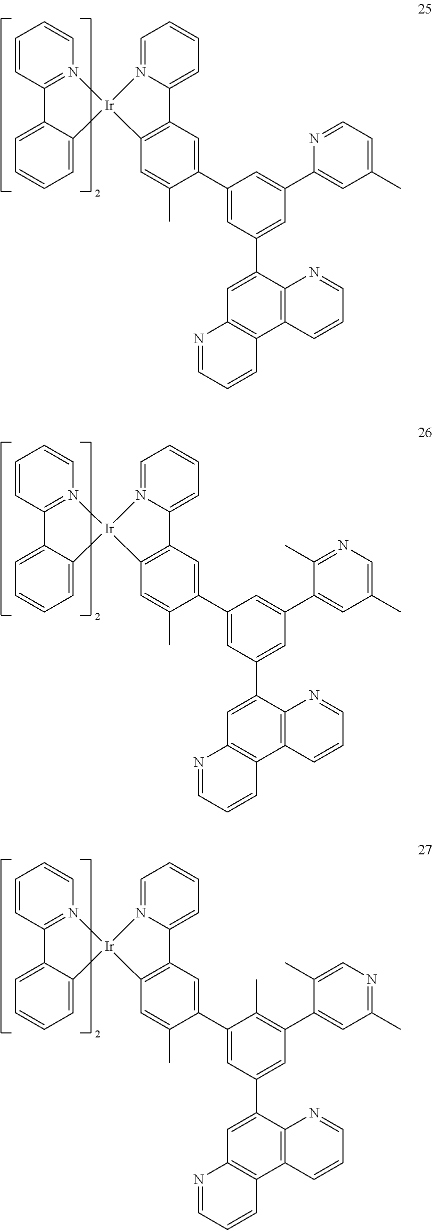

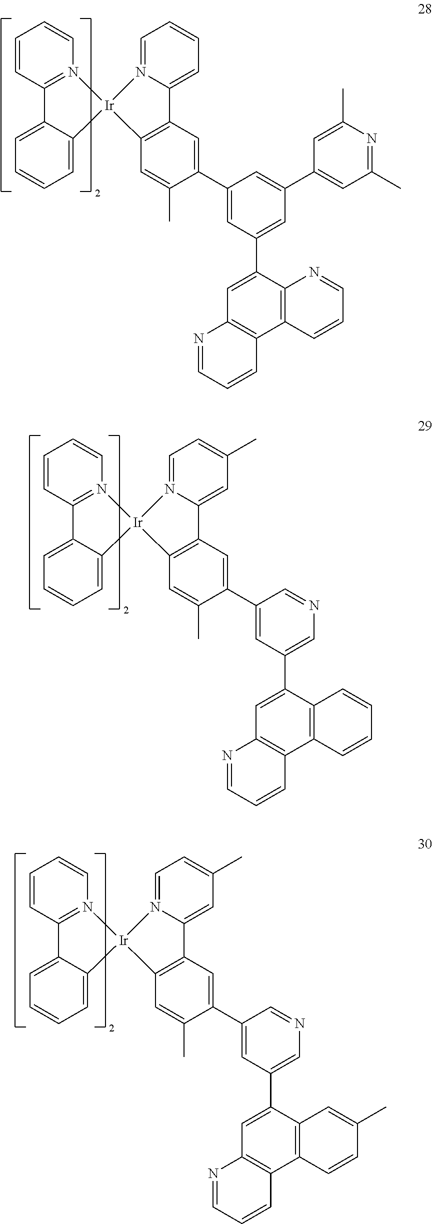

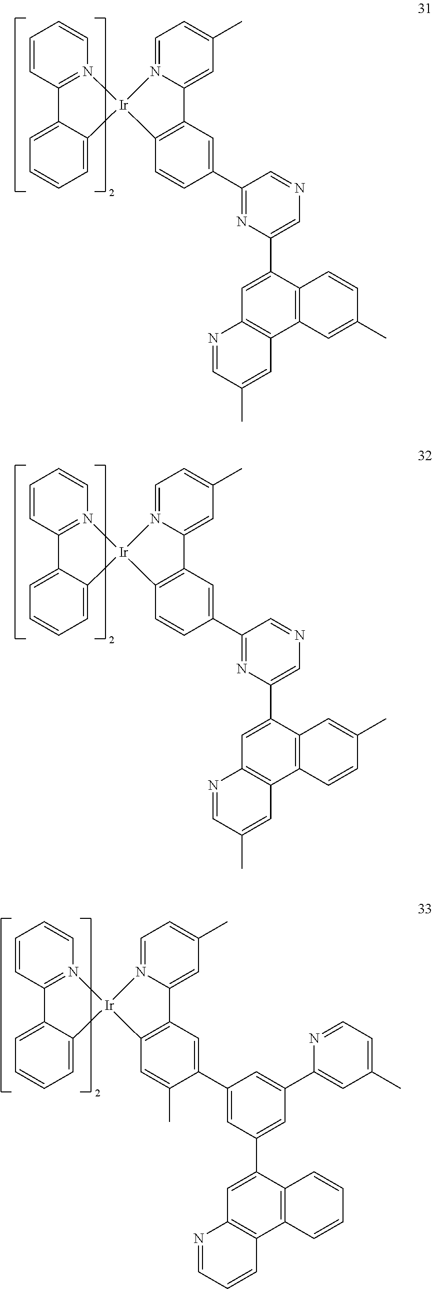

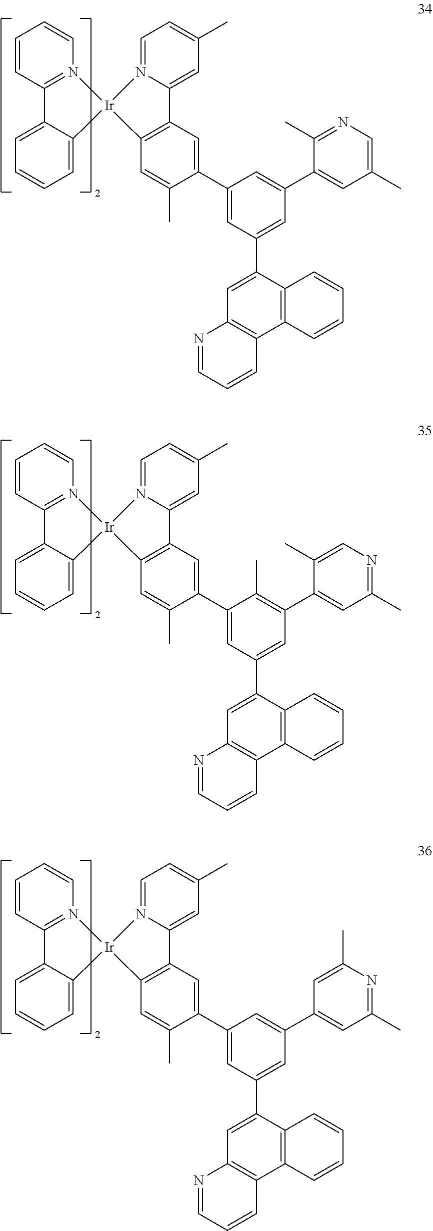

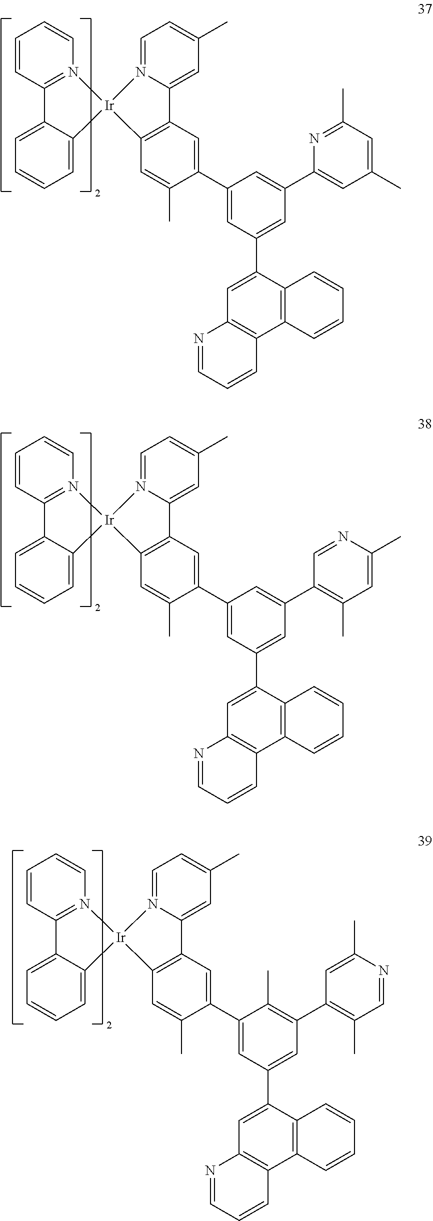

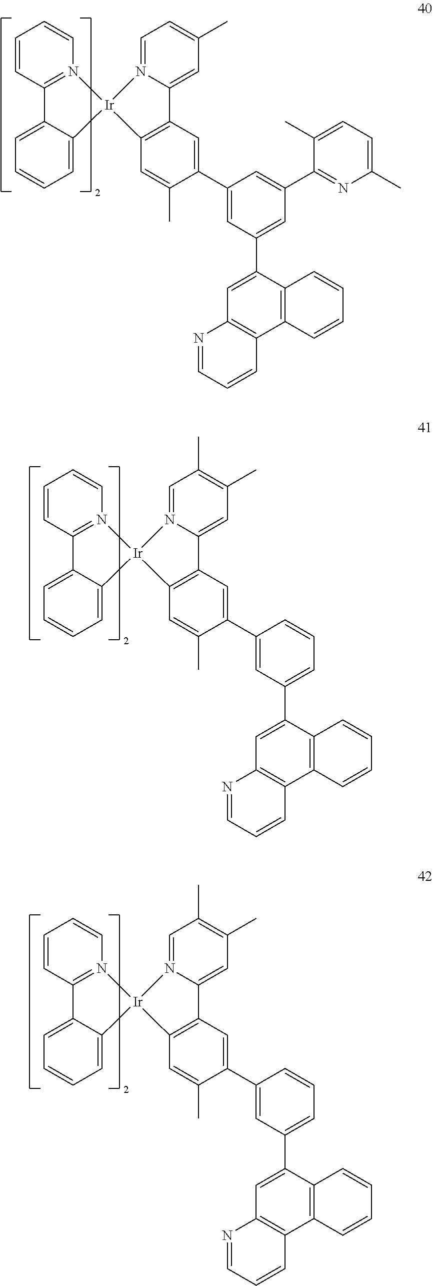

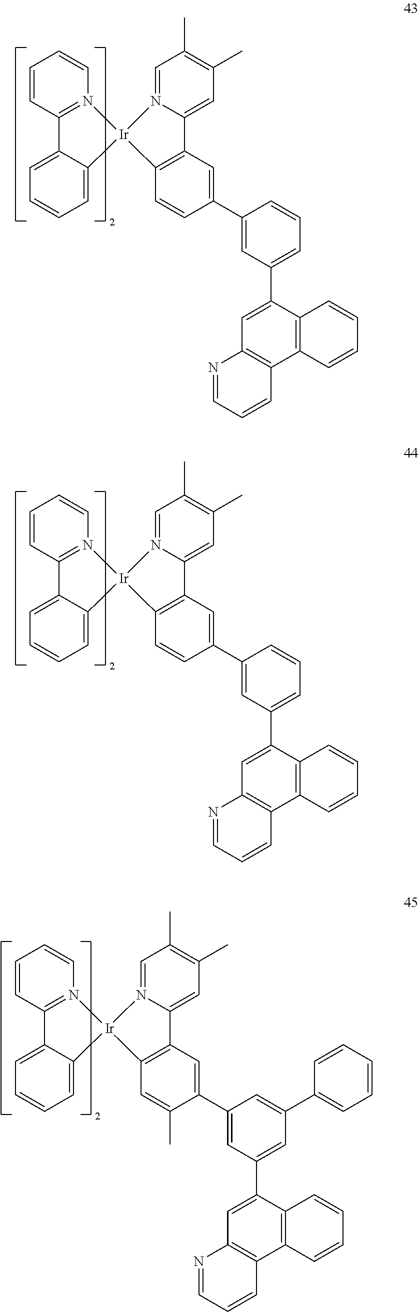

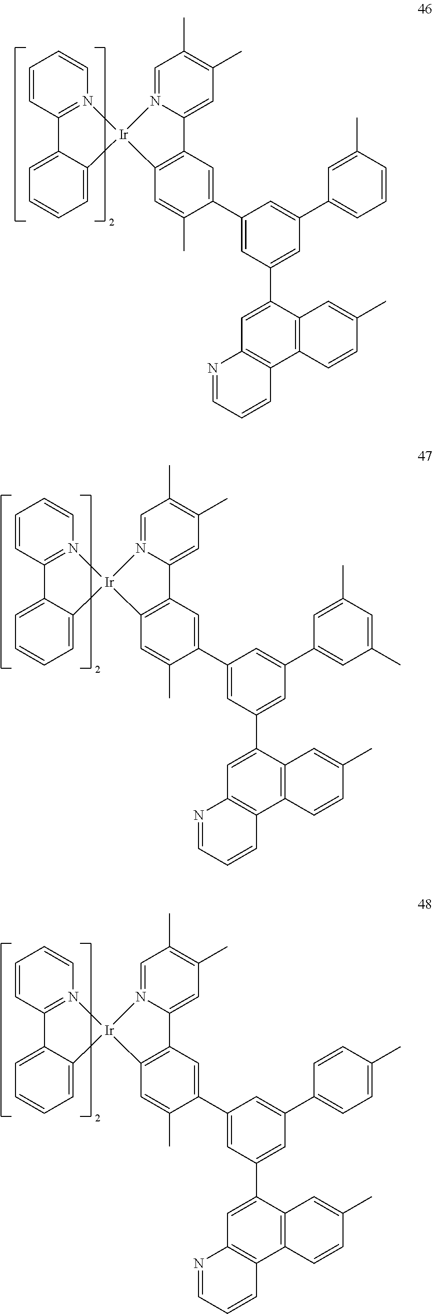

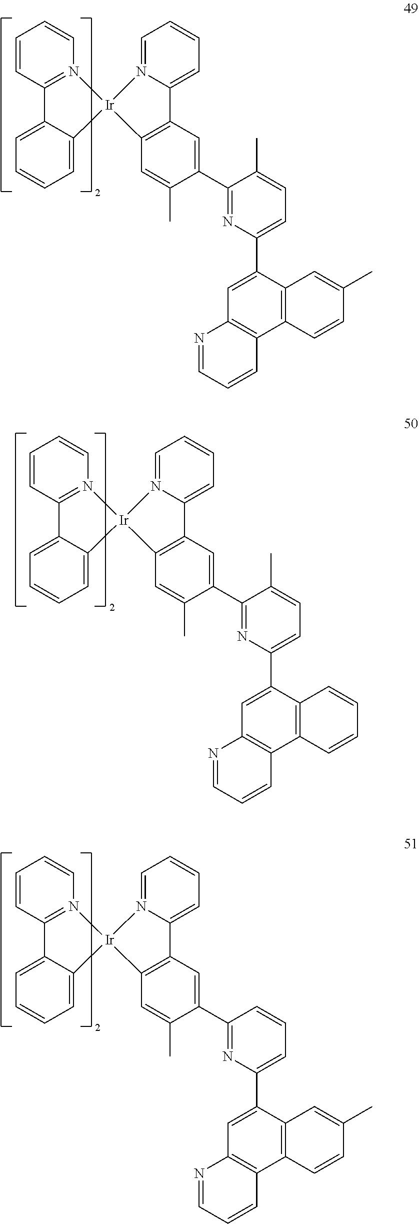

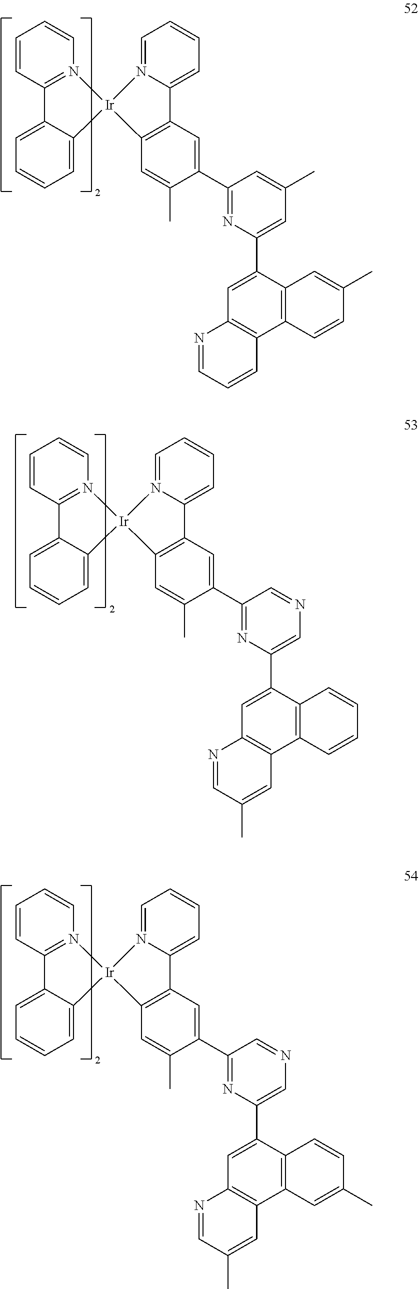

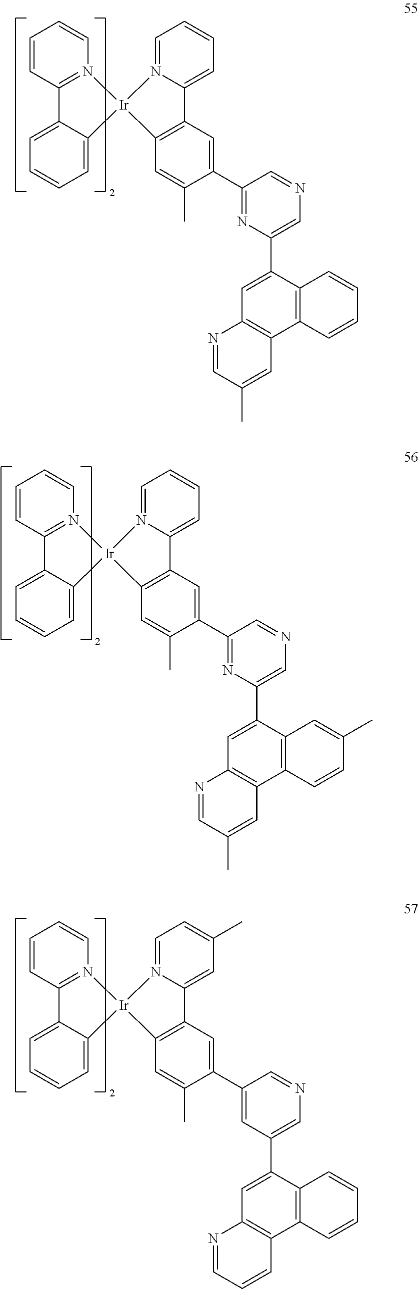

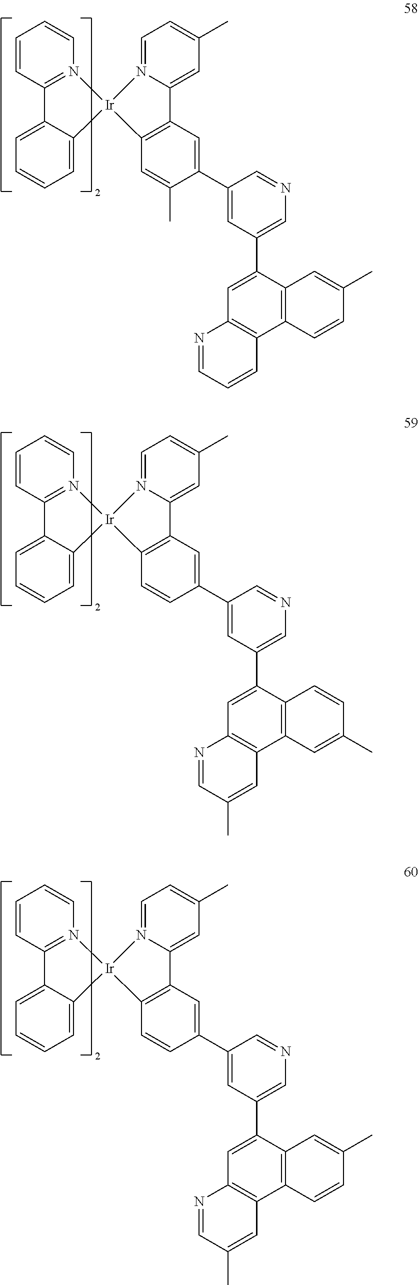

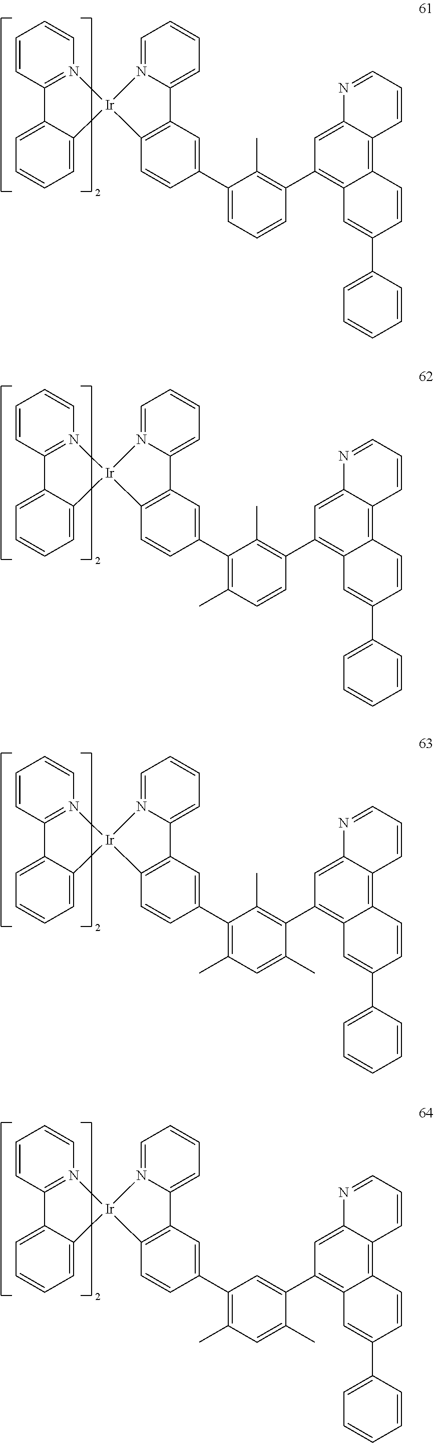

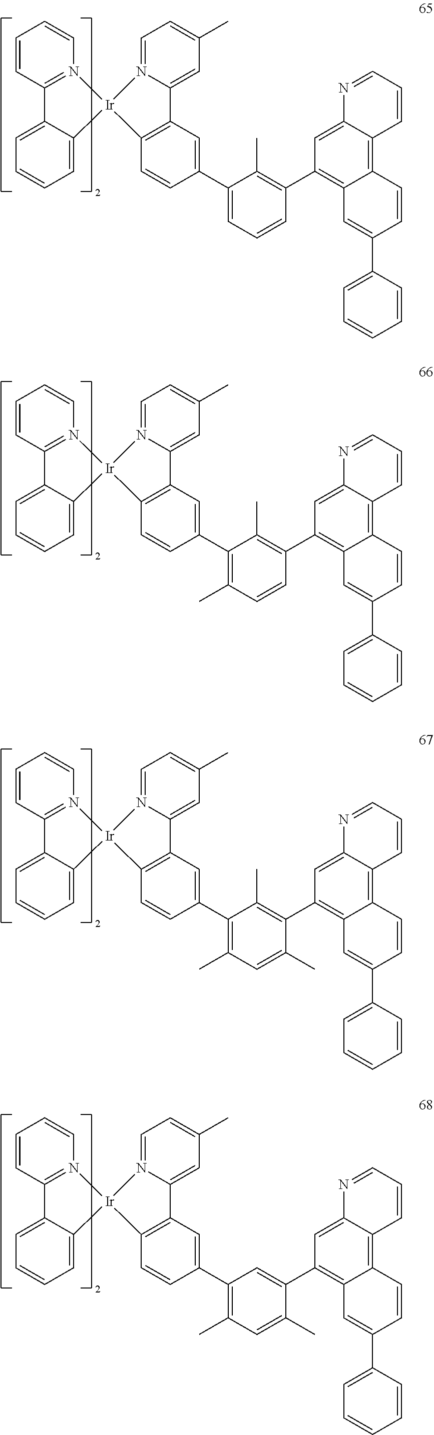

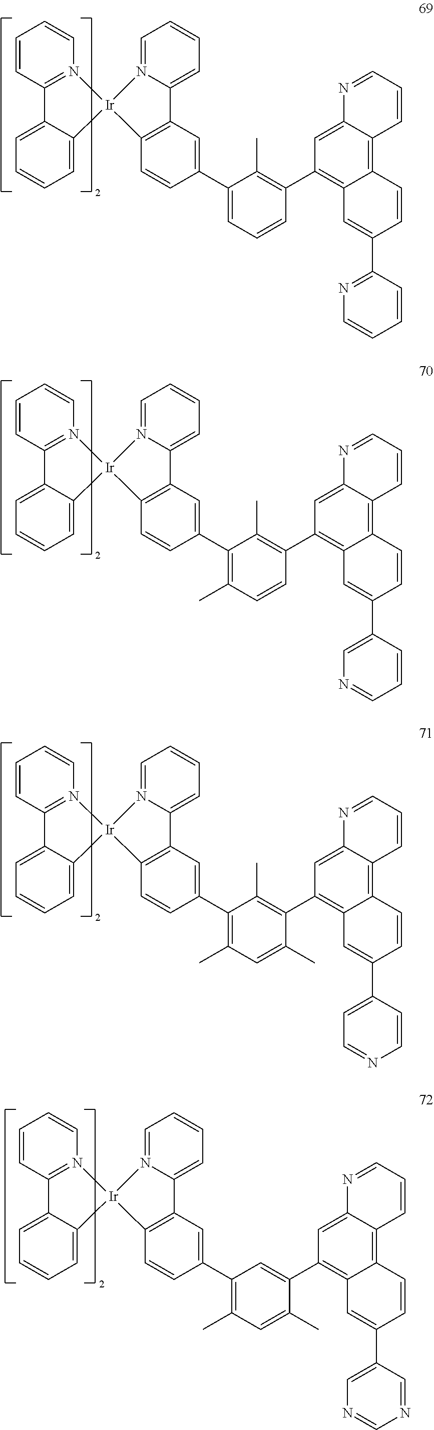

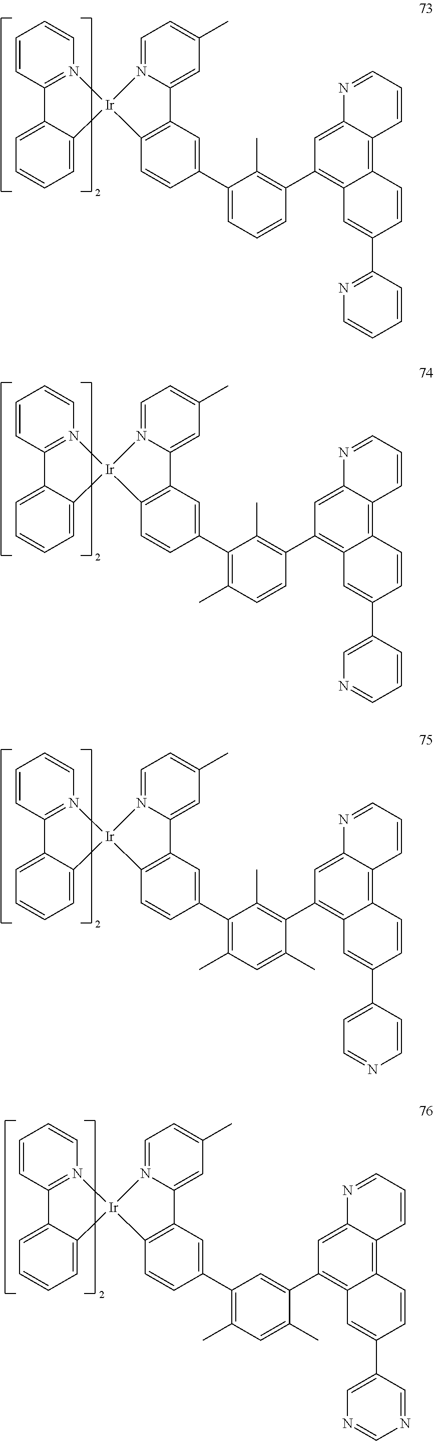

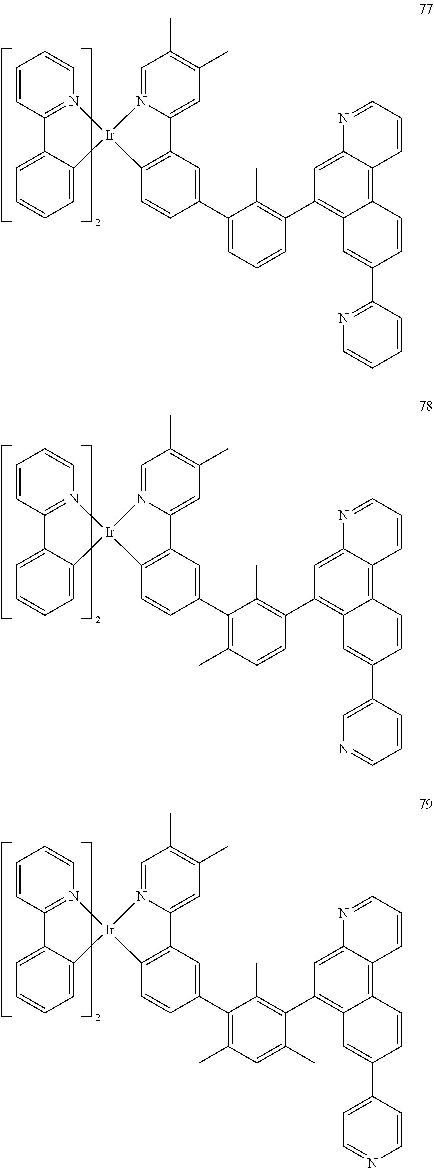

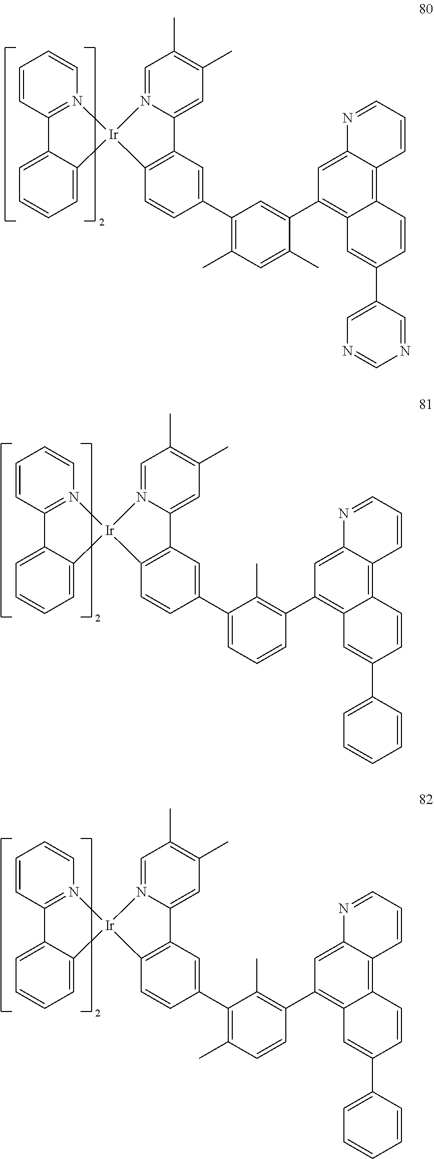

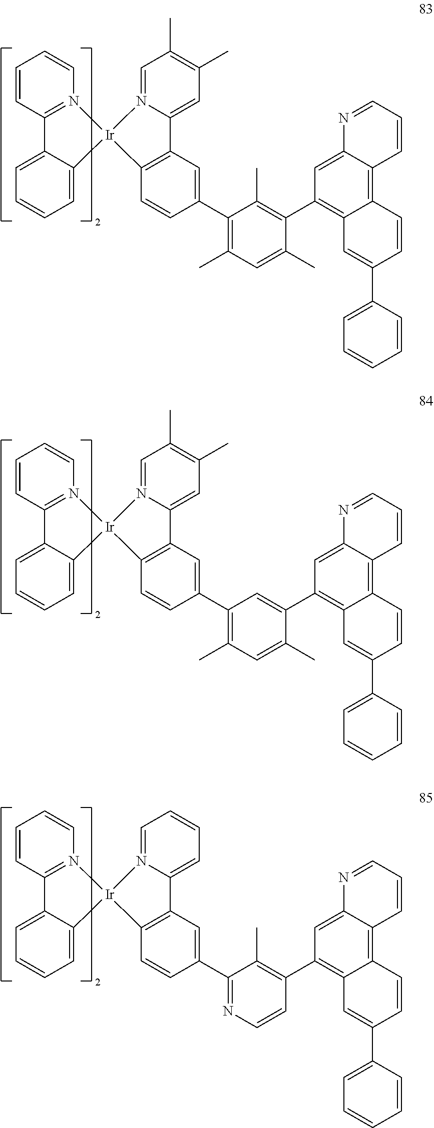

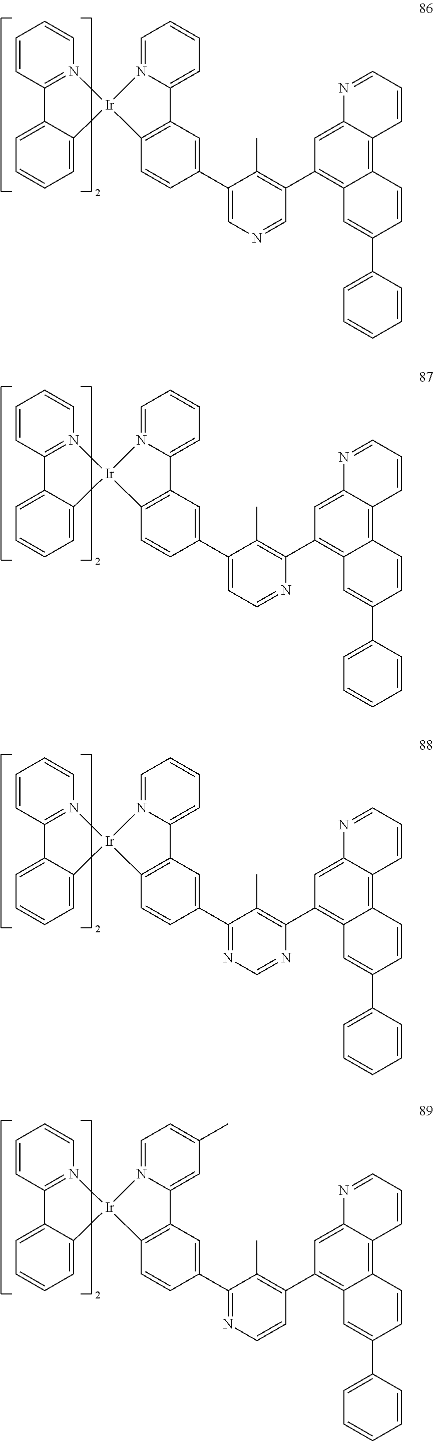

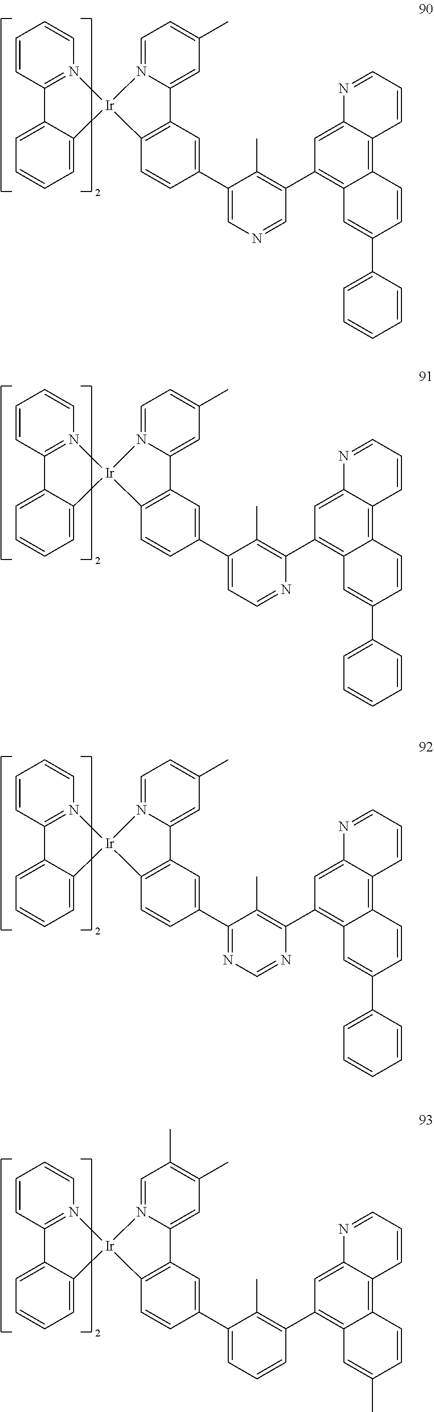

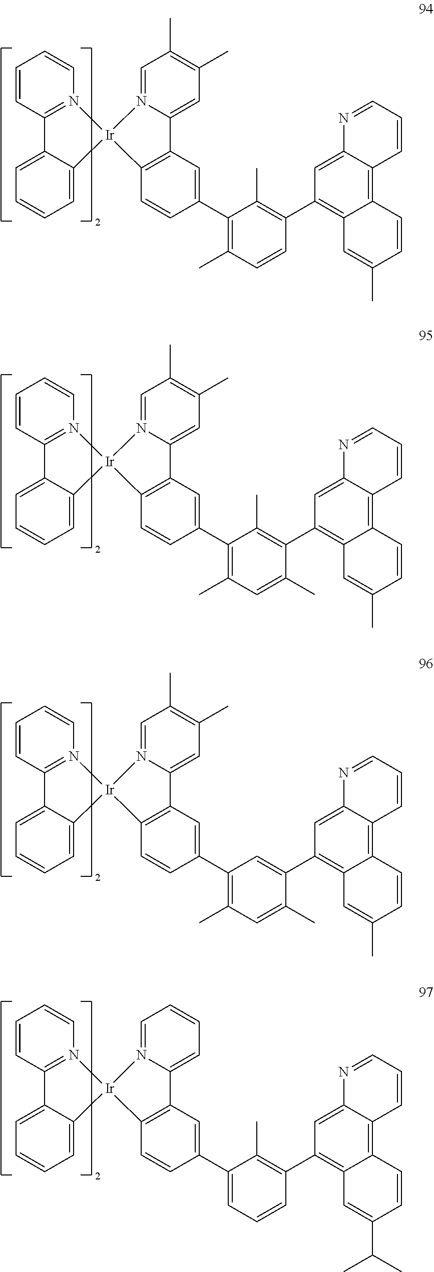

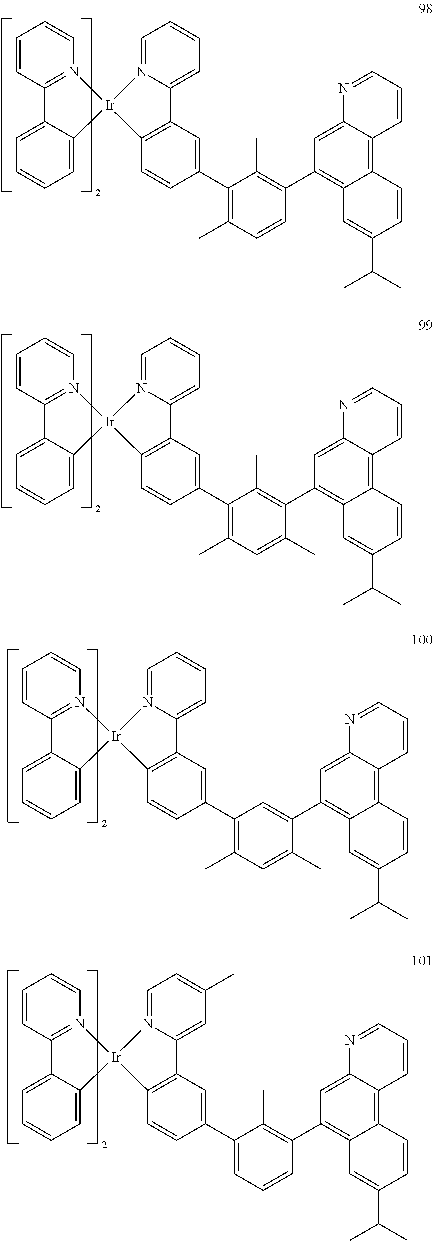

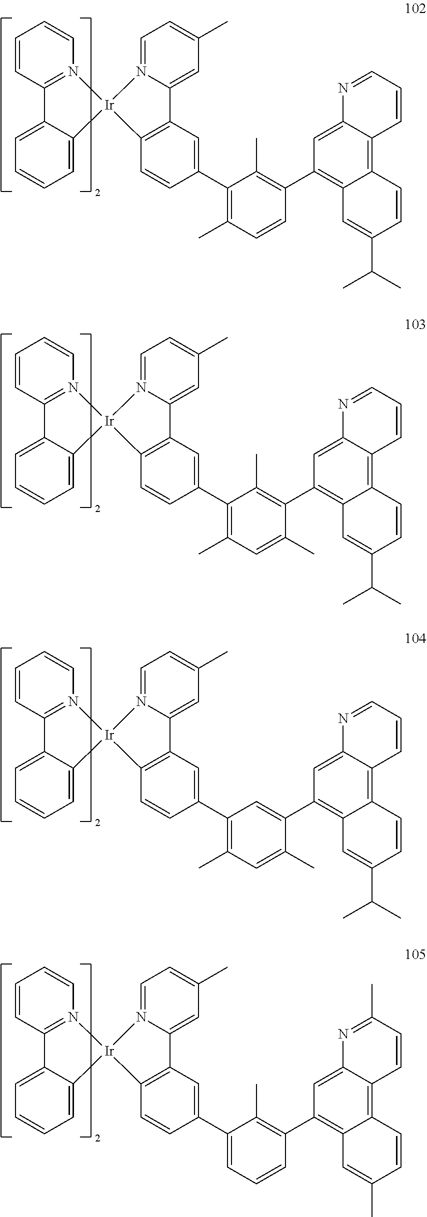

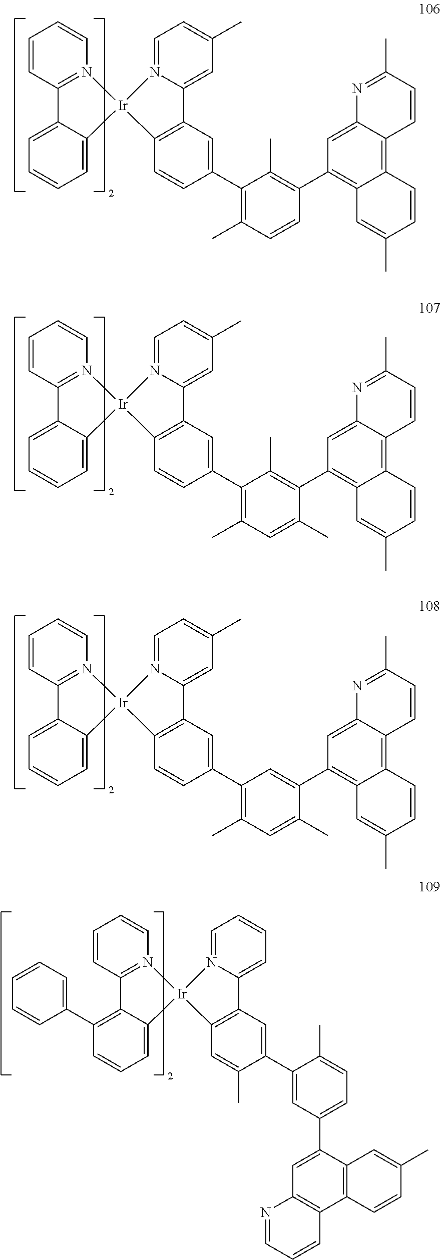

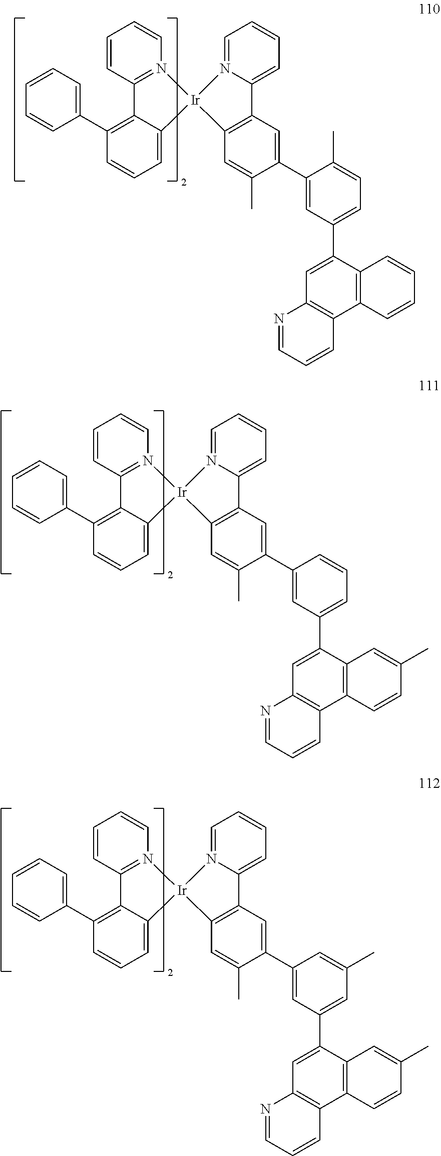

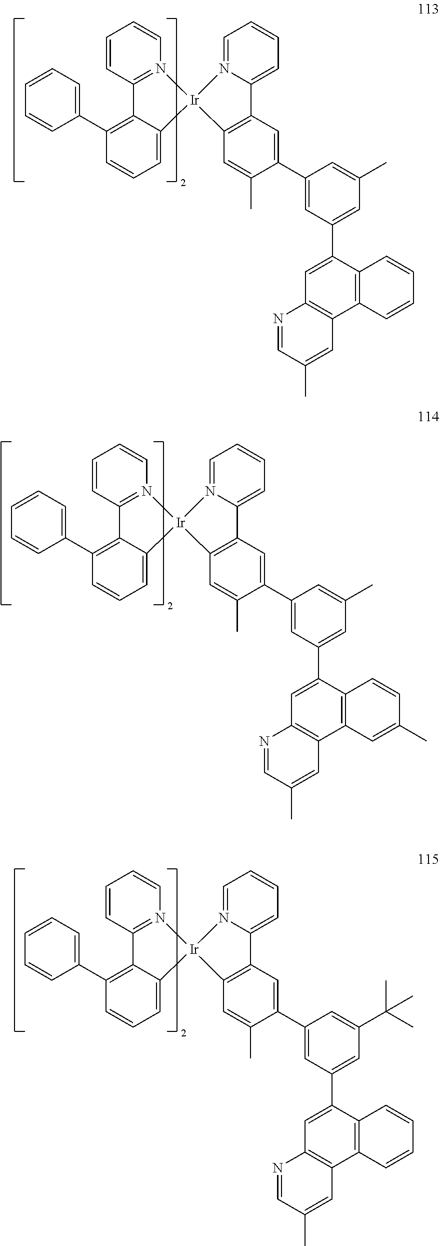

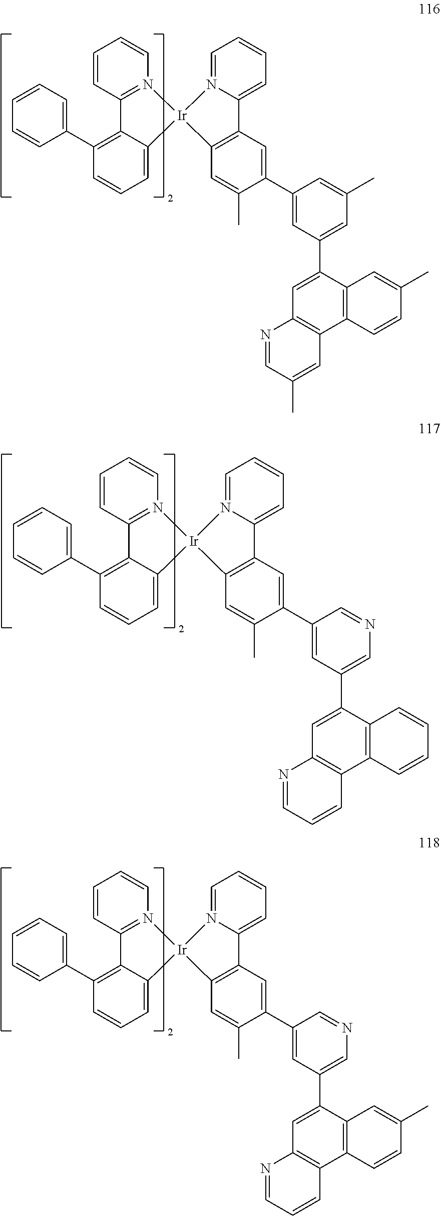

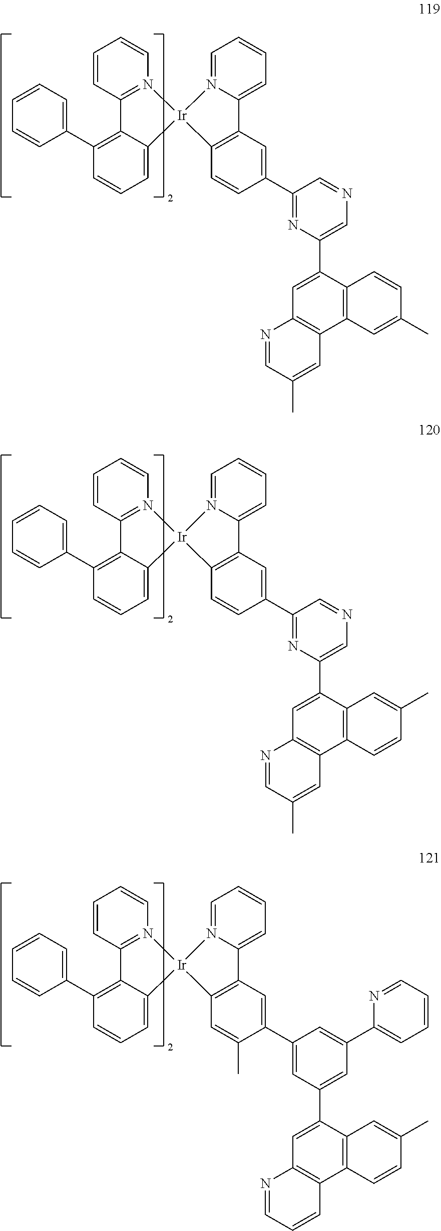

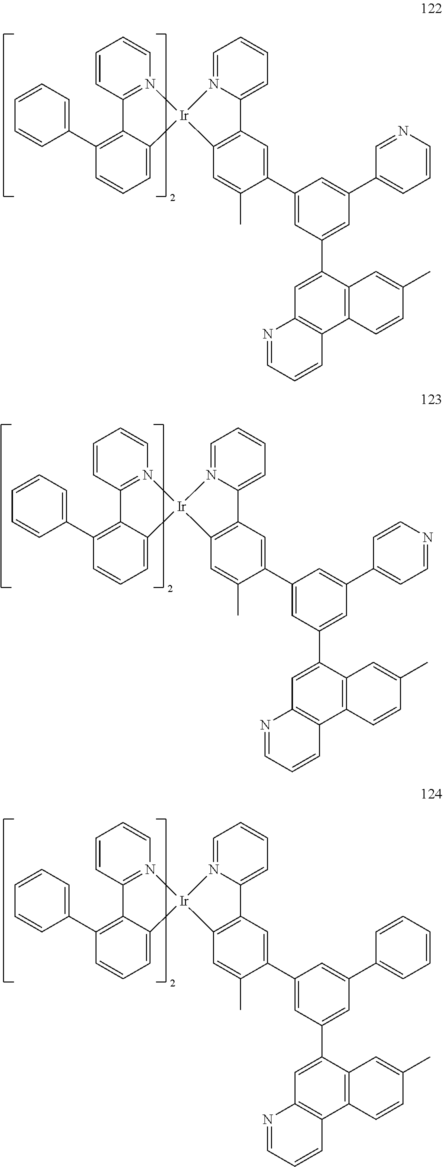

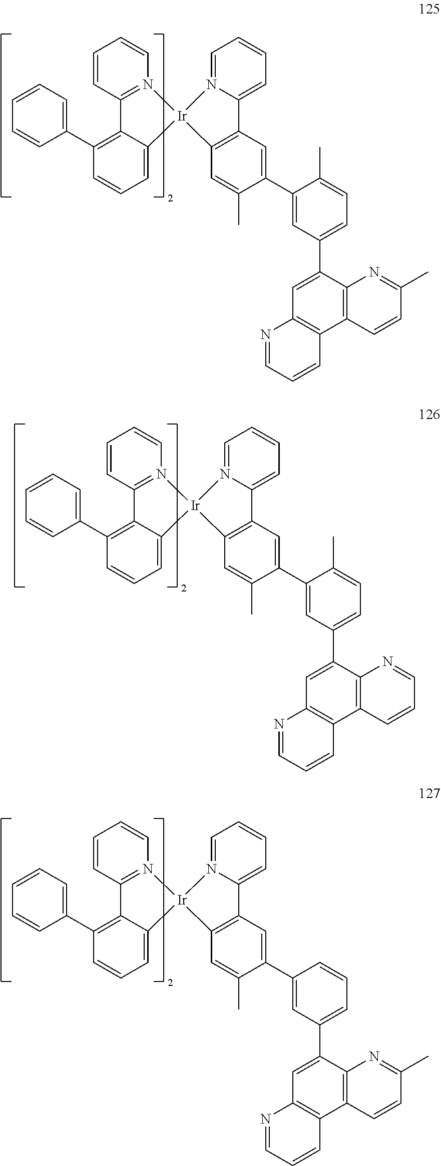

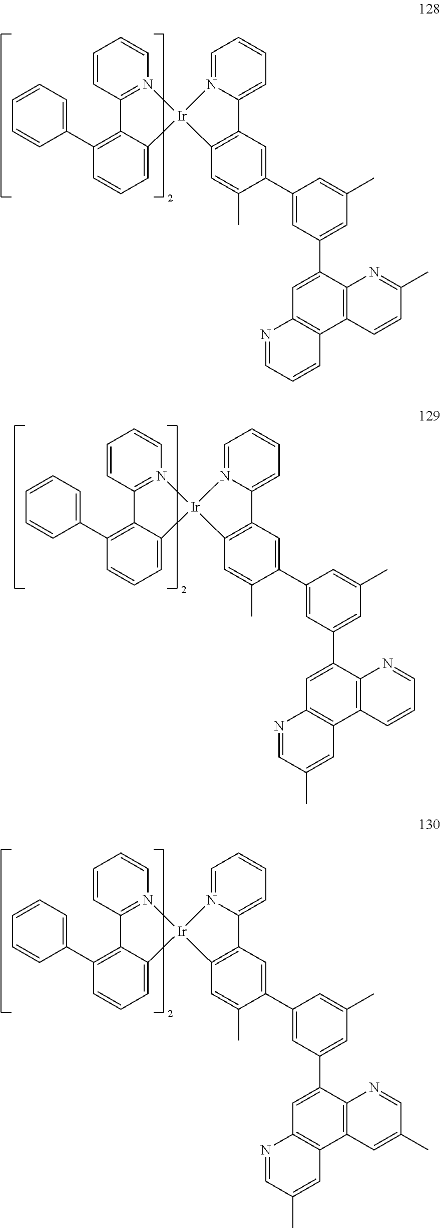

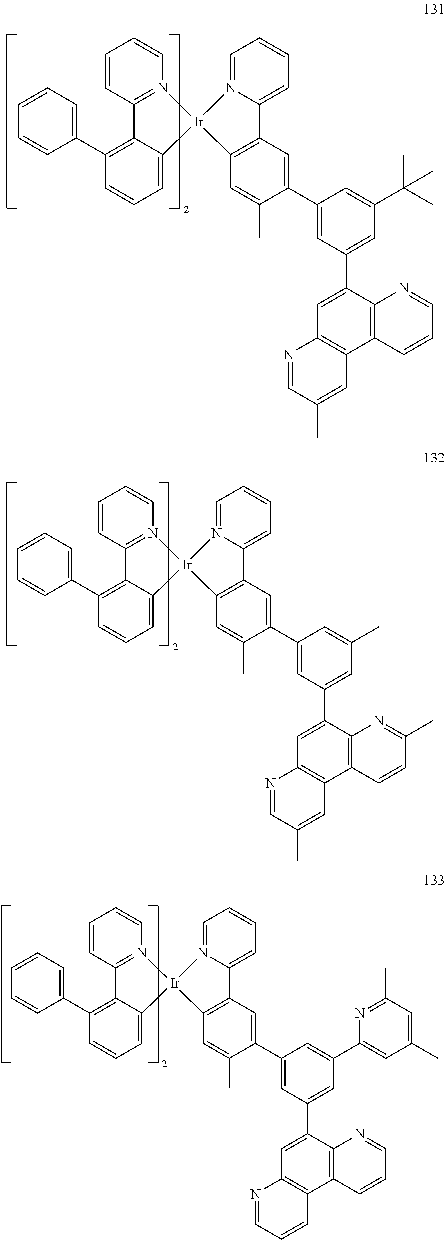

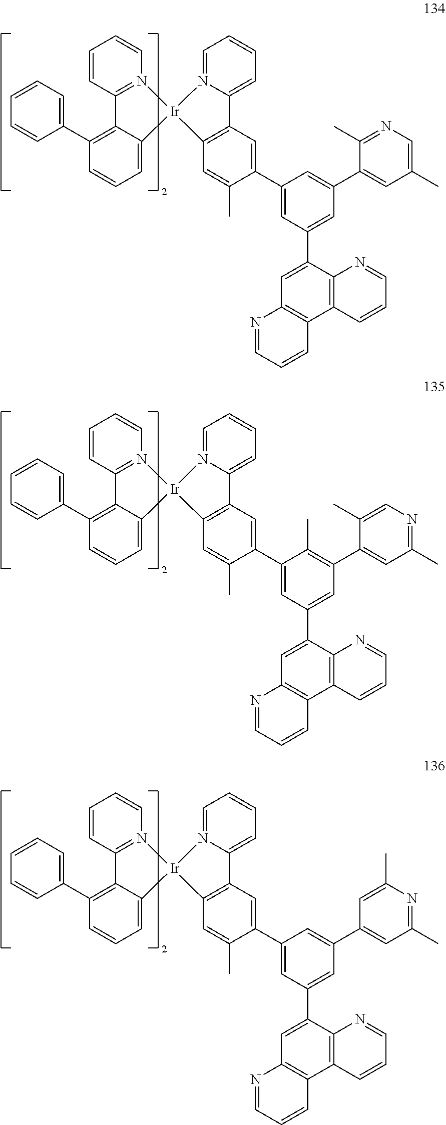

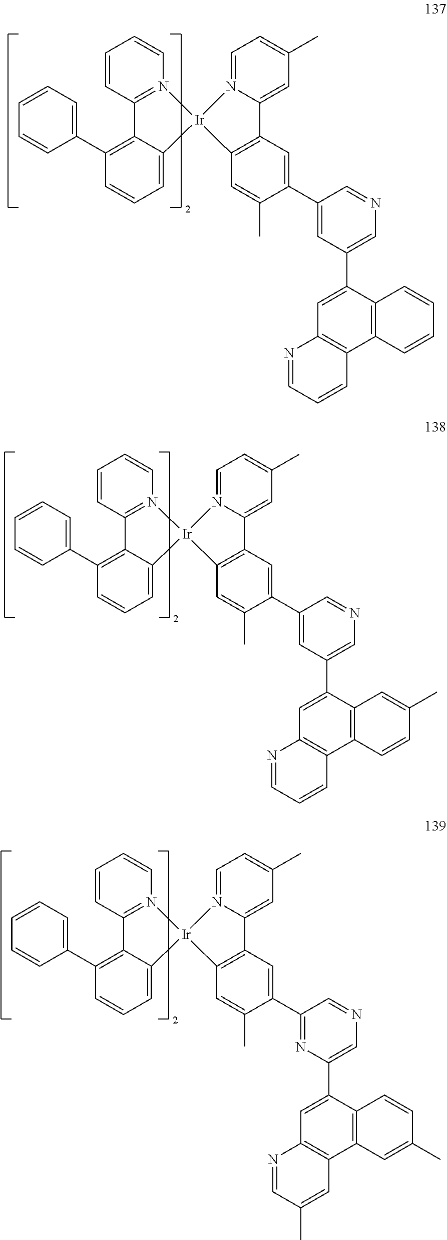

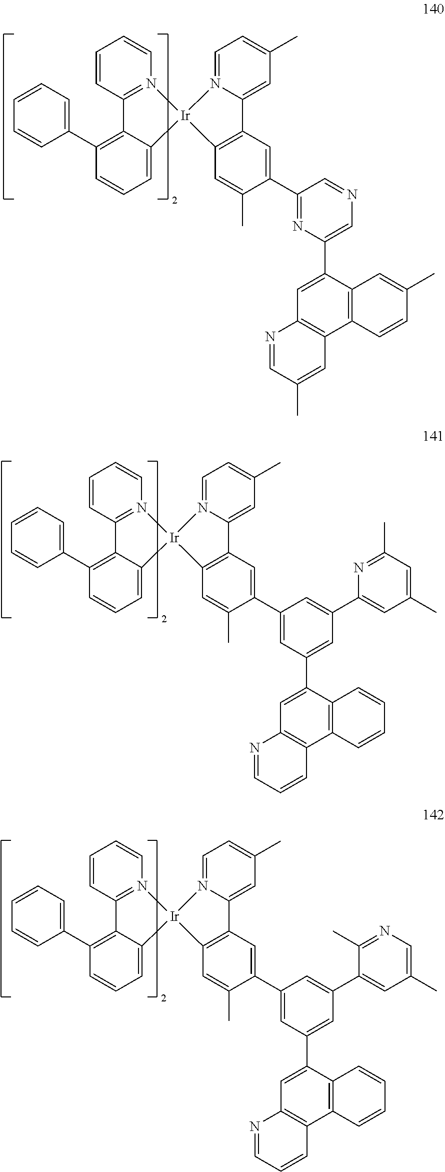

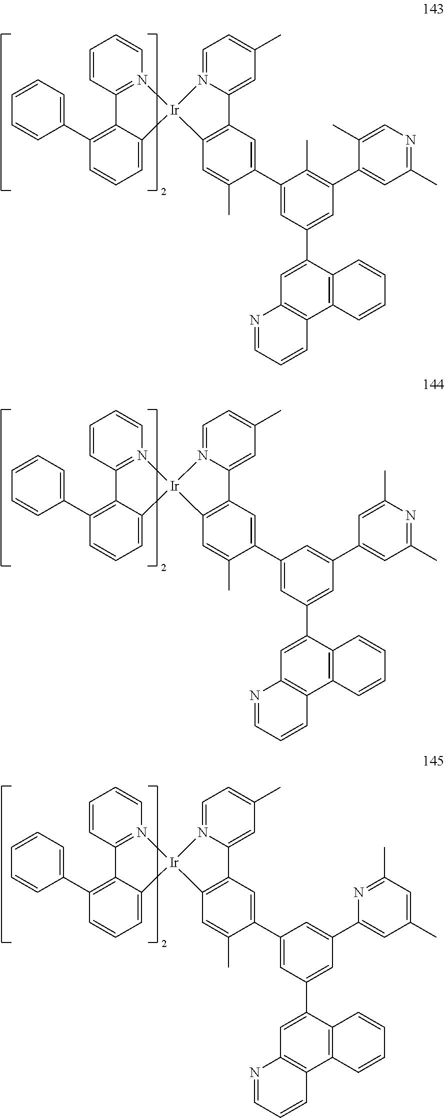

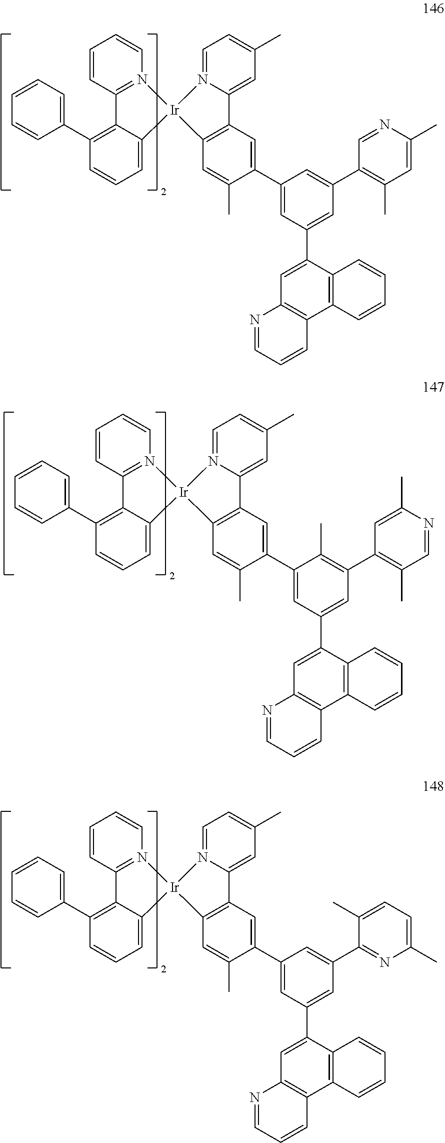

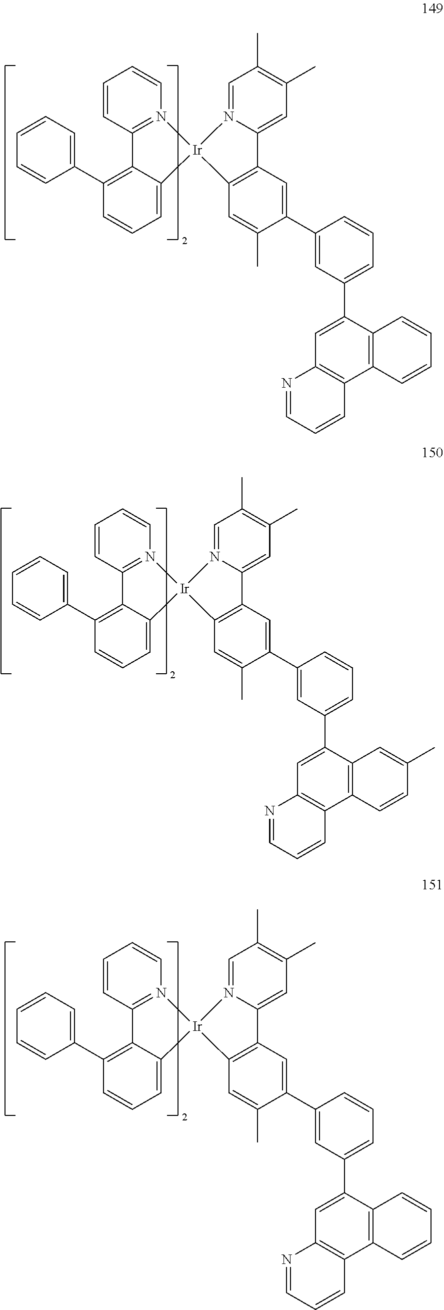

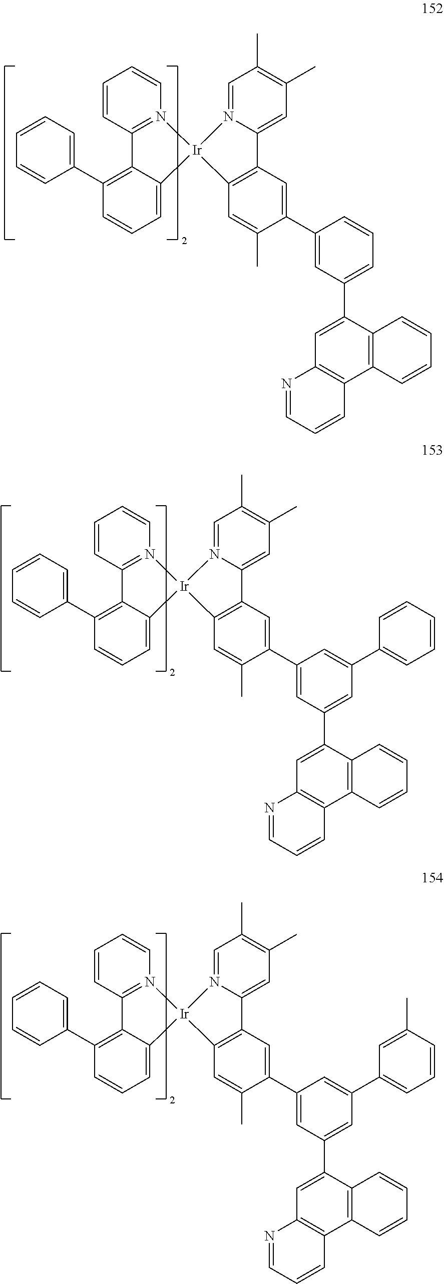

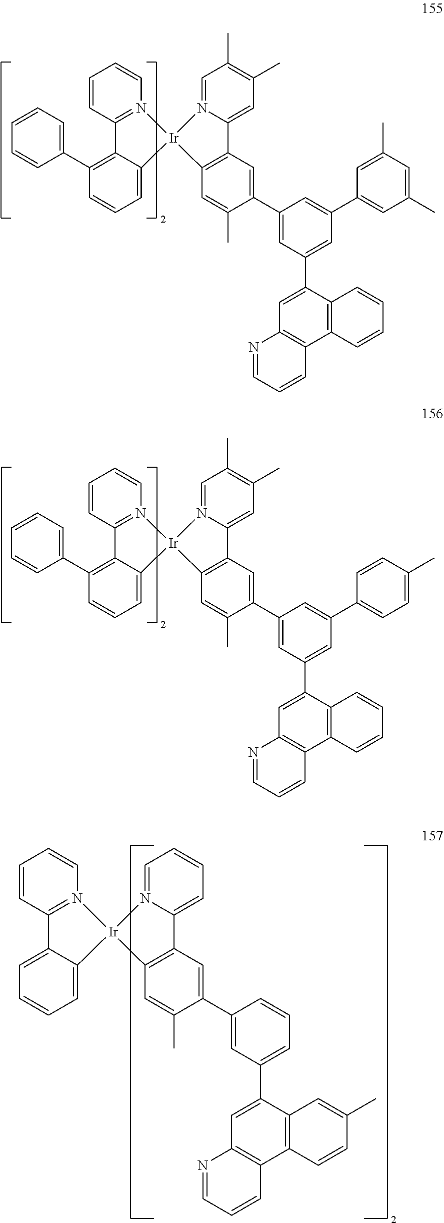

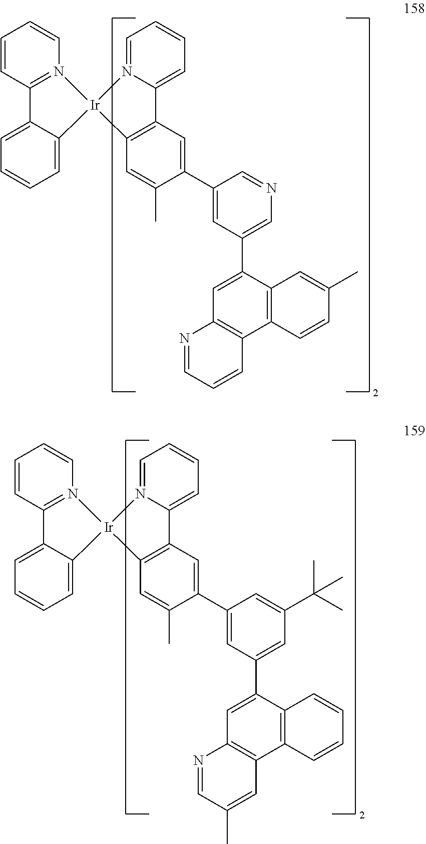

6. An organic light emitting diode, comprising:
a first electrode;
a second electrode facing the first electrode; and
a first emitting part positioned between the first and second electrodes and including a first emitting material layer,
wherein the first emitting material layer includes the organometallic compound of claim 1.

7. The organic light emitting diode according to claim 6, wherein the organometallic compound is used as a first dopant, and the first emitting material layer further includes a first host.

8. The organic light emitting diode according to claim 7, further comprising:
a second emitting part including a second emitting material layer and positioned between the first emitting part and the first electrode; and
a first charge generation layer between the first and second emitting parts.

9. The organic light emitting diode according to claim 8, wherein the second emitting material layer includes a blue dopant.

10. The organic light emitting diode according to claim 9, wherein the first emitting part further include a third emitting material layer disposed under or on the first emitting material layer.

11. The organic light emitting diode according to claim 10, wherein the third emitting material layer includes a red dopant.

12. The organic light emitting diode according to claim 9, further comprising:
a third emitting part positioned between the first emitting part and the second electrode and including a third emitting material layer; and
a second charge generation layer between the first and third emitting parts.

13. The organic light emitting diode according to claim 12, wherein the third emitting material layer includes a red dopant.

14. The organic light emitting diode according to claim 9, further comprising:
a third emitting part positioned between the first emitting part and the second electrode and including a third emitting material layer; and
a second charge generation layer between the first and third emitting parts,
wherein the first emitting part further includes a fourth emitting material layer disposed under or on the first emitting material layer.

15. The organic light emitting diode according to claim 14, wherein the third emitting material layer includes a blue dopant, and the fourth emitting material layer includes a red dopant.

16. An organic light emitting device, comprising:
a substrate;
an organic light emitting diode disposed on the substrate and including a first electrode, a second electrode facing the first electrode, a first emitting part positioned between the first and second electrodes and including a first emitting material layer; and
an encapsulation covering the organic light emitting diode,
wherein the first emitting material layer includes the organometallic compound of claim 1.

17. The organic light emitting device according to claim 16, wherein the organic light emitting diode further includes:
a second emitting part including a second emitting material layer and positioned between the first emitting part and the first electrode; and
a first charge generation layer between the first and second emitting parts,
wherein the second emitting material layer includes a blue dopant.

18. The organic light emitting device according to claim 17, wherein the first emitting part further include a third emitting material layer disposed under or on the first emitting material layer, and
wherein the third emitting material layer includes a red dopant.

19. The organic light emitting device according to claim 17, wherein the organic light emitting diode further includes:
a third emitting part positioned between the first emitting part and the second electrode and including a third emitting material layer; and
a second charge generation layer between the first and third emitting parts,
wherein the third emitting material layer includes a red dopant.

20. The organic light emitting device according to claim 17, wherein the organic light emitting diode further includes:
a third emitting part positioned between the first emitting part and the second electrode and including a third emitting material layer; and
a second charge generation layer between the first and third emitting parts,
wherein the first emitting part further includes a fourth emitting material layer disposed under or on the first emitting material layer, and
wherein the third emitting material layer includes a blue dopant, and the fourth emitting material layer includes a red dopant.
